(19) United States
(12) Patent Application Publication
(10) Pub. No.: US 2023/0069709 A1
(43) Pub. Date: Mar. 2, 2023

(54) TOUCH PANEL SENSOR AND MANUFACTURING METHOD OF TOUCH PANEL SENSOR

(71) Applicant: FUJIFILM Corporation, Tokyo (JP)

(72) Inventors: Yohei ARITOSHI, Shizuoka (JP); Kentaro TOYOOKA, Shizuoka (JP)

(73) Assignee: FUJIFILM Corporation, Tokyo (JP)

(21) Appl. No.: 17/874,528

(22) Filed: Jul. 27, 2022

(30) Foreign Application Priority Data
Jul. 30, 2021 (JP) 2021-125824

(51) Int. Cl. G06F 3/045; G03F 7/16; G03F 7/033; G03F 7/20; G03F 7/30; G03F 7/40

(52) U.S. Cl. CPC G06F 3/045; G03F 7/16; G03F 7/033; G03F 7/20; G03F 7/30; G03F 7/40; G06F 2203/04107; G06F 2203/04103; G06F 2203/04102

(57) ABSTRACT

Provided are a touch panel sensor in which a change in resistance value of a sensor electrode of the touch panel sensor after bending is small, and bright spots are less likely to be generated in a case of handling such as a roll transporting; and a manufacturing method of a touch panel sensor. The touch panel sensor includes a conductive base material including a base material and a sensor electrode disposed on the base material and a protective film covering at least a part of the sensor electrode, in which a surface hardness of the protective film on an opposite side to the conductive base material is 185 mN/mm² or more, and a diameter X obtained by performing a predetermined test is 3 mm or less.

### CROSS-REFERENCE TO RELATED APPLICATIONS

The present application claims priority under 35 U.S.C. § 119 to Japanese Patent Application No. 2021-125824, filed on Jul. 30, 2021. The above application is hereby expressly incorporated by reference, in its entirety, into the present application.

### BACKGROUND OF THE INVENTION

### 1. Field of the Invention

The present invention relates to a touch panel sensor and a manufacturing method of a touch panel sensor.

### 2. Description of the Related Art

In a display device provided with a touch panel such as a capacitive input device (specifically, a display device such as an organic electroluminescence (EL) display device and a liquid crystal display device), a conductive pattern such as a sensor electrode pattern corresponding to a sensor in a visual recognition portion and a wiring line for a peripheral wiring portion and a lead out wiring portion is provided inside the touch panel.

On this conductive pattern, normally, for the purpose of preventing problems such as metal corrosion, increased electrical resistance between electrodes and drive circuits, and disconnection, a pattern formed of a resin may be disposed as a protective film (permanent film).

Generally, a photosensitive composition is used for forming the pattern, and in particular, since the number of steps to obtain the required pattern shape is small, a method using a transfer film having a temporary support and a photosensitive composition layer formed of the photosensitive composition is widely used.

Examples of a method of forming the pattern using a transfer film include a method of exposing and developing a photosensitive composition layer transferred from a transfer film onto any base material through a mask having a predetermined pattern shape. For example, in a case where the photosensitive composition layer is a negative tone photosensitive composition layer, the exposed region is cured, so that a dissolution contrast may be generated between the exposed region and the unexposed region. As a result, a pattern can be formed by removing only the unexposed region during the development treatment.

As the photosensitive composition and the transfer film, for example, WO2013/084886A discloses a “photosensitive resin composition containing, on a base material, a binder polymer having a carboxy group in which an acid value is 75 mgKOH/g or more, a photopolymerizable compound, and a photopolymerization initiator” and a “photosensitive element including a support film and a photosensitive layer consisting of the photosensitive resin composition, which is provided on the support film”.

### SUMMARY OF THE INVENTION

In a case where the present inventors have manufactured a touch panel sensor using the photosensitive element (transfer film) disclosed in WO2013/084886A, and measured a resistance value of a sensor electrode after bending, it is found that a change in resistance value is large between before and after bending.

Further, in a case where the touch panel sensor manufactured by using the above-described transfer film is handled by a roll transporting or the like, bright spots may occur.

In addition, as a result of studies by the present inventors, it is difficult to achieve both the change in resistance value and a suppression of the generation of bright spots.

The change in resistance value and the generation of bright spots are not desirable from the viewpoint of changes in sensor performance and visibility, respectively.

Therefore, an object of the present invention is to provide a touch panel sensor in which a change in resistance value of a sensor electrode of the touch panel sensor after bending is small, and bright spots are less likely to be generated in a case of handling such as a roll transporting.

Another object of the present invention is to provide a manufacturing method of a touch panel sensor.

The present inventors have completed the present invention as a result of intensive studies to solve the above-described problems. That is, the present inventors have found that the above-described objects can be achieved by the following configuration.

[1] A touch panel sensor comprising:

a conductive base material including a base material and a sensor electrode disposed on the base material; and

a protective film covering at least a part of the sensor electrode,

in which a surface hardness of the protective film on an opposite side to the conductive base material is 185 mN/mm² or more, and

a diameter X obtained by performing the following mandrel test is 3 mm or less,

mandrel test: an operation of winding the touch panel sensor around a mandrel and returning the touch panel sensor to an original position is repeated 10 times, an operation of observing the protective film of the touch panel sensor with an optical microscope at a magnification of 10 times to confirm presence or absence of cracks in the protective film is repeated while reducing a diameter of the mandrel, and a diameter of the mandrel in which the protective film is cracked is defined as the diameter X.

[2] The touch panel sensor according to [1],

in which the protective film is a film formed of a photosensitive composition, and

the photosensitive composition includes a binder polymer having an ethylenically unsaturated group in a side chain.

[3] The touch panel sensor according to [2],

in which the photosensitive composition further includes a first polymerizable compound having two ethylenically unsaturated groups and a second polymerizable compound having five or more ethylenically unsaturated groups.

[4] The touch panel sensor according to [3],

in which a mass ratio of a content of the second polymerizable compound to a content of the first polymerizable compound is 0.4 to 1.3.

[5] A manufacturing method of a touch panel sensor, comprising:

a preparing step of preparing a base material with a photosensitive composition layer, which has a conductive base material including a base material and a sensor electrode disposed on the base material and has a photosensitive composition layer disposed on the conductive base material and including a binder polymer, a compound having an ethylenically unsaturated group, and a photopolymerization initiator;

an exposing step of exposing the photosensitive composition layer in a patterned manner;

a developing step of developing the exposed photosensitive composition layer to form a resin layer pattern; and

a curing step of exposing the resin layer pattern under a condition of the resin layer pattern being at 50° C. to 120° C. to form a protective film covering at least a part of the sensor electrode.

[6] The manufacturing method of a touch panel sensor according to [5],

in which an exposure amount in the curing step is 200 to 1500 mJ/cm².

[7] The manufacturing method of a touch panel sensor according to [5] or [6],

in which an exposure amount in the curing step is 200 mJ/cm² or more and less than 1000 mJ/cm².

[8] The manufacturing method of a touch panel sensor according to any one of [5] to [7],

in which, in a case where an intensity of an infrared absorption peak derived from the ethylenically unsaturated group included in the photosensitive composition layer is defined as Y₁ and an intensity of an infrared absorption peak derived from the ethylenically unsaturated group included in the protective film is defined as Y₂, a reaction rate calculated by the following expression (1) is 70% or more,

reaction rate [%]={1−(Y₂/Y₁)}×100. expression (1)

According to the present invention, it is possible to provide a touch panel sensor in which a change in resistance value of a sensor electrode of the touch panel sensor after bending is small, and bright spots are less likely to be generated in a case of handling such as a roll transporting.

In addition, according to the present invention, it is possible to provide a manufacturing method of a touch panel sensor.

### BRIEF DESCRIPTION OF THE DRAWINGS

FIG. 1 is a schematic cross-sectional view showing a method for deforming a touch panel sensor in a resistance change evaluation of Examples.

### DESCRIPTION OF THE PREFERRED EMBODIMENTS

Hereinafter, the present invention will be described in detail.

The description of the configuration requirements described below is made on the basis of representative embodiments of the present invention, but it should not be construed that the present invention is limited to those embodiments.

Hereinafter, meaning of each description in the present specification will be explained.

In the present specification, the numerical ranges shown using “to” indicate ranges including the numerical values described before and after “to” as the lower limit value and the upper limit value.

In the numerical range described stepwise in the present specification, the upper limit value or the lower limit value described in a certain numerical range may be replaced with the upper limit value or the lower limit value of another numerical range described stepwise. In addition, regarding the numerical range described in the present specification, an upper limit value or a lower limit value described in a numerical value may be replaced with a value described in Examples.

In the present specification, the term “step” includes not only an independent step but also a step that cannot be clearly distinguished from other steps, as long as the intended purpose of the step is achieved.

In the present specification, “transparent” means that an average transmittance of visible light having a wavelength of 400 nm to 700 nm is 80% or more, preferably 90% or more.

In the present specification, a transmittance is a value measured by using a spectrophotometer, and for example, can be measured by using a spectrophotometer U-3310 manufactured by Hitachi, Ltd.

In the present specification, unless otherwise specified, a weight-average molecular weight (Mw) and a number average molecular weight (Mn) are values obtained by a gel permeation chromatography (GPC) analysis apparatus and converted using polystyrene as a standard substance, with TSKgel GMHxL, TSKgel G4000HxL, or TSKgel G2000HxL (all product names manufactured by Tosoh Corporation) as a column, tetrahydrofuran (THF) as an eluent, and a differential refractometer as a detector.

In the present specification, unless otherwise specified, a ratio of constitutional units of a polymer is a mass ratio.

In the present specification, unless otherwise specified, a molecular weight of a compound having a molecular weight distribution is the weight-average molecular weight (Mw).

In the present specification, unless otherwise specified, a content of metal elements is a value measured by using an inductively coupled plasma (ICP) spectroscopic analysis apparatus.

In the present specification, unless otherwise specified, a refractive index is a value measured by using an ellipsometer at a wavelength of 550 nm.

In the present specification, unless otherwise specified, a hue is a value measured by using a colorimeter (CR-221, manufactured by Konica Minolta, Inc.).

In the present specification, “(meth)acrylic” is a concept including both acrylic and methacrylic, and “(meth)acryloxy group” is a concept including both an acryloxy group and a methacryloxy group.

In the present specification, “alkali-soluble” means that the solubility in 100 g of aqueous solution of 1% by mass sodium carbonate at 22° C. is 0.1 g or more.

In the present specification, “water-soluble” means that the solubility in 100 g of water with a pH of 7.0 at a liquid temperature of 22° C. is 0.1 g or more. Therefore, for example, a water-soluble resin is intended to be a resin which satisfies the above-described solubility conditions.

In the present specification, a “solid content” of a composition refers to components which form a composition layer formed of the composition, and in a case where the composition includes a solvent (an organic solvent, water, and the like), the solid content means all components except the solvent. In addition, in a case where the components are components which form a composition layer, the components are considered to be solid contents even in a case where the components are liquid components.

Touch Panel Sensor

A touch panel sensor according to an embodiment of the present invention includes a conductive base material including a base material and a sensor electrode disposed on the base material and a protective film covering at least a part of the sensor electrode. As feature points of the touch panel sensor according to the embodiment of the present invention, a surface hardness of the protective film on an opposite side to the conductive base material is 185 mN/mm² or more, and a diameter X obtained by performing a mandrel test described in detail later is 3 mm or less.

Mechanism by which the touch panel sensor having the above-described feature points has small change in resistance value of the sensor electrode of the touch panel sensor after bending and bright spots are less likely to be generated is not necessarily clear in detail, but the present inventors are presumed as follows.

In the touch panel sensor according to the embodiment of the present invention, since the diameter X obtained by performing the mandrel test is 3 mm or less, even in a case where the touch panel sensor is bent during manufacturing of the touch panel sensor, the protective film is not cracked. Therefore, it is considered that local stress acts on the sensor electrode disposed under the protective film to prevent cracks or the like from occurring in the sensor electrode, and as a result, the change in resistance value of the sensor electrode is small.

In addition, in the touch panel sensor according to the embodiment of the present invention, since the surface hardness of the protective film on the opposite side to the conductive base material is 185 mN/mm² or more, it is considered that, even in a case where another object comes into contact with the touch panel sensor in a case of handling (for example, in a case of a roll transporting), the surface of the protective film is not scratched or deformed, and as a result, the bright spots are less likely to be generated in the manufactured touch panel sensor.

Hereinafter, the touch panel sensor according to the embodiment of the present invention will be described. In addition, a manufacturing method of the touch panel sensor according to the embodiment of the present invention will be described later.

In the following, in a case where at least one of the fact that the change in resistance value of the sensor electrode of the touch panel sensor after bending is smaller or the fact that the bright spots are less likely to be generated in the touch panel sensor is referred to as that “the effects of the present invention are more excellent”.

Conductive Base Material

The touch panel sensor according to the embodiment of the present invention includes a conductive base material including a base material and a sensor electrode disposed on the base material.

Hereinafter, the base material and the sensor electrode will be described.

Base Material

Examples of the base material include a resin base material, a glass base material, and a semiconductor base material.

A preferred aspect of the base material is described, for example, in paragraph [0140] of WO2018/155193A, the contents of which are incorporated herein by reference. As a material of the resin base material, a cycloolefin polymer or polyimide is preferable.

A thickness of the resin base material is preferably 5 to 200 μm and more preferably 10 to 100 μm.

In addition, the base material may have a transparent layer. Examples of the transparent layer include a refractive index adjusting layer which may be included in a transfer film described later.

Sensor Electrode

The sensor electrode refers to a patterned electrode formed on the above-described base material. The sensor electrode is an electrode which functions as a sensor unit in a case where a touch panel including the touch panel sensor according to the embodiment of the present invention is formed.

A patterned shape of the sensor electrode is not particularly limited, and may be a known one. The sensor electrode may be disposed on the entire surface of the base material, or may be disposed on a part of the base material. In addition, the sensor electrode may be disposed on both surfaces of the base material.

The sensor electrode preferably includes at least one conductive layer.

As the conductive layer, from the viewpoint of fine line formability and conductivity, at least one layer selected from the group consisting of a metal layer, a conductive metal oxide layer, a graphene layer, a carbon nanotube layer, and a conductive polymer layer is preferable.

In addition, as the sensor electrode, only one conductive layer may be disposed on the base material, or two or more layers may be arranged thereon. In a case where two or more conductive layers are arranged, it is preferable to have conductive layers formed of different materials.

A preferred aspect of the conductive layer is described, for example, in paragraph of WO2018/155193A, the contents of which are incorporated herein by reference.

The sensor electrode is also preferably a transparent electrode. The transparent electrode can function suitably as an electrode for a touch panel. The transparent electrode is preferably composed of a metal oxide film such as indium tin oxide (ITO) and indium zinc oxide (IZO), a metal mesh, and a fine metal wire such as a metal nanowire.

Examples of the fine metal wire include thin wire of silver and copper. Among these, silver conductive materials such as silver mesh and silver nanowire are preferable.

Lead Wire

The conductive base material may have a lead wire. The lead wire is electrically conducted to the above-described sensor electrode. In a case where the conductive base material has the transparent electrode and the lead wire, the conductive base material can be suitably used as a base material for a touch panel.

As a material of the lead wire, metal is preferable.

Examples of a metal which is a material of the lead wire include gold, silver, copper, molybdenum, aluminum, titanium, chromium, zinc, manganese, and alloy consisting of two or more kinds of these metal elements. As the material of the lead wire, copper, molybdenum, aluminum, or titanium is preferable, copper is particularly preferable.

Protective Film

The protective film is disposed on the conductive base material so as to cover at least a part of the above-described sensor electrode.

The protective film is not particularly limited as long as it has the above-described feature points, but preferably includes the above-described resin and is more preferably formed of a photosensitive composition. Further, it is more preferable that the photosensitive composition includes a binder polymer having an ethylenically unsaturated group in a side chain.

The protective film is preferably formed using a transfer film including a photosensitive composition layer, which will be described later. A preferred photosensitive composition layer is described in detail in the section of transfer film. In addition, a forming method of a preferred protective film will be described in detail in the section of manufacturing method of a touch panel sensor.

Physical Properties of Touch Panel Sensor and Protective Film

The touch panel sensor according to the embodiment of the present invention satisfies physical properties shown in the above-described feature points.

Hereinafter, each physical property will be described.

Surface Hardness

In the protective film included in the touch panel sensor according to the embodiment of the present invention, a surface hardness of the protective film on an opposite side to the conductive base material is 185 mN/mm² or more.

In the present specification, the above-described surface hardness is measured by the following procedure.

First, a touch panel sensor having a conductive base material including a base material and a sensor electrode disposed on the base material and at least a protective film covering at least a part of the sensor electrode is prepared. The touch panel sensor is cut into 2 cm squares to produce a sample.

An instant adhesive Aron Alpha (registered trademark) 201 is applied to a slide glass (thickness 0 7 mm) such that a diameter is 1 cm, and immediately, a surface of the slide glass to which the instant adhesive has been applied is bonded to a surface of the sample opposite to the protective film. In the bonding, the sample is held with finger so that there is no gap between the slide glass and the sample. After bonding, the sample is allowed to stand in an environment of 23° C. and 50% humidity. A measurement sample is obtained by the above-described procedure.

Using the obtained measurement sample, the surface hardness of the protective film is measured with a micro hardness tester under the following conditions.
Device name: micro hardness tester (model number: HM2000, manufactured by FISCHER instruments)
Indenter: Berkovich indenter
Maximum load: 1 mN
Load time: 10 seconds (time from when the indenter detects the surface of the cured substance to when the maximum load is reached)
Holding time: 5 seconds (time to hold the maximum load)
Unloading time: 10 seconds (time until the load is reduced to zero)

A contact projected area of the pressed indenter is calculated from a pushing depth, and the maximum load=1 mN is divided by the area to obtain the surface hardness (N/mm²). The measurement location is changed 10 times while being separated from the measurement location by 0.3 mm or more, and the surface hardness obtained by the 10 measurements is arithmetically averaged to obtain the surface hardness of the measurement sample.

The surface hardness of the protective film is 185 N/mm² or more, preferably 190 N/mm² or more and more preferably 200 N/mm² or more. The upper limit is not particularly limited, but is preferably 300 N/mm² or less, more preferably 250 N/mm² or less, and still more preferably 220 N/mm² or less.

In a case where the surface hardness of the protective film is within the above-described preferred range, it is possible to make it more difficult for the touch panel sensor to generate the bright spots during handling such as a roll transporting.

The above-described surface hardness can be adjusted by the type, content, and content ratio of the ethylenically unsaturated compound included in the photosensitive composition layer, which will be described later, and the type of the binder polymer. In addition, the surface hardness can also be adjusted by the manufacturing conditions of the manufacturing method of the touch panel sensor, which will be described later.

Mandrel Test

In the touch panel sensor according to the embodiment of the present invention, a diameter X obtained by performing a mandrel test described in detail later is 3 mm or less.

In the present specification, the diameter X obtained by performing a mandrel test is measured by the following procedure.

Flexibility is evaluated by a method according to JIS K-5600-5-1 (1999) using a type 2 test device, that is, by a cylindrical mandrel method. In the above-described method, a mandrel having a mandrel diameter of 1 mm, 2 mm, 3 mm, 4 mm, and 5 mm is used, and the number of bendings is 10 times. After bending, the surface of the protective film of the touch panel sensor is observed with an optical microscope at a magnification of 10 times to confirm the presence or absence of cracks in the protective film. In a case where the cracks in the protective film cannot be confirmed, the same test is performed with a mandrel having a smaller diameter than the mandrel used.

The above-described test is repeated, and a diameter of the mandrel in which the protective film is cracked for the first time is defined as the diameter X. In a case where no cracks occur even with a 1 mm mandrel, the diameter X is set to 1 mm.

The above-described diameter X is 3 mm or less, preferably 2 mm or less and more preferably 1 mm or less.

In a case where the diameter X is within the above-described preferred range, the change in resistance value of the sensor electrode can be further reduced.

The above-described diameter X can be adjusted by the type, content, and content ratio of the ethylenically unsaturated compound included in the photosensitive composition layer, which will be described later, and the type of the binder polymer. In addition, the diameter X can also be adjusted by the manufacturing conditions of the manufacturing method of the touch panel sensor, which will be described later.

Transfer Film

The transfer film preferably used for forming the protective film of the touch panel sensor according to the embodiment of the present invention will be described.

The transfer film has a temporary support and a composition layer disposed on the temporary support, and the composition layer includes a photosensitive composition layer.

The above-described composition layer is not particularly limited as long as it includes the photosensitive composition layer.

The above-described photosensitive composition layer is preferably a negative tone photosensitive composition layer.

In addition, the above-described composition layer may have a single-layer configuration, or may have a configuration of two or more layers. In a case where the above-described composition layer includes a composition layer other than the photosensitive composition layer, examples of other composition layers include a thermoplastic resin layer, an interlayer, and a refractive index adjusting layer.

In addition, the transfer film may have a configuration in which a protective film is provided on the composition layer.

Examples of the embodiment of the transfer film are shown below, but the present invention is not limited thereto.

(1) “temporary support/photosensitive composition layer/refractive index adjusting layer/protective film”

(2) “temporary support/photosensitive composition layer/protective film”

(3) “temporary support/interlayer/photosensitive composition layer/protective film”

(4) “temporary support/thermoplastic resin layer/interlayer/photosensitive composition layer/protective film”

In each of the above-described configurations, the photosensitive composition layer is preferably a negative tone photosensitive composition layer. In addition, it is also preferable that the photosensitive composition layer is a colored resin layer.

As the configuration of the transfer film, for example, the configuration of (1) or (2) described above is preferable.

In the composition layer of the transfer film, in a case of a configuration in which other composition layers are further provided on a side opposite to the temporary support side of the photosensitive composition layer, the total thickness of the other layers provided on the side opposite to the temporary support side of the photosensitive composition layer is preferably 0.1% to 30% and more preferably 0.1% to 20% with respect to the thickness of the photosensitive composition layer.

From the viewpoint of suppressing generation of air bubbles in the bonding step described later, the maximum width of undulation of the transfer film is preferably 300 μm or less, more preferably 200 μm or less, and still more preferably 60 μm or less. The lower limit value of the maximum width of undulation is 0 μm or more, preferably 0.1 μm or more and more preferably 1 μm or more.

The maximum width of undulation of the transfer film is a value measured by the following procedure.

First, the transfer film is cut in a direction perpendicular to the main surface so as to have a size of 20 cm in length×20 cm in width to produce a test sample. In a case where the transfer film has a protective film, the protective film is peeled off. Next, the above-described test sample is placed on a stage having a smooth and horizontal surface so that the surface of the temporary support faces the stage. After placing, for a range of 10 cm square in the center of the test sample, the surface of the test sample is scanned with a laser microscope (for example, VK-9700SP manufactured by Keyence Corporation) to obtain a three-dimensional surface image, and the minimum concave height is subtracted from the maximum convex height observed in the obtained three-dimensional surface image. The above-described operation is performed on 10 test samples, and the arithmetic mean value thereof is defined as the “maximum width of undulation of the transfer film”.

Hereinafter, the transfer film will be described with reference to an example of the specific embodiment.

Temporary Support

The transfer film has a temporary support.

The temporary support is a member which supports the composition layer, and is finally removed by a peeling treatment.

The temporary support may be a monolayer structure or a multilayer structure.

The temporary support is preferably a film and more preferably a resin film. As the temporary support, a film which has flexibility and does not generate significant deformation, contraction, or stretching under pressure or under pressure and heating is preferable.

Examples of the above-described film include a polyethylene terephthalate film (for example, a biaxial stretching polyethylene terephthalate film), a polymethylmethacrylate film, a cellulose triacetate film, a polystyrene film, a polyimide film, and a polycarbonate film.

Among these, as the temporary support, a polyethylene terephthalate film is preferable.

In addition, it is preferable that the film used as the temporary support does not have deformation such as wrinkles or scratches.

From the viewpoint that pattern exposure through the temporary support can be performed, the temporary support preferably has high transparency, and the transmittance at 365 nm is preferably 60% or more and more preferably 70% or more.

From the viewpoint of pattern formability during pattern exposure through the temporary support and transparency of the temporary support, it is preferable that a haze of the temporary support is small. Specifically, a haze value of the temporary support is preferably 2% or less, more preferably 0.5% or less, and still more preferably 0.1% or less.

From the viewpoint of pattern formability during pattern exposure through the temporary support and transparency of the temporary support, it is preferable that the number of fine particles, foreign substances, and defects included in the temporary support is small. The number of fine particles having a diameter of 1 μm or more, foreign substances, and defects in the temporary support is preferably 50 pieces/10 mm² or less, more preferably 10 pieces/10 mm² or less, still more preferably 3 pieces/10 mm² or less, and particularly preferably 0 piece/10 mm².

A thickness of the temporary support is not particularly limited, but is preferably 5 to 200 μm. In addition, from the viewpoint of ease of handling and general-purpose properties, the thickness of the temporary support is more preferably 5 to 150 μm, still more preferably 5 to 50 μm, and most preferably 5 to 25 μm.

The thickness of the temporary support is calculated as an average value of any five points measured by a cross-sectional observation with a scanning electron microscope (SEM).

In addition, in order to improve adhesiveness between the temporary support and the composition layer, a side of the temporary support in contact with the composition layer may be surface-modified by UV irradiation, corona discharge, plasma, or the like.

In a case where the surface is modified by UV irradiation, the exposure amount is preferably 10 to 2,000 mJ/cm² and more preferably 50 to 1,000 mJ/cm².

Examples of a light source for the UV irradiation include a low pressure mercury lamp, a high pressure mercury lamp, an ultra-high pressure mercury lamp, a carbon arc lamp, a metal halide lamp, a xenon lamp, a chemical lamp, an electrodeless discharge lamp, and a light emitting diode (LED), all of which emit a light in a wavelength range of 150 to 450 nm. As long as the amount of light irradiated is within the range, the lamp output or the illuminance is not particularly limited.

Examples of the temporary support include a biaxial stretching polyethylene terephthalate film having a film thickness of 16 μm, a biaxial stretching polyethylene terephthalate film having a film thickness of 12 μm, and a biaxial stretching polyethylene terephthalate film having a film thickness of 9 μm.

A preferred aspect of the temporary support is described in, for example, paragraphs [0017] and [0018] of JP2014-085643A, paragraphs [0019] to [0026] of JP2016-027363A, paragraphs [0041] to [0057] of WO2012/081680A, and paragraphs [0029] to [0040] of WO2018/179370A, the contents of which are incorporated herein by reference.

From the viewpoint of imparting handleability, a layer (lubricant layer) including fine particles may be provided on the surface of the temporary support. The lubricant layer may be provided on one surface of the temporary support, or on both surfaces thereof. A diameter of the particles included in the lubricant layer is preferably 0.05 to 0.8 μm.

In addition, a film thickness of the lubricant layer is preferably 0.05 to 1.0 μm. Examples of a commercially available product of the temporary support include LUMIRROR 16KS40 and LUMIRROR 16FB40 (all manufactured by Toray Industries, Inc.), and COSMOSHINE A4100, COSMOSHINE A4300, and COSMOSHINE A8300 (all manufactured by TOYOBO Co., Ltd.).

Photosensitive Composition Layer

The transfer film has a photosensitive composition layer.

A pattern can be formed on the object to be transferred by transferring the photosensitive composition layer onto the object to be transferred followed by performing exposure and development.

As the photosensitive composition layer, a negative tone is preferable. Incidentally, the negative tone photosensitive composition layer is a photosensitive composition layer having a solubility in a developer which decreases by exposure to an exposed portion. In a case where the photosensitive composition layer is a negative tone photosensitive composition layer, the formed pattern corresponds to a cured layer.

Hereinafter, the components which can be included in the photosensitive composition layer will be described in detail.

Binder Polymer

The photosensitive composition layer may include a binder polymer.

Examples of the binder polymer include a (meth)acrylic resin, a styrene resin, an epoxy resin, an amide resin, an amido epoxy resin, an alkyd resin, a phenol resin, an ester resin, a urethane resin, an epoxy acrylate resin obtained by a reaction of an epoxy resin and a (meth)acrylic acid, and acid-modified epoxy acrylate resin obtained by a reaction of an epoxy acrylate resin and acid anhydride.

From the viewpoint of excellent alkali developability and film formability, examples of one suitable aspect of the binder polymer include a (meth)acrylic resin.

In the present specification, the (meth)acrylic resin means a resin having a constitutional unit derived from a (meth)acrylic compound.

The content of the constitutional unit derived from a (meth)acrylic compound is preferably 50% by mass or more, more preferably 70% by mass or more, and still more preferably 90% by mass or more with respect to all constitutional units of the (meth)acrylic resin.

The (meth)acrylic resin may be composed of only the constitutional unit derived from a (meth)acrylic compound, or may have a constitutional unit derived from a polymerizable monomer other than the (meth)acrylic compound. That is, the upper limit of the content of the constitutional unit derived from a (meth)acrylic compound is 100% by mass or less with respect to all constitutional units of the (meth)acrylic resin.

Examples of the (meth)acrylic compound include (meth)acrylic acid, (meth)acrylic acid ester, (meth)acrylamide, and (meth)acrylonitrile.

Examples of the (meth)acrylic acid ester include (meth)acrylic acid alkyl ester, (meth)acrylic acid tetrahydrofurfuryl ester, (meth)acrylic acid dimethylamino ethyl ester, (meth)acrylic acid diethylaminoethyl ester, (meth)acrylic acid glycidyl ester, (meth)acrylic acid benzyl ester, 2,2,2-trifluoroethyl (meth)acrylate, and 2,2,3,3-tetrafluoropropyl (meth)acrylate, and (meth)acrylic acid alkyl ester is preferable.

Examples of the (meth)acrylamide include acrylamides such as diacetone acrylamide.

An alkyl group of the (meth)acrylic alkyl ester may be linear or branched. Specific examples thereof include (meth)acrylic acid alkyl esters having an alkyl group having 1 to 12 carbon atoms, such as methyl (meth)acrylate, ethyl (meth)acrylate, propyl (meth)acrylate, butyl (meth)acrylate, pentyl (meth)acrylate, hexyl (meth)acrylate, heptyl (meth)acrylate, octyl (meth)acrylate, 2-ethylhexyl (meth)acrylate, nonyl (meth)acrylate, decyl (meth)acrylate, undecyl (meth)acrylate, and dodecyl (meth)acrylate.

As the (meth)acrylic acid ester, (meth)acrylic acid alkyl ester having an alkyl group having 1 to 4 carbon atoms is preferable, and methyl (meth)acrylate or ethyl (meth)acrylate is more preferable.

The (meth)acrylic resin may have a constitutional unit other than the constitutional unit derived from a (meth)acrylic compound.

The polymerizable monomer forming the above-described constitutional unit is not particularly limited as long as it is a compound other than the (meth)acrylic compound, which can be copolymerized with the (meth)acrylic compound, and examples thereof include styrene compounds which may have a substituent at an α-position or an aromatic ring, such as styrene, vinyltoluene, and α-methylstyrene, vinyl alcohol esters such as acrylonitrile and vinyl-n-butyl ether, maleic acid monoesters such as maleic acid, maleic acid anhydride, monomethyl maleate, monoethyl maleate, and monoisopropyl maleate, fumaric acid, cinnamic acid, α-cyanocinnamic acid, itaconic acid, and crotonic acid.

These polymerizable monomers may be used alone or in combination of two or more kinds thereof.

In addition, from the viewpoint of improving alkali developability, the (meth)acrylic resin preferably has a constitutional unit having an acid group. Examples of the acid group include a carboxy group, a sulfo group, a phosphoric acid group, and a phosphonic acid group.

Among these, the (meth)acrylic resin more preferably has a constitutional unit having a carboxy group, and still more preferably has a constitutional unit derived from the above-described (meth)acrylic acid.

From the viewpoint of excellent developability, the content of the constitutional unit having an acid group (preferably, the constitutional unit derived from (meth)acrylic acid) in the (meth)acrylic resin is preferably 10% by mass or more with respect to the total mass of the (meth)acrylic resin. In addition, the upper limit value thereof is not particularly limited, but from the viewpoint of excellent alkali resistance, is preferably 50% by mass or less and more preferably 40% by mass or less.

In addition, it is more preferable that the (meth)acrylic resin has a constitutional unit derived from the above-described (meth)acrylic acid alkyl ester.

In a case of having a constitutional unit derived from the (meth)acrylic acid alkyl ester, a content of the constitutional unit derived from (meth)acrylic acid alkyl ester in the (meth)acrylic resin is preferably 1% to 90% by mass, more preferably 1% to 50% by mass, and still more preferably 1% to 30% by mass with respect to all constitutional units of the (meth)acrylic resin.

As the (meth)acrylic resin, a resin having both the constitutional unit derived from (meth)acrylic acid and the constitutional unit derived from (meth)acrylic acid alkyl ester is preferable, and a resin composed only of the constitutional unit derived from (meth)acrylic acid and the constitutional unit derived from (meth)acrylic acid alkyl ester is more preferable.

In addition, as the (meth)acrylic resin, an acrylic resin which has a constitutional unit derived from methacrylic acid, a constitutional unit derived from methyl methacrylate, and a constitutional unit derived from ethyl acrylate is also preferable.

In addition, from the viewpoint that the effects of the present invention are more excellent, the (meth)acrylic resin preferably has at least one selected from the group consisting of a constitutional unit derived from methacrylic acid and a constitutional unit derived from methacrylic acid alkyl ester, and more preferably has both the constitutional unit derived from methacrylic acid and the constitutional unit derived from methacrylic acid alkyl ester.

From the viewpoint that the effects of the present invention are more excellent, the total content of the constitutional unit derived from methacrylic acid and the constitutional unit derived from methacrylic acid alkyl ester in the (meth)acrylic resin is preferably 40% by mass or more and more preferably 60% by mass or more with respect to all constitutional units of the (meth)acrylic resin. The upper limit is not particularly limited, and may be 100% by mass or less, preferably 80% by mass or less.

In addition, from the viewpoint that the effects of the present invention are more excellent, it is also preferable that the (meth)acrylic resin has at least one selected from the group consisting of a constitutional unit derived from methacrylic acid and a constitutional unit derived from methacrylic acid alkyl ester, and has at least one selected from the group consisting of a constitutional unit derived from acrylic acid and a constitutional unit derived from acrylic acid alkyl ester.

From the viewpoint that the effects of the present invention are more excellent, the total content of the constitutional unit derived from methacrylic acid and the constitutional unit derived from methacrylic acid alkyl ester is preferably 60/40 to 80/20 in terms of mass ratio with respect to the total content of the constitutional unit derived from acrylic acid and the constitutional unit derived from acrylic acid alkyl ester.

From the viewpoint of excellent developability of the photosensitive composition layer after transfer, the (meth)acrylic resin preferably has an ester group at the terminal.

The terminal portion of the (meth)acrylic resin is composed of a site derived from a polymerization initiator used in the synthesis. The (meth)acrylic resin having an ester group at the terminal can be synthesized by using a polymerization initiator which generates a radical having an ester group.

In addition, examples of other suitable aspects of the binder polymer include an alkali-soluble resin.

From the viewpoint of developability, for example, the binder polymer is preferably a binder polymer having an acid value of 60 mgKOH/g or more.

In addition, from the viewpoint that it is easy to form a strong film by thermally crosslinking with a crosslinking component by heating, for example, the binder polymer is more preferably a resin (so-called a carboxy group-containing resin) having an acid value of 60 mgKOH/g or more and having a carboxy group, and still more preferably a (meth)acrylic resin (so-called a carboxy group-containing (meth)acrylic resin) having an acid value of 60 mgKOH/g or more and having a carboxy group.

In a case where the binder polymer is a resin having a carboxy group, for example, the three-dimensional crosslinking density can be increased by adding a thermal crosslinking compound such as a blocked isocyanate compound and thermally crosslinking In addition, in a case where the carboxy group of the resin having a carboxy group is anhydrous and hydrophobized, wet heat resistance can be improved.

The carboxy group-containing (meth)acrylic resin having an acid value of 60 mgKOH/g or more is not particularly limited as long as the above-described conditions of acid value are satisfied, and a known (meth)acrylic resin can be appropriately selected.

For example, a carboxy group-containing acrylic resin having an acid value of 60 mgKOH/g or more among polymers described in paragraph [0025] of JP2011-095716A, a carboxy group-containing acrylic resin having an acid value of 60 mgKOH/g or more among polymers described in paragraphs [0033] to [0052] of JP2010-237589A, and the like can be preferably used.

Examples of other suitable aspects of the binder polymer include a styrene-acrylic copolymer.

In the present specification, the styrene-acrylic copolymer refers to a resin having a constitutional unit derived from a styrene compound and a constitutional unit derived from a (meth)acrylic compound, and the total content of the constitutional unit derived from a styrene compound and the constitutional unit derived from a (meth)acrylic compound is preferably 30% by mass or more and more preferably 50% by mass or more with respect to all constitutional units of the copolymer.

In addition, the content of the constitutional unit derived from a styrene compound is preferably 1% by mass or more, more preferably 5% by mass or more, and still more preferably 5% to 80% by mass with respect to the all constitutional units of the above-described copolymer.

In addition, the content of the constitutional unit derived from the above-described (meth)acrylic compound is preferably 5% by mass or more, more preferably 10% by mass or more, and still more preferably 20% by mass to 95% by mass with respect to the all constitutional units of the above-described copolymer.

From the viewpoint that the effects of the present invention are more excellent, the binder polymer preferably has an aromatic ring structure, and more preferably has a constitutional unit having an aromatic ring structure.

Examples of a monomer forming the constitutional unit having an aromatic ring structure include a monomer having an aralkyl group, styrene, and a polymerizable styrene derivative (for example, methylstyrene, vinyltoluene, tert-butoxystyrene, acetoxystyrene, 4-vinylbenzoic acid, styrene dimer, and styrene trimer). Among these, a monomer having an aralkyl group or styrene is preferable. Examples of the aralkyl group include a substituted or unsubstituted phenylalkyl group (excluding a benzyl group), and a substituted or unsubstituted benzyl group, and a substituted or unsubstituted benzyl group is preferable.

Examples of a monomer having the phenylalkyl group include phenylethyl (meth)acrylate.

Examples of a monomer having the benzyl group include (meth)acrylates having a benzyl group, such as benzyl (meth)acrylate and chlorobenzyl (meth)acrylate; and vinyl monomers having a benzyl group, such as vinylbenzyl chloride and vinylbenzyl alcohol. Among these, benzyl (meth)acrylate is preferable.

In addition, from the viewpoint that the effects of the present invention are more excellent, the binder polymer more preferably has a constitutional unit represented by Formula (S) (constitutional unit derived from styrene).

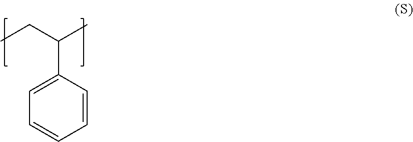

In a case where the binder polymer has the constitutional unit having an aromatic ring structure, from the viewpoint that the effects of the present invention are more excellent, the content of the constitutional unit having an aromatic ring structure is preferably 5% to 90% by mass, more preferably 10% to 70% by mass, and still more preferably 20% to 60% by mass with respect to the all constitutional units of the binder polymer.

In addition, from the viewpoint that the effects of the present invention are more excellent, the content of the constitutional unit having an aromatic ring structure in the binder polymer is preferably 5 to 70 mol %, more preferably 10 to 60 mol %, and still more preferably 20 to 60 mol % with respect to all constitutional units of the binder polymer.

Further, from the viewpoint that the effects of the present invention are more excellent, the content of the constitutional unit represented by Formula (S) in the binder polymer is preferably 5 to 70 mol %, more preferably 10 to 60 mol %, still more preferably 20 to 60 mol %, and particularly preferably 20 to 50 mol % with respect to all constitutional units of the binder polymer.

In the present specification, in a case where the content of a “constitutional unit” is defined by a molar ratio, the “constitutional unit” is synonymous with the “monomer unit”. In addition, in the present specification, the “monomer unit” may be modified after polymerization by a polymer reaction or the like. The same applies to the following.

From the viewpoint that the effects of the present invention are more excellent, the binder polymer preferably has an aliphatic hydrocarbon ring structure. That is, the binder polymer preferably has a constitutional unit having an aliphatic hydrocarbon ring structure. The aliphatic hydrocarbon ring structure may be monocyclic or polycyclic. Among these, the binder polymer more preferably has a ring structure in which two or more aliphatic hydrocarbon rings are fused.

Examples of a ring constituting the aliphatic hydrocarbon ring structure in the constitutional unit having an aliphatic hydrocarbon ring structure include a tricyclodecane ring, a cyclohexane ring, a cyclopentane ring, a norbornane ring, and an isophorone ring.

Among these, from the viewpoint that the effects of the present invention are more excellent, a ring in which two or more aliphatic hydrocarbon rings are fused is preferable, and a tetrahydrodicyclopentadiene ring (tricyclo[5.2.1.0^{2,6}]decane ring) is more preferable.

Examples of a monomer forming the constitutional unit having an aliphatic hydrocarbon ring structure include dicyclopentanyl (meth)acrylate, cyclohexyl (meth)acrylate, and isobornyl (meth)acrylate.

In addition, from the viewpoint that the effects of the present invention are more excellent, the binder polymer more preferably has a constitutional unit represented by Formula (Cy), and still more preferably has the constitutional unit represented by Formula (S) and the constitutional unit represented by Formula (Cy).

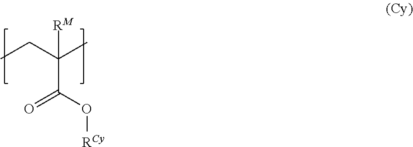

In Formula (Cy), R^{M} represents a hydrogen atom or a methyl group, and R^{Cy} represents a monovalent group having an aliphatic hydrocarbon ring structure.

R^{M} in Formula (Cy) is preferably a methyl group.

From the viewpoint that the effects of the present invention are more excellent, R^{Cy} in Formula (Cy) is preferably a monovalent group having an aliphatic hydrocarbon ring structure having 5 to 20 carbon atoms, more preferably a monovalent group having an aliphatic hydrocarbon ring structure having 6 to 16 carbon atoms, and still more preferably a monovalent group having an aliphatic hydrocarbon ring structure having 8 to 14 carbon atoms.

In addition, from the viewpoint that the effects of the present invention are more excellent, the aliphatic hydrocarbon ring structure in R^{Cy} of Formula (Cy) is preferably a cyclopentane ring structure, a cyclohexane ring structure, a tetrahydrodicyclopentadiene ring structure, a norbornane ring structure, or an isophorone ring structure, more preferably a cyclohexane ring structure or a tetrahydrodicyclopentadiene ring structure, and still more preferably a tetrahydrodicyclopentadiene ring structure.

Further, from the viewpoint that the effects of the present invention are more excellent, the aliphatic hydrocarbon ring structure in R^{Cy} of Formula (Cy) is preferably a ring structure in which two or more aliphatic hydrocarbon rings are fused, and more preferably a ring in which two to four aliphatic hydrocarbon rings are fused.

Further, from the viewpoint that the effects of the present invention are more excellent, R^{Cy} in Formula (Cy) is preferably a group in which the oxygen atom in —C(═O)O— of Formula (Cy) and the aliphatic hydrocarbon ring structure are directly bonded, that is, an aliphatic hydrocarbon ring group, more preferably a cyclohexyl group or a dicyclopentanyl group, and still more preferably a dicyclopentanyl group.

The binder polymer may have one constitutional unit having an aliphatic hydrocarbon ring structure alone, or two or more kinds thereof.

In a case where the binder polymer has the constitutional unit having an aliphatic hydrocarbon ring structure, from the viewpoint that the effects of the present invention are more excellent, the content of the constitutional unit having an aliphatic hydrocarbon ring structure is preferably 5% to 90% by mass, more preferably 10% to 80% by mass, and still more preferably 20% to 70% by mass with respect to the all constitutional units of the binder polymer.

In addition, from the viewpoint that the effects of the present invention are more excellent, the content of the constitutional unit having an aliphatic hydrocarbon ring structure in the binder polymer is preferably 5 to 70 mol %, more preferably 10 to 60 mol %, and still more preferably 20 to 50 mol % with respect to all constitutional units of the binder polymer.

Further, from the viewpoint that the effects of the present invention are more excellent, the content of the constitutional unit represented by Formula (Cy) in the binder polymer is preferably 5 to 70 mol %, more preferably 10 to 60 mol %, and still more preferably 20 to 50 mol % with respect to all constitutional units of the binder polymer.

In a case where the binder polymer includes the constitutional unit having an aromatic ring structure and the constitutional unit having an aliphatic hydrocarbon ring structure, from the viewpoint that the effects of the present invention are more excellent, the total content of the constitutional unit having an aromatic ring structure and the constitutional unit having an aliphatic hydrocarbon ring structure is preferably 10% to 90% by mass, more preferably 20% to 80% by mass, and still more preferably 40% to 75% by mass with respect to all constitutional units of the binder polymer.

In addition, from the viewpoint that the effects of the present invention are more excellent, the total content of the constitutional unit having an aromatic ring structure and the constitutional unit having an aliphatic hydrocarbon ring structure in the binder polymer is preferably 10 to 80 mol %, more preferably 20 to 70 mol %, and still more preferably 40 to 60 mol % with respect to all constitutional units of the binder polymer.

Further, from the viewpoint that the effects of the present invention are more excellent, the total content of the constitutional unit represented by Formula (S) and the constitutional unit represented by Formula (Cy) in the binder polymer is preferably 10 to 80 mol %, more preferably 20 to 70 mol %, and still more preferably 40 to 60 mol % with respect to all constitutional units of the binder polymer.

In addition, from the viewpoint that the effects of the present invention are more excellent, a molar amount nS of the constitutional unit represented by Formula (S) and a molar amount nCy of the constitutional unit represented by Formula (Cy) in the binder polymer preferably satisfy the relationship shown in the following expression (SCy), more preferably satisfy the following expression (SCy-1), and still more preferably satisfy the following expression (SCy-2).

0.2≤nS/(nS+nCy)≤0.8 Expression (SCy)

0.30≤nS/(nS+nCy)≤0.75 Expression (SCy-1)

0.40≤nS/(nS+nCy)≤0.70 Expression (SCy-2)

From the viewpoint that the effects of the present invention are more excellent, the binder polymer preferably has a constitutional unit having an acid group.

Examples of the above-described acid group include a carboxy group, a sulfo group, a phosphonic acid group, and a phosphoric acid group, and a carboxy group is preferable.

As the above-described constitutional unit having an acid group, constitutional units derived from (meth)acrylic acid, which are shown below, is preferable, and a constitutional unit derived from methacrylic acid is more preferable.

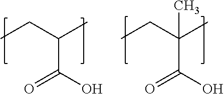

The binder polymer may have one constitutional unit having an acid group alone, or two or more kinds thereof.

In a case where the binder polymer has the constitutional unit having an acid group, from the viewpoint that the effects of the present invention are more excellent, the content of the constitutional unit having an acid group is preferably 5% to 50% by mass, more preferably 5% to 40% by mass, and still more preferably 10% to 30% by mass with respect to the all constitutional units of the binder polymer.

In addition, from the viewpoint that the effects of the present invention are more excellent, the content of the constitutional unit having an acid group in the binder polymer is preferably 5 to 70 mol %, more preferably 10 to 50 mol %, and still more preferably 20 to 40 mol % with respect to all constitutional units of the binder polymer.

Further, from the viewpoint that the effects of the present invention are more excellent, the content of the constitutional unit derived from (meth)acrylic acid in the binder polymer is preferably 5 to 70 mol %, more preferably 10 to 50 mol %, and still more preferably 20 to 40 mol % with respect to all constitutional units of the binder polymer.

From the viewpoint that the effects of the present invention are more excellent, the binder polymer preferably has a reactive group, and more preferably has a constitutional unit having a reactive group.

As the reactive group, a radically polymerizable group is preferable, and an ethylenically unsaturated group is more preferable. In addition, in a case where the binder polymer has an ethylenically unsaturated group, the binder polymer preferably has a constitutional unit having an ethylenically unsaturated group in the side chain. That is, as the binder polymer, a binder polymer having an ethylenically unsaturated group in the side chain is preferable.

In the present specification, the “main chain” represents a relatively longest binding chain in a molecule of a polymer compound constituting a resin, and the “side chain” represents an atomic group branched from the main chain.

As the ethylenically unsaturated group, an allyl group or a (meth)acryloxy group is more preferable.

Examples of the constitutional unit having a reactive group include those shown below, but the constitutional unit having a reactive group is not limited thereto.

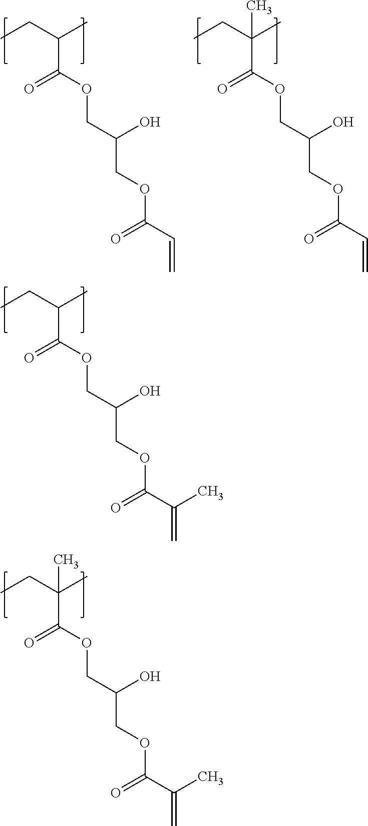

The binder polymer may have one constitutional unit having a reactive group alone, or two or more kinds thereof.

In a case where the binder polymer has the constitutional unit having a reactive group, from the viewpoint that the effects of the present invention are more excellent, the content of the constitutional unit having a reactive group is preferably 5% to 70% by mass, more preferably 10% to 50% by mass, and still more preferably 20% to 40% by mass with respect to the all constitutional units of the binder polymer.

In addition, from the viewpoint that the effects of the present invention are more excellent, the content of the constitutional unit having a reactive group in the binder polymer is preferably 5 to 70 mol %, more preferably 10 to 60 mol %, and still more preferably 20 to 50 mol % with respect to all constitutional units of the binder polymer.

Examples of a method for introducing the reactive group into the binder polymer include a method of reacting a compound such as an epoxy compound, a blocked isocyanate compound, an isocyanate compound, a vinyl sulfone compound, an aldehyde compound, a methylol compound, and a carboxylic acid anhydride with a functional group such as a hydroxy group, a carboxy group, a primary amino group, a secondary amino group, an acetoacetyl group, and a sulfo group.

Preferred examples of the method for introducing the reactive group into the binder polymer include a method in which a polymer having a carboxy group is synthesized by a polymerization reaction, and then a glycidyl (meth)acrylate is reacted with a part of the carboxy group of the obtained polymer by a polymer reaction, thereby introducing a (meth)acryloxy group into the polymer. By this method, a binder polymer having a (meth)acryloxy group in the side chain can be obtained.

The above-described polymerization reaction is preferably carried out under a temperature condition of 70° C. to 100° C., and more preferably carried out under a temperature condition of 80° C. to 90° C. As a polymerization initiator used in the above-described polymerization reaction, an azo-based initiator is preferable, and for example, V-601 (product name) or V-65 (product name) manufactured by FUJIFILM Wako Pure Chemical Corporation is more preferable. The above-described polymer reaction is preferably carried out under a temperature condition of 80° C. to 110° C. In the above-described polymer reaction, it is preferable to use a catalyst such as an ammonium salt.

The binder polymer may be a polymer shown below. Content ratios (a to d) and weight-average molecular weights Mw of each of the constitutional units shown below can be appropriately changed according to the purpose.

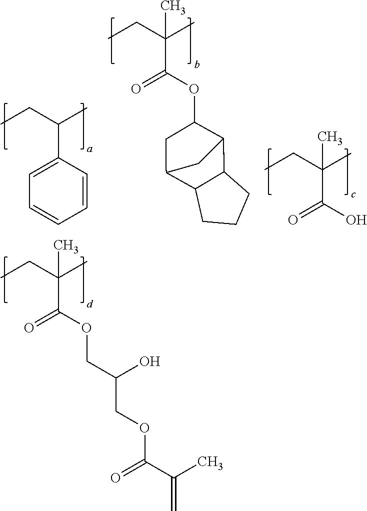

a to d in the above-described binder polymer are respectively preferably a: 20 to 60 wt %, b: 10 to 50 wt %, c: 5.0 to 25 wt %, and d: 10 to 50 wt %.

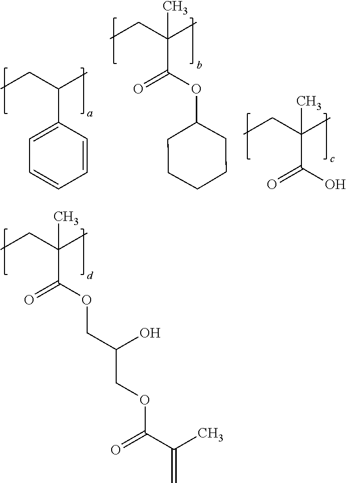

a to d in the above-described binder polymer are respectively preferably a: 20 to 60 wt %, b: 10 to 50 wt %, c: 5.0 to 25 wt %, and d: 10 to 50 wt %.

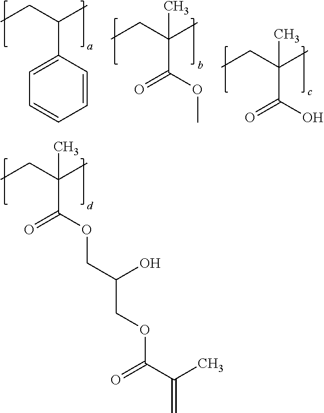

a to d in the above-described binder polymer are respectively preferably a: 30 to 65 wt %, b: 1.0 to 20 wt %, c: 5.0 to 25 wt %, and d: 10 to 50 wt %.

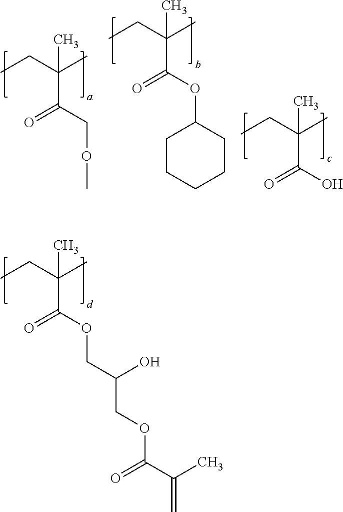

a to d in the above-described binder polymer are respectively preferably a: 1.0 to 20 wt %, b: 20 to 60 wt %, c: 5.0 to 25 wt %, and d: 10 to 50 wt %.

In addition, the binder polymer may include a polymer (hereinafter, also referred to as a “polymer X”) having a constitutional unit having a carboxylic acid anhydride structure.

The carboxylic acid anhydride structure may be either a chain carboxylic acid anhydride structure or a cyclic carboxylic acid anhydride structure, and a cyclic carboxylic acid anhydride structure is preferable.

The ring of the cyclic carboxylic acid anhydride structure is preferably a 5- to 7-membered ring, more preferably a 5-membered ring or a 6-membered ring, and still more preferably a 5-membered ring.

The constitutional unit having a carboxylic acid anhydride structure is preferably a constitutional unit containing a divalent group obtained by removing two hydrogen atoms from a compound represented by Formula P-1 in a main chain, or a constitutional unit in which a monovalent group obtained by removing one hydrogen atom from a compound represented by Formula P-1 is bonded to the main chain directly or through a divalent linking group.

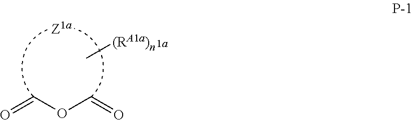

In Formula P-1, R^{A1a} represents a substituent, n^{1a} pieces of R^{A1a}'s may be the same or different, Z^{1a} represents a divalent group forming a ring including —C(═O)—O—C(═O)—, and n^{1a} represents an integer of 0 or more.

Examples of the substituent represented by R^{A1a} include an alkyl group.

Z^{1a} is preferably an alkylene group having 2 to 4 carbon atoms, more preferably an alkylene group having 2 or 3 carbon atoms, and still more preferably an alkylene group having 2 carbon atoms.

n^{1a} represents an integer of 0 or more. In a case where Z^{1a} represents an alkylene group having 2 to 4 carbon atoms, n^{1a} is preferably an integer of 0 to 4, more preferably an integer of 0 to 2, and still more preferably 0.

In a case where n^{1a} represents an integer of 2 or more, a plurality of R^{A1a}'s existing may be the same or different. In addition, the plurality of R^{A1a}'s existing may be bonded to each other to form a ring, but it is preferable that they are not bonded to each other to form a ring.

As the constitutional unit having a carboxylic acid anhydride structure, a constitutional unit derived from an unsaturated carboxylic acid anhydride is preferable, a constitutional unit derived from an unsaturated cyclic carboxylic acid anhydride is more preferable, a constitutional unit derived from an unsaturated aliphatic carboxylic acid anhydride is still more preferable, a constitutional unit derived from maleic anhydride or itaconic anhydride is particularly preferable, and a constitutional unit derived from maleic acid anhydride is most preferable.

Hereinafter, specific examples of the constitutional unit having a carboxylic acid anhydride structure will be described, but the constitutional unit having a carboxylic acid anhydride structure is not limited to these specific examples. In the following constitutional units, Rx represents a hydrogen atom, a methyl group, a CH₂OH group, or a CF₃ group, and Me represents a methyl group.

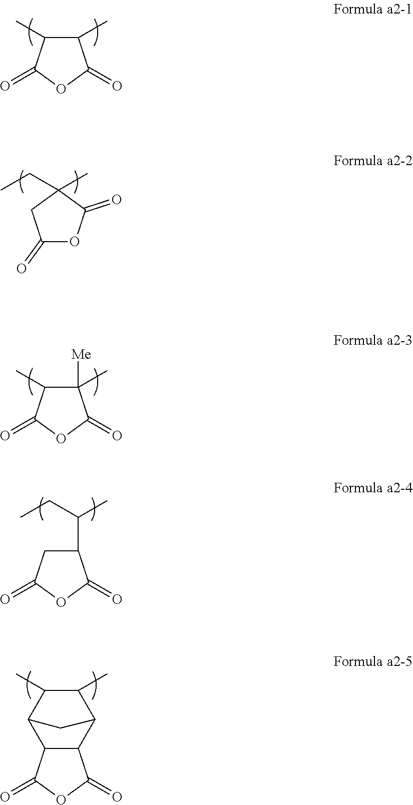

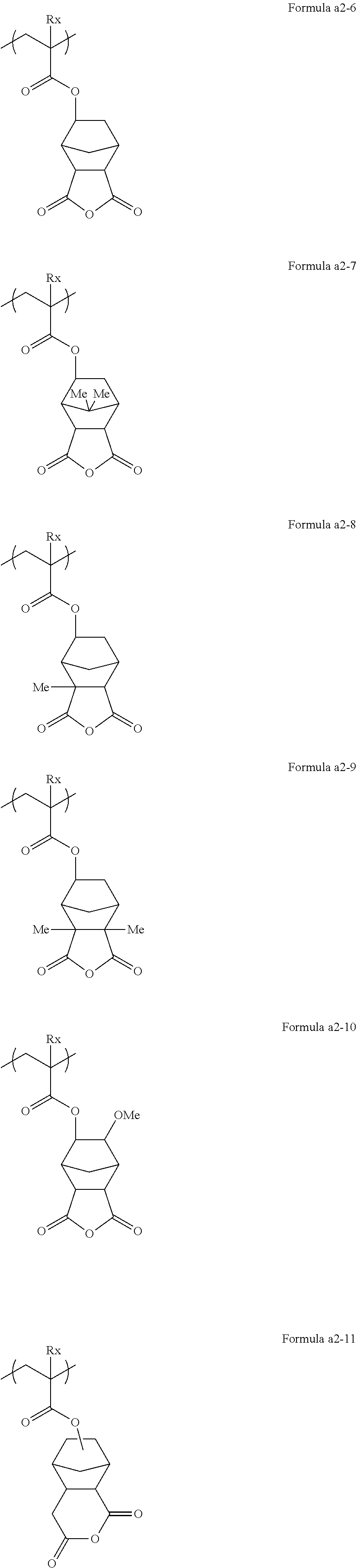

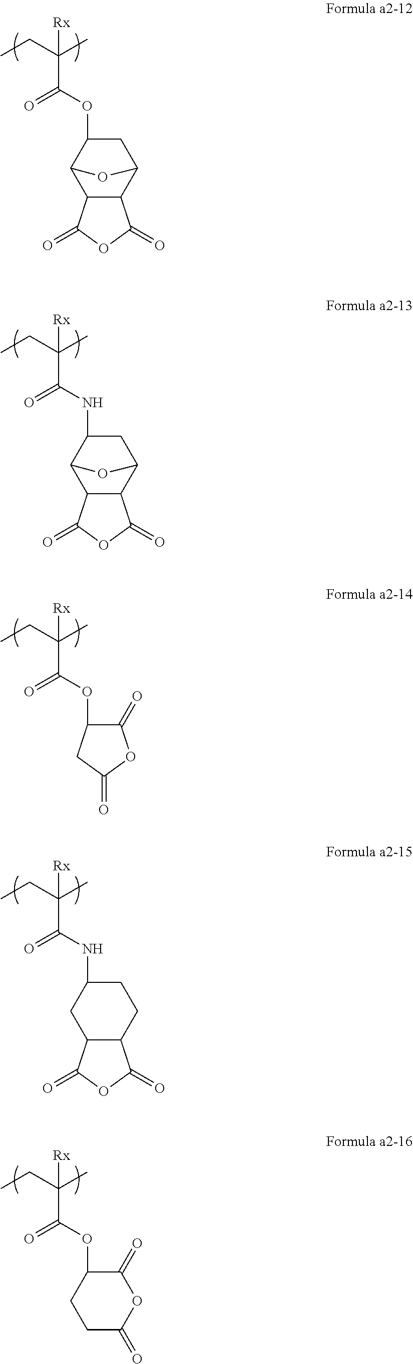

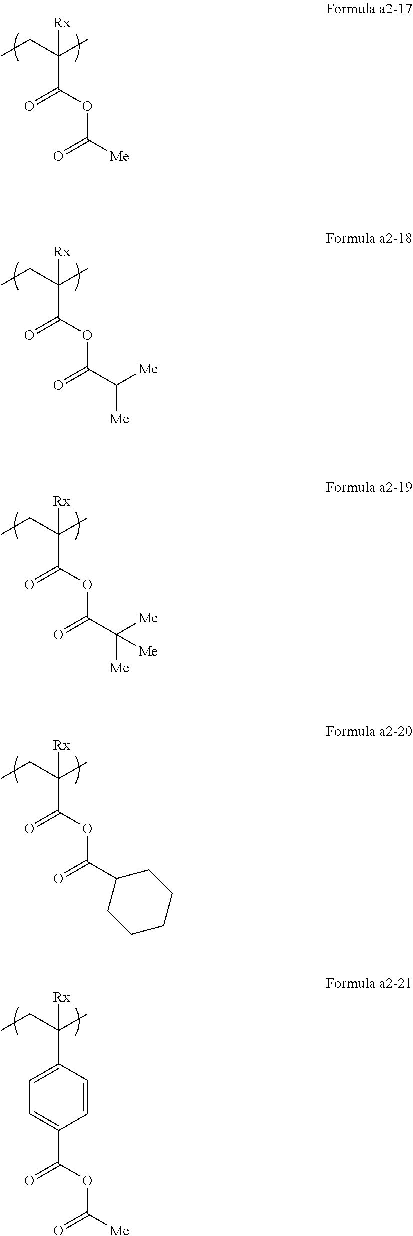

The polymer X may have one constitutional unit having a carboxylic acid anhydride structure alone, or two or more kinds thereof.

The total content of the constitutional unit having a carboxylic acid anhydride structure is preferably 0 to 60 mol %, more preferably 5 to 40 mol %, and still more preferably 10 to 35 mol % with respect to all constitutional units of the polymer X.

The photosensitive composition layer may include only one kind of the polymer X, or may include two or more kinds thereof.

In a case where the photosensitive composition layer includes the polymer X, from the viewpoint that the effects of the present invention are more excellent, the content of the polymer X is preferably 0.1% to 30% by mass, more preferably 0.2% to 20% by mass, still more preferably 0.5% to 20% by mass, and particularly preferably 1% to 20% by mass with respect to the total mass of the photosensitive composition layer.

From the viewpoint that the effects of the present invention are more excellent, a weight-average molecular weight (Mw) of the binder polymer is preferably 5,000 or more, more preferably 10,000 or more, still more preferably 10,000 to 50,000, and particularly preferably 15,000 to 30,000.

An acid value of the binder polymer is preferably 10 to 200 mgKOH/g, more preferably 60 to 200 mgKOH/g, still more preferably 60 to 150 mgKOH/g, and particularly preferably 70 to 130 mgKOH/g.

The acid value of the binder polymer is a value measured according to the method described in JIS K0070: 1992. From the viewpoint of developability, a dispersity of the binder polymer is preferably 1.0 to 6.0, more preferably 1.0 to 5.0, still more preferably 1.0 to 4.0, and particularly preferably 1.0 to 3.0.

The photosensitive composition layer may include only one kind of the binder polymer, or may include two or more kinds thereof.

From the viewpoint that the effects of the present invention are more excellent, a content of the binder polymer is preferably 10% to 90% by mass, more preferably 20% to 80% by mass, and still more preferably 30% to 70% by mass with respect to the total mass of the photosensitive composition layer.

Compound having Ethylenically Unsaturated Group

The photosensitive composition layer may include a compound having an ethylenically unsaturated group (hereinafter, also simply referred to as an “ethylenically unsaturated compound”).

As the ethylenically unsaturated group, a (meth)acryloxy group is preferable.

The ethylenically unsaturated compound in the present specification is a compound other than the above-described binder polymer, and preferably has a molecular weight of less than 5,000.

Examples of one suitable aspect of the ethylenically unsaturated compound include a compound represented by Formula (M) (simply referred to as a “compound M”).

Q²-R¹-Q¹ Formula (M)

In Formula (M), Q¹ and Q² each independently represent a (meth)acryloyloxy group, and R¹ represents a divalent linking group having a chain structure.

From the viewpoint of easiness of synthesis, Q¹ and Q² in Formula (M) preferably have the same group.

In addition, from the viewpoint of reactivity, Q¹ and Q² in Formula (M) are preferably acryloyloxy groups.

From the viewpoint that the effects of the present invention are more excellent, R¹ in Formula (M) is preferably an alkylene group, an alkyleneoxyalkylene group (-L¹-O-L¹-), or a polyalkyleneoxyalkylene group (-(L¹-O)ₚ-L¹-), more preferably a hydrocarbon group having 2 to 20 carbon atoms or a polyalkyleneoxyalkylene group, still more preferably an alkylene group having 4 to 20 carbon atoms, and particularly preferably a linear alkylene group having 6 to 18 carbon atoms.

It is sufficient that the above-described hydrocarbon group has a chain structure at least in part, and a portion other than the chain structure is not particularly limited. For example, the portion may be a branched chain, a cyclic or a linear alkylene group having 1 to 5 carbon atoms, an arylene group, an ether bond, or a combination thereof, and an alkylene group or a group in which two or more alkylene groups and one or more arylene groups are combined is preferable, an alkylene group is more preferable, and a linear alkylene group is still more preferable.

The above-described L¹'s each independently represent an alkylene group, and an ethylene group, a propylene group, or a butylene group is preferable and an ethylene group or a 1,2-propylene group is more preferable. p represents an integer of 2 or more, and is preferably an integer of 2 to 10.

In addition, from the viewpoint that the effects of the present invention are more excellent, the number of atoms in the shortest linking chain which links Q¹ and Q² in the compound M is preferably 3 to 50, more preferably 4 to 40, still more preferably 6 to 20, and particularly preferably 8 to 12.

In the present specification, the “number of atoms in the shortest linking chain which links Q¹ and Q²” is the shortest number of atoms linking from an atom in R¹ linked to Q¹ to an atom in R¹ linked to Q².

Specific examples of the compound M include 1,3-butanediol di(meth)acrylate, tetramethylene glycol di(meth)acrylate, neopentyl glycol di(meth)acrylate, 1,6-hexanediol di(meth)acrylate, 1,7-heptanediol di(meth)acrylate, 1,8-octanediol di(meth)acrylate, 1,9-nonanediol di(meth)acrylate, 1,10-decanediol di(meth)acrylate, hydrogenated bisphenol A di(meth)acrylate, hydrogenated bisphenol F di(meth)acrylate, polyethylene glycol di(meth)acrylate, polypropylene glycol di(meth)acrylate, poly (ethylene glycol/propylene glycol) di(meth)acrylate, and polybutylene glycol di(meth)acrylate. The above-described ester monomers can also be used as a mixture.

Among the above-described compounds, from the viewpoint that the effects of the present invention are more excellent, at least one compound selected from the group consisting of 1,6-hexanediol di(meth)acrylate, 1,9-nonanediol di(meth)acrylate, 1,10-decanediol di(meth)acrylate, and neopentyl glycol di(meth)acrylate is preferable, at least one compound selected from the group consisting of 1,6-hexanediol di(meth)acrylate, 1,9-nonanediol di(meth)acrylate, and 1,10-decanediol di(meth)acrylate is more preferable, and at least one compound selected from the group consisting of 1,9-nonanediol di(meth)acrylate and 1,10-decanediol di(meth)acrylate is still more preferable.

In addition, examples of one suitable aspect of the ethylenically unsaturated compound include a bi- or higher functional ethylenically unsaturated compound.

In the present specification, the “bi- or higher functional ethylenically unsaturated compound” means a compound having two or more ethylenically unsaturated groups in one molecule.

As the ethylenically unsaturated group in the ethylenically unsaturated compound, a (meth)acryloyl group is preferable.

As the ethylenically unsaturated compound, a (meth)acrylate compound is preferable.

The bifunctional ethylenically unsaturated compound is not particularly limited and can be appropriately selected from a known compound.

Examples of the bifunctional ethylenically unsaturated compound other than the above-described compound M include tricyclodecane dimethanol di(meth)acrylate, dioxane glycol di(meth)acrylate, and 1,4-cyclohexanediol di(meth)acrylate.

Examples of a commercially available product of the bifunctional ethylenically unsaturated compound include tricyclodecane dimethanol diacrylate (product name: NK ESTER A-DCP, manufactured by Shin-Nakamura Chemical Co., Ltd.), tricyclodecane dimethanol dimethacrylate (product name: NK ESTER DCP, manufactured by Shin-Nakamura Chemical Co., Ltd.), 1,9-nonanediol diacrylate (product name: NK ESTER A-NOD-N, manufactured by Shin-Nakamura Chemical Co., Ltd.), 1,6-hexanediol diacrylate (product name: NK ESTER A-HD-N, manufactured by Shin-Nakamura Chemical Co., Ltd.), and dioxane glycol diacrylate (KAYARAD R-604 manufactured by Nippon Kayaku Co., Ltd.).

The tri- or higher functional ethylenically unsaturated compound is not particularly limited and can be appropriately selected from a known compound.

Examples of the tri- or higher functional ethylenically unsaturated compound include dipentaerythritol (tri/tetra/penta/hexa) (meth)acrylate, pentaerythritol (tri/tetra) (meth)acrylate, trimethylolpropane tri(meth)acrylate, ditrimethylolpropane tetra(meth)acrylate, isocyanuric acid (meth)acrylate, and a (meth)acrylate compound of a glycerin tri(meth)acrylate skeleton.

Here, the “(tri/tetra/penta/hexa) (meth)acrylate” has a concept including tri(meth)acrylate, tetra(meth)acrylate, penta(meth)acrylate, and hexa(meth)acrylate, and the “(tri/tetra) (meth)acrylate” has a concept including tri(meth)acrylate and tetra(meth)acrylate.

Examples of the ethylenically unsaturated compound also include a caprolactone-modified compound of a (meth)acrylate compound (KAYARAD (registered trademark) DPCA-20 manufactured by Nippon Kayaku Co., Ltd., A-9300-1CL manufactured by Shin-Nakamura Chemical Co., Ltd., or the like), an alkylene oxide-modified compound of a (meth)acrylate compound (KAYARAD (registered trademark) RP-1040 manufactured by Nippon Kayaku Co., Ltd., ATM-35E or A-9300 manufactured by Shin-Nakamura Chemical Co., Ltd., EBECRYL (registered trademark) 135 manufactured by Daicel-Allnex Ltd., or the like), and ethoxylated glycerin triacrylate (NK ESTER A-GLY-9E manufactured by Shin-Nakamura Chemical Co., Ltd., or the like).

Examples of the ethylenically unsaturated compound also include a urethane (meth)acrylate compound.

Examples of the urethane (meth)acrylate include urethane di(meth)acrylate, and examples thereof include propylene oxide-modified urethane di(meth)acrylate and ethylene oxide and propylene oxide-modified urethane di(meth)acrylate.

In addition, examples of the urethane (meth)acrylate also include tri- or higher functional urethane (meth)acrylate. The lower limit of the number of functional groups is more preferably 6 or more and still more preferably 8 or more. The upper limit of the number of functional groups is preferably 20 or less. Examples of the tri- or higher functional urethane (meth)acrylate include 8UX-015A (manufactured by Taisei Fine Chemical Co., Ltd.), UA-32P (manufactured by Shin-Nakamura Chemical Co., Ltd.), U-15HA (manufactured by Shin-Nakamura Chemical Co., Ltd.), UA-1100H (manufactured by Shin-Nakamura Chemical Co., Ltd.), AH-600 (product name) manufactured by KYOEISHA CHEMICAL Co., LTD, UA-306H, UA-306T, UA-306I, UA-510H, and UX-5000 (all manufactured by Nippon Kayaku Co., Ltd.).

Examples of one suitable aspect of the ethylenically unsaturated compound include an ethylenically unsaturated compound having an acid group.

Examples of the acid group include a phosphoric acid group, a sulfo group, and a carboxy group.

Among these, as the acid group, a carboxy group is preferable.

Examples of the ethylenically unsaturated compound having an acid group include a tri- or tetra-functional ethylenically unsaturated compound having an acid group [component obtained by introducing a carboxy group to pentaerythritol tri- and tetra-acrylate (PETA) skeleton (acid value: 80 to 120 mgKOH/g)), and a penta- to hexa-functional ethylenically unsaturated compound having an acid group [component obtained by introducing a carboxy group to dipentaerythritol penta- and hexa-acrylate (DPHA) skeleton (acid value: 25 to 70 mgKOH/g)].

The tri- or higher functional ethylenically unsaturated compound having an acid group may be used in combination with the bifunctional ethylenically unsaturated compound having an acid group, as necessary.

As the ethylenically unsaturated compound having an acid group, at least one selected from the group consisting of bi- or higher functional ethylenically unsaturated compound having a carboxy group and a carboxylic acid anhydride thereof is preferable.

In a case where the ethylenically unsaturated compound having an acid group is at least one selected from the group consisting of bi- or higher functional ethylenically unsaturated compound having a carboxy group and a carboxylic acid anhydride thereof, developability and film hardness are further enhanced.

The bi- or higher functional ethylenically unsaturated compound having a carboxy group is not particularly limited and can be appropriately selected from a known compound.

Examples of the bi- or higher functional ethylenically unsaturated compound having a carboxy group include ARONIX (registered trademark) TO-2349 manufactured by Toagosei Co., Ltd., ARONIX (registered trademark) M-520 manufactured by Toagosei Co., Ltd., and ARONIX (registered trademark) M-510 manufactured by Toagosei Co., Ltd.

As the ethylenically unsaturated compound having an acid group, ethylenically unsaturated compounds having an acid group, which are described in paragraphs [0025] to [0030] of JP2004-239942A, are preferable, and the contents described in this publication are incorporated in the present specification.

Examples of the ethylenically unsaturated compound also include a compound obtained by reacting a polyhydric alcohol with an α,β-unsaturated carboxylic acid, a compound obtained by reacting a glycidyl group-containing compound with an α,β-unsaturated carboxylic acid, urethane monomer such as a (meth)acrylate compound having a urethane bond, phthalate compounds such as γ-chloro-β-hydroxypropyl-β′-(meth)acryloyloxyethyl-o-phthalate, β-hydroxyethyl-β′-(meth)acryloyloxyethyl-o-phthalate, and β-hydroxypropyl-β′-(meth)acryloyloxyethyl-o-phthalate, and (meth)acrylic acid alkyl esters.

These compounds may be used alone or in combination of two or more kinds thereof.

Examples of the compound obtained by reacting a polyhydric alcohol with an α,β-unsaturated carboxylic acid include bisphenol A-based (meth)acrylate compounds such as 2,2-bis(4-((meth)acryloxypolyethoxy)phenyl)propane, 2,2-bis(4-((meth)acryloxypolypropoxy)phenyl)propane, and 2,2-bis(4-((meth)acryloxypolyethoxypolypropoxy)phenyl)propane, polyethylene glycol di(meth)acrylate having 2 to 14 ethylene oxide groups, polypropylene glycol di(meth)acrylate having 2 to 14 propylene oxide groups, polyethylene polypropylene glycol di(meth)acrylate having 2 to 14 ethylene oxide groups and 2 to 14 propylene oxide groups, trimethylolpropane di(meth)acrylate, trimethylolpropane tri(meth)acrylate, trimethylolpropane ethoxy tri(meth)acrylate, trimethylolpropane diethoxy tri(meth)acrylate, trimethylolpropane triethoxy tri(meth)acrylate, trimethylolpropane tetraethoxy tri(meth)acrylate, trimethylolpropane pentaethoxy tri(meth)acrylate, di(trimethylolpropane) tetraacrylate, tetramethylolmethane tri(meth)acrylate, tetramethylolmethane tetra(meth)acrylate, dipentaerythritol tetra(meth)acrylate, dipentaerythritol penta(meth)acrylate, and dipentaerythritol hexa(meth)acrylate.

Among these, an ethylenically unsaturated compound having a tetramethylolmethane structure or a trimethylolpropane structure is preferable, and tetramethylolmethane tri(meth)acrylate, tetramethylolmethane tetra(meth)acrylate, trimethylolpropane tri(meth)acrylate, or di(trimethylolpropane) tetraacrylate is more preferable.

Examples of the ethylenically unsaturated compound also include a caprolactone-modified compound of ethylenically unsaturated compound (for example, KAYARAD (registered trademark) DPCA-20 manufactured by Nippon Kayaku Co., Ltd., A-9300-1CL manufactured by Shin-Nakamura Chemical Co., Ltd., and the like), an alkylene oxide-modified compound of ethylenically unsaturated compound (for example, KAYARAD RP-1040 manufactured by Nippon Kayaku Co., Ltd., ATM-35E or A-9300 manufactured by Shin-Nakamura Chemical Co., Ltd., EBECRYL (registered trademark) 135 manufactured by Daicel-Allnex Ltd., and the like), and ethoxylated glycerin triacrylate (A-GLY-9E manufactured by Shin-Nakamura Chemical Co., Ltd., and the like).

Among these, as the ethylenically unsaturated compound, from the viewpoint of excellent developability of the photosensitive composition layer after transfer, an ethylenically unsaturated compound including an ester bond is also preferable.

The ethylenically unsaturated compound including an ester bond is not particularly limited as long as it includes an ester bond in the molecule, but from the viewpoint that the effects of the present invention are excellent, an ethylenically unsaturated compound having a tetramethylolmethane structure or a trimethylolpropane structure is preferable, and tetramethylolmethane tri(meth)acrylate, tetramethylolmethane tetra(meth)acrylate, trimethylolpropane tri(meth)acrylate, or di(trimethylolpropane) tetraacrylate is more preferable.

As the ethylenically unsaturated compound, from the viewpoint of imparting reliability, it is preferable to include an ethylenically unsaturated compound having an aliphatic group having 6 to 20 carbon atoms and the above-described ethylenically unsaturated compound having a tetramethylolmethane structure or a trimethylolpropane structure.

Examples of the ethylenically unsaturated compound having an aliphatic group having 6 to 20 carbon atoms include 1,9-nonanediol di(meth)acrylate, 1,10-decanediol di(meth)acrylate, and tricyclodecane dimethanol di(meth)acrylate.

Examples of one suitable aspect of the ethylenically unsaturated compound include an ethylenically unsaturated compound (preferably, a bifunctional ethylenically unsaturated compound) having an aliphatic hydrocarbon ring structure.

As the above-described ethylenically unsaturated compound, an ethylenically unsaturated compound having a ring structure in which two or more aliphatic hydrocarbon rings are fused (preferably, a structure selected from the group consisting of a tricyclodecane structure and a tricyclodecene structure) is preferable, a bifunctional ethylenically unsaturated compound having a ring structure in which two or more aliphatic hydrocarbon rings are fused is more preferable, and tricyclodecane dimethanol di(meth)acrylate is still more preferable.

As the above-described aliphatic hydrocarbon ring structure, from the viewpoint that the effects of the present invention are more excellent, a cyclopentane structure, a cyclohexane structure, a tricyclodecane structure, a tricyclodecene structure, a norbornane structure, or an isophorone structure is preferable.

A molecular weight of the ethylenically unsaturated compound is preferably 200 to 3,000, more preferably 250 to 2,600, still more preferably 280 to 2,200, and particularly preferably 300 to 2,200.

A proportion of the content of the ethylenically unsaturated compound having a molecular weight of 300 or less to ethylenically unsaturated compounds included in the photosensitive composition layer is preferably 30% by mass or less, more preferably 25% by mass or less, and even more preferably 20% by mass or less with respect to all ethylenically unsaturated compounds included in the photosensitive composition layer.

As one suitable aspect of the photosensitive composition layer, the photosensitive composition layer preferably includes the bi- or higher functional ethylenically unsaturated compound, more preferably includes the tri- or higher functional ethylenically unsaturated compound, and still more preferably includes a tri- or tetrafunctional ethylenically unsaturated compound.

In addition, as one suitable aspect of the photosensitive composition layer, the photosensitive composition layer preferably includes the bifunctional ethylenically unsaturated compound having an aliphatic hydrocarbon ring structure and the binder polymer having the constitutional unit having an aliphatic hydrocarbon ring.

In addition, as one suitable aspect of the photosensitive composition layer, the photosensitive composition layer preferably includes the compound represented by Formula (M) and the ethylenically unsaturated compound having an acid group, more preferably includes 1,9-nonanediol diacrylate, tricyclodecane dimethanol diacrylate, and a polyfunctional ethylenically unsaturated compound having a carboxylic acid group, and still more preferably includes 1,9-nonanediol diacrylate, tricyclodecane dimethanol diacrylate, and a succinic acid-modified form of dipentaerythritol pentaacrylate.

In addition, as one suitable aspect of the photosensitive composition layer, the photosensitive composition layer preferably includes the compound represented by Formula (M), the ethylenically unsaturated compound having an acid group, and a thermal crosslinking compound described later, and more preferably includes the compound represented by Formula (M), the ethylenically unsaturated compound having an acid group, and a blocked isocyanate compound described later.

In addition, as one suitable aspect of the photosensitive composition layer, from the viewpoint of development residue inhibitory property and rust preventive property, the photosensitive composition layer preferably includes the bifunctional ethylenically unsaturated compound (preferably, a bifunctional (meth)acrylate compound) and the tri- or higher functional ethylenically unsaturated compound (preferably, a tri- or higher functional (meth)acrylate compound).

A mass ratio of a content of the bifunctional ethylenically unsaturated compound and a content of the tri- or higher functional ethylenically unsaturated compound is preferably 10:90 to 90:10 and more preferably 30:70 to 70:30.

The content of the bifunctional ethylenically unsaturated compound is preferably 20% to 80% by mass and more preferably 30% to 70% by mass with respect to the total amount of all ethylenically unsaturated compounds.

The bifunctional ethylenically unsaturated compound in the photosensitive composition layer is preferably 10% to 60% by mass and more preferably 15% to 40% by mass.

In addition, as one suitable aspect of the photosensitive composition layer, from the viewpoint of rust preventive property, the photosensitive composition layer preferably includes the compound M and the bifunctional ethylenically unsaturated compound having an aliphatic hydrocarbon ring structure.

In addition, as one suitable aspect of the photosensitive composition layer, from the viewpoint of base material adhesiveness, development residue inhibitory property, and rust preventive property, the photosensitive composition layer preferably includes the compound M and the ethylenically unsaturated compound having an acid group, more preferably includes the compound M, the bifunctional ethylenically unsaturated compound having an aliphatic hydrocarbon ring structure, and the ethylenically unsaturated compound having an acid group, still more preferably includes the compound M, the bifunctional ethylenically unsaturated compound having an aliphatic hydrocarbon ring structure, the tri- or higher functional ethylenically unsaturated compound, and the ethylenically unsaturated compound having an acid group, and particularly preferably includes the compound M, the bifunctional ethylenically unsaturated compound having an aliphatic hydrocarbon ring structure, the tri- or higher functional ethylenically unsaturated compound, the ethylenically unsaturated compound having an acid group, and the urethane (meth)acrylate compound.

In addition, as one suitable aspect of the photosensitive composition layer, from the viewpoint of base material adhesiveness, development residue inhibitory property, and rust preventive property, the photosensitive composition layer preferably includes 1,9-nonanediol diacrylate and the polyfunctional ethylenically unsaturated compound having a carboxylic acid group, more preferably includes 1,9-nonanediol diacrylate, tricyclodecane dimethanol diacrylate, and the polyfunctional ethylenically unsaturated compound having a carboxylic acid group, still more preferably includes 1,9-nonanediol diacrylate, tricyclodecane dimethanol diacrylate, dipentaerythritol hexaacrylate, and an ethylenically unsaturated compound having a carboxylic acid group, and particularly preferably includes 1,9-nonanediol diacrylate, tricyclodecane dimethanol diacrylate, an ethylenically unsaturated compound having a carboxylic acid group, and a urethane acrylate compound.

The photosensitive composition layer may include a monofunctional ethylenically unsaturated compound as the ethylenically unsaturated compound.

The content of the bi- or higher functional ethylenically unsaturated compound in the above-described ethylenically unsaturated compound is preferably 60% to 100% by mass, more preferably 80% to 100% by mass, and still more preferably 90% to 100% by mass with respect to the total content of all ethylenically unsaturated compounds included in the photosensitive composition layer.

The ethylenically unsaturated compound may be used alone or in combination of two or more kinds thereof.

Among these, from the viewpoint that the effects of the present invention are more excellent, it is preferable that the photosensitive composition layer includes a first polymerizable compound having two ethylenically unsaturated groups and a second polymerizable compound having five or more ethylenically unsaturated groups.

A content of the ethylenically unsaturated compound in the photosensitive composition layer is preferably 1% to 70% by mass, more preferably 5% to 70% by mass, still more preferably 5% to 60% by mass, and particularly preferably 5% to 50% by mass with respect to the total mass of the photosensitive composition layer.

In addition, in a case where the photosensitive composition layer includes the first polymerizable compound and the second polymerizable compound, from the viewpoint that the effects of the present invention are more excellent, a mass ratio of a content of the second polymerizable compound to a content of the first polymerizable compound is preferably 0.2 to 1.8, more preferably 0.4 to 1.3, and still more preferably 0.5 to 1.3.

Photopolymerization Initiator

The photosensitive composition layer may include a photopolymerization initiator.

The photopolymerization initiator is not particularly limited and a known photopolymerization initiator can be used.

Examples of the photopolymerization initiator include a photopolymerization initiator having an oxime ester structure (hereinafter, also referred to as an “oxime-based photopolymerization initiator”), a photopolymerization initiator having an α-aminoalkylphenone structure (hereinafter, also referred to as an “α-aminoalkylphenone-based photopolymerization initiator”), a photopolymerization initiator having an α-hydroxyalkylphenone structure (hereinafter also referred to as an “α-hydroxyalkylphenone-based photopolymerization initiator”), a photopolymerization initiator having an acylphosphine oxide structure, (hereinafter, also referred to as an “acylphosphine oxide-based photopolymerization initiator”), and a photopolymerization initiator having an N-phenylglycine structure (hereinafter, also referred to as an “N-phenylglycine-based photopolymerization initiator”).

The photopolymerization initiator preferably includes at least one kind selected from the group consisting of the oxime-based photopolymerization initiator, the α-aminoalkylphenone-based photopolymerization initiator, the α-hydroxyalkylphenone-based photopolymerization initiator, and the N-phenylglycine-based photopolymerization initiator, and more preferably includes at least one kind selected from the group consisting of the oxime-based photopolymerization initiator, the α-aminoalkylphenone-based photopolymerization initiator, and the N-phenylglycine-based photopolymerization initiator.

In addition, as the photopolymerization initiator, for example, polymerization initiators described in paragraphs [0031] to [0042] of JP2011-95716A and paragraphs [0064] to [0081] of JP2015-014783A may be used.

Examples of a commercially available product of the photopolymerization initiator include 1-[4-(phenylthio)phenyl]-1,2-octanedione-2-(O-benzoyloxime) [product name: IRGACURE (registered trademark) OXE-01, manufactured by BASF SE], 1-[9-ethyl-6-(2-methylbenzoyl)-9H-carbazol-3-yl]ethanone-1-(O-acetyloxime) [product name: IRGACURE (registered trademark) OXE-02, manufactured by BASF SE], IRGACURE (registered trademark) OXE-03 (manufactured by BASF SE), IRGACURE (registered trademark) OXE-04 (manufactured by BASF SE), 2-(dimethylamino)-2-[(4-methylphenyl)methyl]-1-[4-(4-morpholinyl)phenyl]-1-butanone [product name: Omnirad (registered trademark) 379EG, manufactured by IGM Resins B.V.], 2-methyl-1-(4-methylthiophenyl)-2-morpholinopropan-1-one [product name: Omnirad (registered trademark) 907, manufactured by IGM Resins B.V.], 2-hydroxy-1-{4-[4-(2-hydroxy-2-methylpropionyl)benzyl]phenyl}-2-methylpropan-1-one [product name: Omnirad (registered trademark) 127, manufactured by IGM Resins B.V.], 2-benzyl-2-dimethylamino-1-(4-morpholinophenyl)butanone-1 [product name: Omnirad (registered trademark) 369, manufactured by IGM Resins B.V.], 2-hydroxy-2-methyl-1-phenylpropan-1-one [product name: Omnirad (registered trademark) 1173, manufactured by IGM Resins B.V.], 1-hydroxy cyclohexyl phenyl ketone [product name: Omnirad (registered trademark) 184, manufactured by IGM Resins B.V.], 2,2-dimethoxy-1,2-diphenylethan-1-one (product name: Omnirad (registered trademark) 651, manufactured by IGM Resins B.V.], an oxime ester-based photopolymerization initiator [product name: Lunar (registered trademark) 6, manufactured by DKSH Management Ltd.], 1-[4-(phenylthio)phenyl]-3-cyclopentylpropan-1,2-dione-2-(O-benzoyloxime) (product name: TR-PBG-305, manufactured by TRONLY), 1,2-propanedione, 3-cyclohexyl-1-[9-ethyl-6-(2-furanylcarbonyl)-9H-carbazole-3-yl]-, 2-(O-acetyloxime) (product name: TR-PBG-326, manufactured by TRONLY), 3-cyclohexyl-1-(6-(2-(benzoyloxyimino)hexanoyl)-9-ethyl-9H-carbazole-3-yl)-propan-1,2-dione-2-(O-benzoyloxime) (product name: TR-PBG-391, manufactured by TRONLY), and APi-307 (1-(biphenyl-4-yl)-2-methyl-2-morpholinopropan-1-one, manufactured by Shenzhen UV-ChemTech Co., Ltd.).

The photopolymerization initiator may be used alone or in combination of two or more kinds thereof. In a case of using two or more kinds thereof, it is preferable to use at least one selected from the oxime-based photopolymerization initiator, the α-aminoalkylphenone-based photopolymerization initiator, or the α-hydroxyalkylphenone-based photopolymerization initiator.

In a case where the photosensitive composition layer includes the photopolymerization initiator, a content of the photopolymerization initiator is preferably 0.1% by mass or more, more preferably 0.5% by mass or more, and still more preferably 1.0% by mass or more with respect to the total mass of the photosensitive composition layer. In addition, the upper limit thereof is preferably 10% by mass or less and more preferably 5% by mass or less with respect to the total mass of the photosensitive composition layer.

Heterocyclic Compound

The photosensitive composition layer may include a heterocyclic compound.

A heterocyclic ring included in the heterocyclic compound may be either a monocyclic or polycyclic heterocyclic ring.

Examples of a heteroatom included in the heterocyclic compound include an oxygen atom, a nitrogen atom, and a sulfur atom. The heterocyclic compound preferably has at least one atom selected from the group consisting of a nitrogen atom, an oxygen atom, and a sulfur atom, and more preferably has a nitrogen atom.

Examples of the heterocyclic compound include a triazole compound, a benzotriazole compound, a tetrazole compound, a thiadiazole compound, a triazine compound, a rhodanine compound, a thiazole compound, a benzothiazole compound, a benzimidazole compound, a benzoxazole compound, and a pyrimidine compound.

Among the above-described compounds, the heterocyclic compound is preferably at least one compound selected from the group consisting of a triazole compound, a benzotriazole compound, a tetrazole compound, a thiadiazole compound, a triazine compound, a rhodanine compound, a thiazole compound, a benzimidazole compounds, and a benzoxazole compound, and more preferably at least one compound selected from the group consisting of a triazole compound, a benzotriazole compound, a tetrazole compound, a thiadiazole compound, a thiazole compound, a benzothiazole compound, a benzimidazole compound, and a benzoxazole compound.

Preferred specific examples of the heterocyclic compound are shown below. Examples of the triazole compound and the benzotriazole compound include the following compounds.

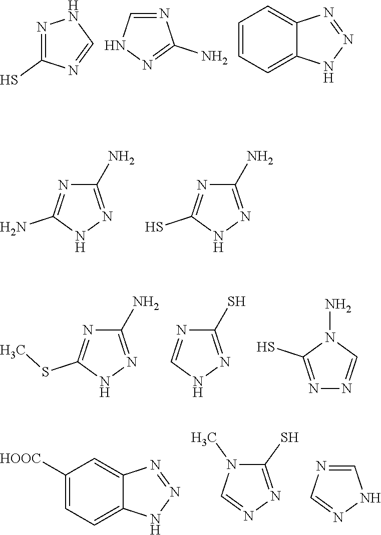

Examples of the tetrazole compound include the following compounds.

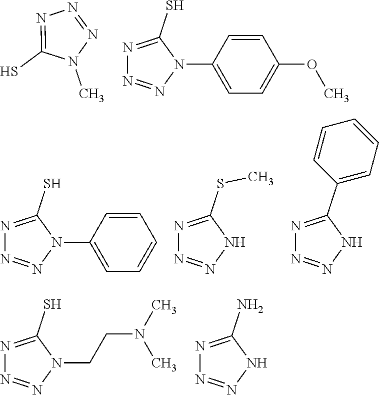

Examples of the thiadiazole compound include the following compounds.

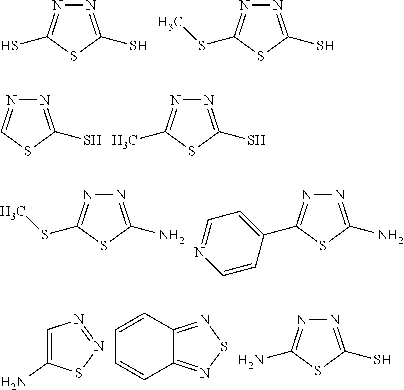

Examples of the triazine compound include the following compounds.

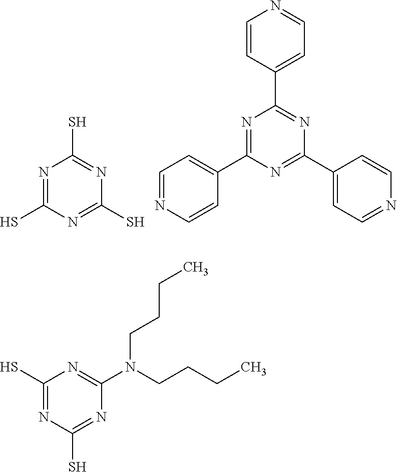

Examples of the rhodanine compound include the following compounds.

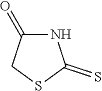

Examples of the thiazole compound include the following compounds.

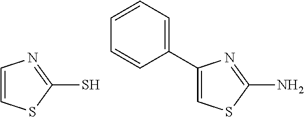

Examples of the benzothiazole compound include the following compounds.

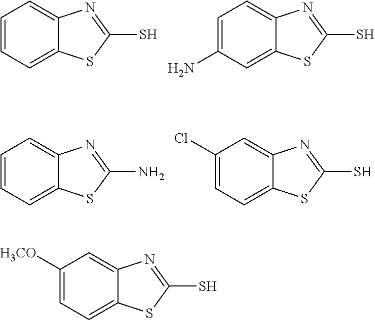 [SMILES: Sc1nc2ccccc2s1 ; Nc1ccc2nc(S)sc2c1 ; Nc1nc2ccccc2s1 ; Sc1nc2cc(Cl)ccc2s1 ; COc1ccc2sc(S)nc2c1]

Examples of the benzimidazole compound include the following compounds.

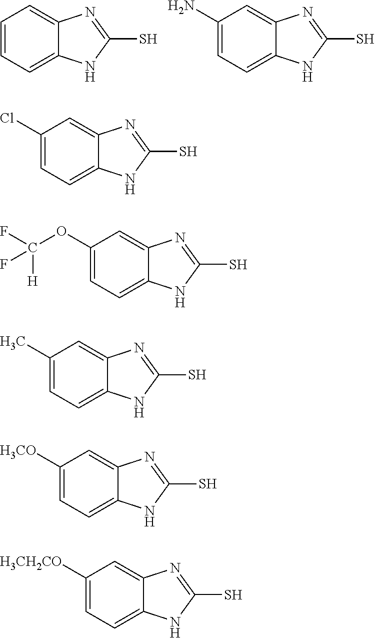

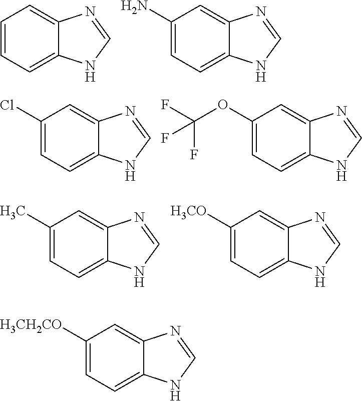

Examples of the benzoxazole compound include the following compounds.

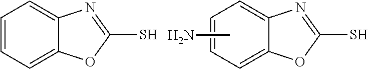

The heterocyclic compound may be used alone or in combination of two or more kinds thereof.

In a case where the photosensitive composition layer includes the heterocyclic compound, a content of the heterocyclic compound is preferably 0.01% to 20.0% by mass, more preferably 0.10% to 10.0% by mass, still more preferably 0.30% to 8.0% by mass, and particularly preferably 0.50% to 5.0% by mass with respect to the total mass of the photosensitive composition layer.

Aliphatic Thiol Compound

The photosensitive composition layer may include an aliphatic thiol compound.

In a case where the photosensitive composition layer includes an aliphatic thiol compound, an ene-thiol reaction of the aliphatic thiol compound with the radically polymerizable compound having an ethylenically unsaturated group suppresses a curing contraction of the formed film and relieves stress.

As the aliphatic thiol compound, a monofunctional aliphatic thiol compound or a polyfunctional aliphatic thiol compound (that is, bi- or higher functional aliphatic thiol compound) is preferable.

Among the above-described compounds, as the aliphatic thiol compound, from the viewpoint of adhesiveness of the formed pattern (particularly, adhesiveness after exposure), a polyfunctional aliphatic thiol compound is preferable.

In the present specification, the “polyfunctional aliphatic thiol compound” refers to an aliphatic compound having two or more thiol groups (also referred to as “mercapto groups”) in a molecule.

As the polyfunctional aliphatic thiol compound, a low-molecular-weight compound having a molecular weight of 100 or more is preferable. Specifically, the molecular weight of the polyfunctional aliphatic thiol compound is more preferably 100 to 1,500 and still more preferably 150 to 1,000.

From the viewpoint of adhesiveness of the formed pattern, for example, the number of functional groups in the polyfunctional aliphatic thiol compound is preferably 2 to 10, more preferably 2 to 8, and still more preferably 2 to 6.

Examples of the polyfunctional aliphatic thiol compound include trimethylolpropane tris(3-mercaptobutyrate), 1,4-bis(3-mercaptobutyryloxy)butane, pentaerythritol tetrakis(3-mercaptobutyrate), 1,3,5-tris(3-mercaptobutyryloxyethyl)-1,3,5-triazine-2,4,6(1H,3H,5H)-trione, trimethylolethane tris(3-mercaptobutyrate), tris[(3-mercaptopropionyloxy)ethyl] isocyanurate, trimethylolpropane tris(3-mercaptopropionate), pentaerythritol tetrakis(3-mercaptopropionate), tetraethylene glycol bis(3-mercaptopropionate), dipentaerythritol hexakis(3-mercaptopropionate), ethylene glycol bisthiopropionate, 1,2-ethanedithiol, 1,3-propanedithiol, 1,6-hexamethylenedithiol, 2,2′-(ethylenedithio)diethanethiol, meso-2,3-dimercaptosuccinic acid, and di(mercaptoethyl) ether.

Among the above-described compounds, the polyfunctional aliphatic thiol compound is preferably at least one compound selected from the group consisting of trimethylolpropane tris(3-mercaptobutyrate), 1,4-bis(3-mercaptobutyryloxy)butane, and 1,3,5-tris(3-mercaptobutyryloxyethyl)-1,3,5-triazine-2,4,6(1H,3H,5H)-trione.

Examples of the monofunctional aliphatic thiol compound include 1-octanethiol, 1-dodecanethiol, β-mercaptopropionic acid, methyl-3-mercaptopropionate, 2-ethylhexyl-3-mercaptopropionate, n-octyl-3-mercaptopropionate, methoxybutyl-3-mercaptopropionate, and stearyl-3-mercaptopropionate.

The photosensitive composition layer may include only one kind of the aliphatic thiol compound, or may include two or more kinds of the aliphatic thiol compounds.

In a case where the photosensitive composition layer includes the aliphatic thiol compound, a content of the aliphatic thiol compound is preferably 5% by mass or more, more preferably 5% by mass to 50% by mass, still more preferably 5% to 30% by mass, and particularly preferably 8% to 20% by mass with respect to the total mass of the photosensitive composition layer.

Thermal Crosslinking Compound

From the viewpoint of hardness of a cured film to be obtained and pressure-sensitive adhesiveness of an uncured film to be obtained, the photosensitive composition layer preferably includes a thermal crosslinking compound. In the present specification, a thermal crosslinking compound having an ethylenically unsaturated group, which will be described later, is not treated as the ethylenically unsaturated compound, but is treated as the thermal crosslinking compound.

Examples of the thermal crosslinking compound include an epoxy compound, an oxetane compound, a methylol compound, and a blocked isocyanate compound. Among these, from the viewpoint of hardness of a cured film to be obtained and pressure-sensitive adhesiveness of an uncured film to be obtained, a blocked isocyanate compound is preferable.

Since the blocked isocyanate compound reacts with a hydroxy group and a carboxy group, for example, in a case where at least one of the binder polymer or the radically polymerizable compound having an ethylenically unsaturated group has at least one of a hydroxy group or a carboxy group, hydrophilicity of the formed film tends to decrease, and the function as a protective film tends to be strengthened.

The blocked isocyanate compound refers to a “compound having a structure in which the isocyanate group of isocyanate is protected (so-called masked) with a blocking agent”.

A dissociation temperature of the blocked isocyanate compound is not particularly limited, but is preferably 90° C. to 160° C. and more preferably 100° C. to 150° C.

The dissociation temperature of blocked isocyanate means “temperature at an endothermic peak accompanied with a deprotection reaction of blocked isocyanate, in a case where the measurement is performed by differential scanning calorimetry (DSC) analysis using a differential scanning calorimeter”.

As the differential scanning calorimeter, for example, a differential scanning calorimeter (model: DSC6200) manufactured by Seiko Instruments Inc. can be suitably used. However, the differential scanning calorimeter is not limited thereto.

Examples of the blocking agent having a dissociation temperature of 100° C. to 160° C. include an active methylene compound [diester malonates (dimethyl malonate, diethyl malonate, di-n-butyl malonate, di-2-ethylhexyl malonate, and the like)], and an oxime compound (compound having a structure represented by —C(═N—OH)— in a molecule, such as formaldoxime, acetoaldoxime, acetoxime, methyl ethyl ketoxime, and cyclohexanoneoxime).

Among these, from the viewpoint of storage stability, the blocking agent having a dissociation temperature of 90° C. to 160° C. is preferably, for example, at least one selected from an oxime compound and a pyrazole compound.

From the viewpoint of improving brittleness of the film and improving the adhesion to the object to be transferred, for example, the blocked isocyanate compound preferably has an isocyanurate structure.

The blocked isocyanate compound having an isocyanurate structure can be obtained, for example, by isocyanurate-forming and protecting hexamethylene diisocyanate.

Among the blocked isocyanate compounds having an isocyanurate structure, a compound having an oxime structure using an oxime compound as a blocking agent is preferable from the viewpoint that the dissociation temperature can be easily set in a preferred range and the development residue can be easily reduced, as compared with a compound having no oxime structure.

The blocked isocyanate compound may have a polymerizable group.

The polymerizable group is not particularly limited, and a known polymerizable group can be used, and a radically polymerizable group is preferable.

Examples of the polymerizable group include a (meth)acryloxy group, a (meth)acrylamide group, an ethylenically unsaturated group such as styryl group, and an epoxy group such as a glycidyl group.

Among these, as the polymerizable group, an ethylenically unsaturated group is preferable, a (meth)acryloxy group is more preferable, and an acryloxy group still more preferable.

As the blocked isocyanate compound, a commercially available product can be used.

Examples of the commercially available product of the blocked isocyanate compound include Karenz (registered trademark) AOI-BM, Karenz (registered trademark) MOI-BM, Karenz (registered trademark) MOI-BP, and the like (all of which are manufactured by SHOWA DENKO K.K.), and block-type DURANATE series (for example, DURANATE (registered trademark) TPA-B80E, DURANATE (registered trademark) SBN-70D, DURANATE (registered trademark) WT32-B75P, and the like manufactured by Asahi Kasei Corporation).

As the blocked isocyanate compound, from the viewpoint that the effects of the present invention are more excellent, it is preferable to contain a blocked isocyanate compound having an NCO value of 4.5 mmol/g or more (hereinafter, may be referred to as a first blocked isocyanate compound). The NCO value of the first blocked isocyanate compound is preferably 5.0 mmol/g or more and more preferably 5.3 mmol/g or more.

From the viewpoint that the effects of the present invention are more excellent, the upper limit value of the NCO value of the first blocked isocyanate compound is preferably 8.0 mmol/g or less, more preferably 6.0 mmol/g or less, still more preferably less than 5.8 mmol/g, and particularly preferably 5.7 mmol/g or less.

The NCO value of the blocked isocyanate compound in the present invention means the number of moles of isocyanate groups included in 1 g of the blocked isocyanate compound, and is a value calculated from the structural formula of the blocked isocyanate compound.

From the viewpoint that the effects of the present invention are more excellent, the first blocked isocyanate compound preferably has a ring structure. Examples of the ring structure include an aliphatic hydrocarbon ring, an aromatic hydrocarbon ring, and a heterocyclic ring, and from the viewpoint that the effects of the present invention are more excellent, an aliphatic hydrocarbon ring or an aromatic hydrocarbon ring is preferable, and an aliphatic hydrocarbon ring is more preferable.

Specific examples of the aliphatic hydrocarbon ring include a cyclopentane ring and a cyclohexane ring, and among these, a cyclohexane ring is preferable.

Specific examples of the aromatic hydrocarbon ring include a benzene ring and a naphthalene ring, and among these, a benzene ring is preferable.

Specific examples of the heterocyclic ring include an isocyanurate ring.

In a case where the first blocked isocyanate compound has a ring structure, from the viewpoint that the effects of the present invention are more excellent, the number of rings is preferably 1 or 2 and more preferably 1. In a case where the first blocked isocyanate compound includes a fused ring, the number of rings constituting the fused ring is counted, for example, the number of rings in the naphthalene ring is counted as 2.

From the viewpoint that the strength of the formed pattern is excellent and the effects of the present invention are more excellent, the number of blocked isocyanate groups in the first blocked isocyanate compound is preferably 2 to 5, more preferably 2 or 3, and still more preferably 2.

From the viewpoint that the effects of the present invention are more excellent, the first blocked isocyanate compound is preferably a blocked isocyanate compound represented by Formula Q.

B¹-A¹-L¹-A²-B² Formula Q

In Formula Q, B¹ and B² each independently represent a blocked isocyanate group.

The blocked isocyanate group is not particularly limited, but from the viewpoint that the effects of the present invention are more excellent, a group in which an isocyanate group is blocked with an oxime compound is preferable, and a group in which an isocyanate group is blocked with methyl ethyl ketooxime (specifically, a group represented by *—NH—C(═O)—O—N═C(CH₃)—C₂H₅; * represents a bonding position with A¹ or A²) is more preferable.

B¹ and B² are preferably the same group.

In Formula Q, A¹ and A² each independently represent a single bond or an alkylene group having 1 to 10 carbon atoms, and an alkylene group having 1 to 10 carbon atoms is preferable.

The alkylene group may be linear, branched, or cyclic, and is preferably linear.

The number of carbon atoms in the alkylene group is 1 to 10, and from the viewpoint that the effects of the present invention are more excellent, is preferably 1 to 5, more preferably 1 to 3, and still more preferably 1.

A¹ and A² are preferably the same group.

In Formula Q, L¹ represents a divalent linking group.

Specific examples of the divalent linking group include a divalent hydrocarbon group.

Specific examples of the divalent hydrocarbon group include a divalent saturated hydrocarbon group, a divalent aromatic hydrocarbon group, and a group formed by linking two or more of these groups.

The divalent saturated hydrocarbon group may be linear, branched, or cyclic, and from the viewpoint that the effects of the present invention are more excellent, is preferably cyclic. From the viewpoint that the effects of the present invention are more excellent, the number of carbon atoms in the divalent saturated hydrocarbon group is preferably 4 to 15, more preferably 5 to 10, and still more preferably 5 to 8.

The divalent aromatic hydrocarbon group preferably has 5 to 20 carbon atoms, and examples thereof include a phenylene group. The divalent aromatic hydrocarbon group may have a substituent (for example, an alkyl group).

Among these, as the divalent linking group, a linear, branched, or cyclic divalent saturated hydrocarbon group having 5 to 10 carbon atoms, a group in which a cyclic saturated hydrocarbon group having 5 to 10 carbon atoms is linked to a linear alkylene group having 1 to 3 carbon atoms, a divalent aromatic hydrocarbon group which may have a substituent, or a group in which a divalent aromatic hydrocarbon group is linked to a linear alkylene group having 1 to 3 carbon atoms is preferable, a cyclic divalent saturated hydrocarbon group having 5 to 10 carbon atoms or a phenylene group which may have a substituent is more preferable, a cyclohexylene group or a phenylene group which may have a substituent is still more preferable, and a cyclohexylene group is particularly preferable.

From the viewpoint that the effects of the present invention are more excellent, the blocked isocyanate compound represented by Formula Q is particularly preferably a blocked isocyanate compound represented by Formula QA.

B^{1a}-A^{1a}-L^{1a}-A^{2a}-B^{2a} Formula QA

In Formula QA, B^{1a} and B^{2a} each independently represent a blocked isocyanate group. Suitable aspects of B^{1a} and B^{2a} are the same as those of B¹ and B² in Formula Q.

In Formula QA, A^{1a} and A^{2a} each independently represent a divalent linking group. A suitable aspect of the divalent linking group in A^{1a} and A^{2a} is the same as those of A¹ and A² in Formula Q.

In Formula QA, L^{1a} represents a cyclic divalent saturated hydrocarbon group or a divalent aromatic hydrocarbon group.

The number of carbon atoms in the cyclic divalent saturated hydrocarbon group in L^{1a} is preferably 5 to 10, more preferably 5 to 8, still more preferably 5 or 6, and particularly preferably 6.

A suitable aspect of the divalent aromatic hydrocarbon group in L^{1a} is the same as that of L¹ in Formula Q.

Among these, L^{1a} is preferably a cyclic divalent saturated hydrocarbon group, more preferably a cyclic divalent saturated hydrocarbon group having 5 to 10 carbon atoms, still more preferably a cyclic divalent saturated hydrocarbon group having 5 to 8 carbon atoms, particularly preferably a cyclic divalent saturated hydrocarbon group having 5 or 6 carbon atoms, and most preferably a cyclohexylene group.

In a case where L^{1a} is a cyclohexylene group, the blocked isocyanate compound represented by Formula QA may be an isomer mixture of a cis form and a trans form (hereinafter, also referred to as a “cis-trans isomer mixture”).

A mass ratio of the cis form and the trans form is preferably cis form/trans form=10/90 to 90/10, and more preferably cis form/trans form=40/60 to 60/40.

Specific examples of the first blocked isocyanate compound are shown below, but the first blocked isocyanate compound is not limited thereto.

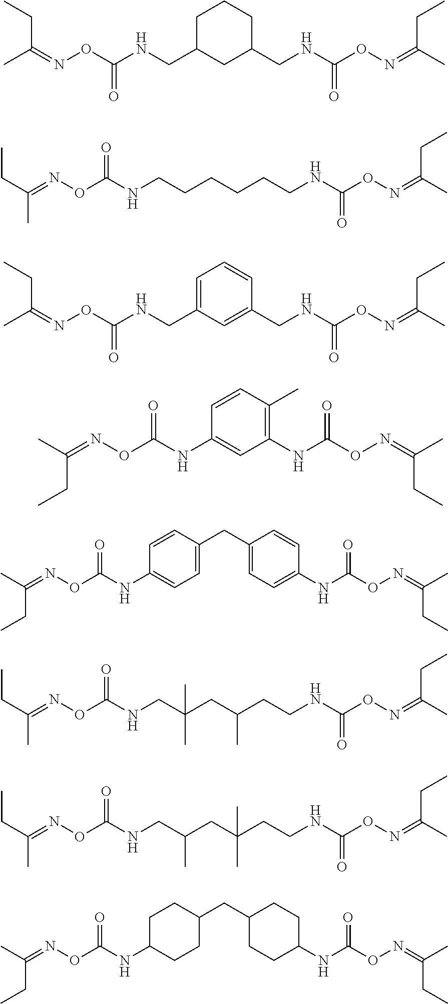

The thermal crosslinking compound may be used alone or in combination of two or more kinds thereof.

In a case where the photosensitive composition layer includes the thermal crosslinking compound, a content of the thermal crosslinking compound is preferably 1% to 50% by mass and more preferably 5% to 30% by mass with respect to the total mass of the photosensitive composition layer.

Surfactant

The photosensitive composition layer may include a surfactant.

Examples of the surfactant include surfactants described in paragraph [0017] of JP4502784B and paragraphs [0060] to [0071] of JP2009-237362A.

As the surfactant, a nonionic surfactant, a fluorine-based surfactant, or a silicone-based surfactant is preferable.

Examples of a commercially available product of the fluorine-based surfactant include: MEGAFACE F-171, F-172, F-173, F-176, F-177, F-141, F-142, F-143, F-144, F-437, F-475, F-477, F-479, F-482, F-551-A, F-552, F-554, F-555-A, F-556, F-557, F-558, F-559, F-560, F-561, F-565, F-563, F-568, F-575, F-780, EXP, MFS-330, EXP.MFS-578, EXP.MFS-579, EXP.MFS-586, EXP.MFS-587, R-41, R-41-LM, R-01, R-40, R-40-LM, RS-43, TF-1956, RS-90, R-94, RS-72-K, and DS-21 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); and POLYFOX PF636, PF656, PF6320, PF6520, and PF7002 (all of which are manufactured by OMNOVA Solutions Inc.); FTERGENT 710FL, 710FM, 610FM, 601AD, 601ADH2, 602A, 215M, 245F, 251, 212M, 250, 209F, 222F, 208G, 710LA, 710FS, 730LM, 650AC, 681, and 683 (all of which are manufactured by NEOS COMPANY LIMITED).

In addition, as the fluorine-based surfactant, an acrylic compound, which has a molecular structure having a functional group containing a fluorine atom and in which, by applying heat to the molecular structure, the functional group containing a fluorine atom is broken to volatilize a fluorine atom, can also be suitably used. Examples of such a fluorine-based surfactant include MEGAFACE DS series manufactured by DIC Corporation (The Chemical Daily (Feb. 22, 2016) and Nikkei Business Daily (Feb. 23, 2016)), for example, MEGAFACE DS-21.

In addition, as the fluorine-based surfactant, a polymer of a fluorine atom-containing vinyl ether compound having a fluorinated alkyl group or a fluorinated alkylene ether group, and a hydrophilic vinyl ether compound is also preferably used.

In addition, as the fluorine-based surfactant, a block polymer can also be used.

In addition, as the fluorine-based surfactant, a fluorine-containing polymer compound including a constitutional unit derived from a (meth)acrylate compound having a fluorine atom and a constitutional unit derived from a (meth)acrylate compound having 2 or more (preferably 5 or more) alkyleneoxy groups (preferably ethyleneoxy groups or propyleneoxy groups) can also be preferably used.

In addition, as the fluorine-based surfactant, a fluorine-containing polymer having an ethylenically unsaturated bond-containing group in the side chain can also be used. Examples thereof include MEGAFACE RS-101, RS-102, RS-718K, and RS-72-K (all of which are manufactured by DIC Corporation).

As the fluorine-based surfactant, from the viewpoint of improving environmental suitability, a surfactant derived from a substitute material for a compound having a linear perfluoroalkyl group having 7 or more carbon atoms, such as perfluorooctanoic acid (PFOA) and perfluorooctanesulfonic acid (PFOS), is preferable.

Examples of the nonionic surfactant include glycerol, trimethylolpropane, trimethylolethane, an ethoxylate and propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC (registered trademark) L10, L31, L61, L62, 10R5, 17R2, and 25R2 (all of which are manufactured by BASF SE), TETRONIC 304, 701, 704, 901, 904, and 150R1 (all of which are manufactured by BASF SE), SOLSPERSE 20000 (manufactured by Lubrizol Corporation), NCW-101, NCW-1001, and NCW-1002 (all of which are manufactured by FUJIFILM Wako Pure Chemical Corporation), PIONIN D-6112, D-6112-W, and D-6315 (all of which are manufactured by Takemoto Oil&Fat Co., Ltd.), and OLFINE E1010 and SURFYNOL 104, 400, and 440 (all of which are manufactured by Nissin Chemical Co., Ltd.).

Examples of the silicone-based surfactant include a linear polymer consisting of a siloxane bond and a modified siloxane polymer with an organic group introduced in the side chain or the terminal.

Specific examples of the silicone-based surfactant include DOWSIL 8032 ADDITIVE, TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Toray Co., Ltd.), X-22-4952, X-22-4272, X-22-6266, KF-351A, K354L, KF-355A, KF-945, KF-640, KF-642, KF-643, X-22-6191, X-22-4515, KF-6004, KP-341, KF-6001, and KF-6002 (all of which are manufactured by Shin-Etsu Silicone Co., Ltd.), F-4440, TSF-4300, TSF-4445, TSF-4460, and TSF-4452 (all of which are manufactured by Momentive Performance Materials Co., Ltd.), and BYK307, BYK323, and BYK330 (all of which are manufactured by BYK Chemie).

The surfactant may be used alone or in combination of two or more kinds thereof.

In a case where the photosensitive composition layer includes the surfactant, a content of the surfactant is preferably 0.01% to 3.0% by mass, more preferably 0.01% to 1.0% by mass, and still more preferably 0.05% to 0.80% by mass with respect to the total mass of the photosensitive composition layer.

Polymerization Inhibitor

The photosensitive composition layer may include a polymerization inhibitor.

The polymerization inhibitor means a compound having a function of delaying or prohibiting a polymerization reaction. As the polymerization inhibitor, for example, a known compound used as a polymerization inhibitor can be used.

Examples of the polymerization inhibitor include phenothiazine compounds such as phenothiazine, bis-(1-dimethylbenzyl)phenothiazine, and 3,7-dioctylphenothiazine; hindered phenolic compounds such as bis[3-(3-tert-butyl-4-hydroxy-5-methylphenyl)propionic acid] [ethylene bis(oxyethylene)], 2,4-bis[(laurylthio)methyl]-o-cresol, 1,3,5-tris(3,5-di-t-butyl-4-hydroxybenzyl), 1,3,5-tris(4-t-butyl-3-hydroxy-2,6-dimethylbenzyl), 2,4-bis-(n-octylthio)-6-(4-hydroxy-3,5-di-t-butylanilino)-1,3,5-triazine, and pentaerythritol tetrakis3-(3,5-di-tert-butyl-4-hydroxyphenyl)propionate; nitroso compounds or a salt thereof, such as 4-nitrosophenol, N-nitrosodiphenylamine, N-nitrosocyclohexylhydroxylamine, and N-nitrosophenylhydroxylamine; quinone compounds such as methylhydroquinone, t-butylhydroquinone, 2,5-di-t-butylhydroquinone, and 4-benzoquinone; phenolic compounds such as 4-methoxyphenol, 4-methoxy-1-naphthol, and t-butylcatechol; and metal salt compounds such as copper dibutyldithiocarbamate, copper diethyldithiocarbamate, manganese diethyldithiocarbamate, and manganese diphenyldithiocarbamate.

Among these, as the polymerization inhibitor, from the viewpoint that the effects of the present invention are more excellent, at least one selected from the group consisting of a phenothiazine compound, a nitroso compound or a salt thereof, and a hindered phenolic compound is preferable, and phenothiazine, bis[3-(3-tert-butyl-4-hydroxy-5-methylphenyl)propionic acid][ethylene bis(oxyethylene)], 2,4-bis[(laurylthio)methyl]-o-cresol, 1,3,5-tris(3,5-di-t-butyl-4-hydroxybenzyl), p-methoxyphenol, or an aluminum salt of N-nitrosophenylhydroxylamine is more preferable.

The polymerization inhibitor may be used alone or in combination of two or more kinds thereof.

In a case where the photosensitive composition layer includes the polymerization inhibitor, a content of the polymerization inhibitor is preferably 0.001% to 5.0% by mass, more preferably 0.01% to 3.0% by mass, and still more preferably 0.02% to 2.0% by mass with respect to the total mass of the photosensitive composition layer. The content of the polymerization inhibitor is preferably 0.005% to 5.0% by mass, more preferably 0.01% to 3.0% by mass, and still more preferably 0.01% to 1.0% by mass with respect to the total mass of the ethylenically unsaturated compound.

Hydrogen Donating Compound

The photosensitive composition layer may include a hydrogen donating compound.

The hydrogen donating compound has a function of further improving sensitivity of the photopolymerization initiator to actinic ray, suppressing inhibition of polymerization of the ethylenically unsaturated compound by oxygen, or the like.

Examples of the hydrogen donating compound include amines and an amino acid compound.

Examples of the amines include compounds described in M. R. Sander et al., “Journal of Polymer Society,” Vol. 10, page 3173 (1972), JP1969-020189B (JP-S44-020189B), JP1976-082102A (JP-S51-082102A), JP1977-134692A (JP-S52-134692A), JP1984-138205A (JP-S59-138205A), JP1985-084305A (JP-S60-084305A), JP 1987-018537A (JP-S62-018537A), JP1989-033104A (JP-S64-033104A), and Research Disclosure 33825. More specific examples thereof include 4,4′-bis(diethylamino)benzophenone, tris(4-dimethylaminophenyl)methane (another name: Leucocrystal Violet), triethanolamine, p-dimethylaminobenzoic acid ethyl ester, p-formyldimethylaniline, and p-methylthiodimethylaniline.

Among these, as the amines, from the viewpoint that the effects of the present invention are more excellent, at least one selected from the group consisting of 4,4′-bis(diethylamino)benzophenone and tris(4-dimethylaminophenyl)methane is preferable.

Examples of the amino acid compound include N-phenylglycine, N-methyl-N-phenylglycine, and N-ethyl-N-phenylglycine.

Among these, as the amino acid compound, from the viewpoint that the effects of the present invention are more excellent, N-phenylglycine is preferable.

In addition, examples of the hydrogen donating compound also include an organic metal compound described in JP1973-042965B (JP-S48-042965B) (tributyl tin acetate and the like), a hydrogen donor described in JP1980-034414B (JP-S55-034414B), and a sulfur compound described in JP1994-308727A (JP-H6-308727A) (trithiane and the like).

The hydrogen donating compound may be used alone or in combination of two or more kinds thereof.

In a case where the photosensitive composition layer includes the hydrogen donating compound, from the viewpoint of improving a curing rate by balancing the polymerization growth rate and chain transfer, a content of the hydrogen donating compound is preferably 0.01% to 10.0% by mass, more preferably 0.01% to 8.0% by mass, and still more preferably 0.03% to 5.0% by mass with respect to the total mass of the photosensitive composition layer. Impurities and the like

The photosensitive composition layer may include a predetermined amount of impurities.

Examples of the impurities include sodium, potassium, magnesium, calcium, iron, manganese, copper, aluminum, titanium, chromium, cobalt, nickel, zinc, tin, halogen, and ions of these. Among these, halide ion (chloride ion, bromide ion, and iodide ion), sodium ion, and potassium ion are easily mixed as impurities, so that the following content is preferable.

A content of impurities in the photosensitive composition layer is preferably 80 ppm or less, more preferably 10 ppm or less, and particularly preferably 2 ppm or less on a mass basis. The content of impurities in the photosensitive composition layer may be 1 ppb or more or 0.1 ppm or more on a mass basis. Specific examples of the content of the impurities in the photosensitive composition layer include an aspect in which all the above-described impurities are 0.6 ppm on a mass basis.

Examples of a method of setting the impurities in the above-described range include selecting a raw material having a low content of impurities as a raw material for the photosensitive composition layer, preventing the impurities from being mixed in a case of forming the photosensitive composition layer, and washing and removing the impurities. By such a method, the amount of impurities can be kept within the above-described range.

The impurities can be quantified by a known method such as inductively coupled plasma (ICP) emission spectroscopy, atomic absorption spectroscopy, and ion chromatography.

In the photosensitive composition layer, it is preferable that the content of compounds such as benzene, formaldehyde, trichlorethylene, 1,3-butadiene, carbon tetrachloride, chloroform, N,N-dimethylformamide, N,N-dimethylacetamide, and hexane is low in each layer. The content of these compounds in the photosensitive composition layer is preferably 100 ppm or less, more preferably 20 ppm or less, and particularly preferably 4 ppm or less on a mass basis. The lower limit thereof may be 10 ppb or more or 100 ppb or more on a mass basis. The content of these compounds can be suppressed in the same manner as in the above-described metal as impurities. In addition, the compounds can be quantified by a known measurement method.

From the viewpoint of reliability and laminating property, the content of water in the photosensitive composition layer is preferably 0.01% to 1.0% by mass and more preferably 0.05% to 0.5% by mass.

Residual Monomer

The photosensitive composition layer may include a residual monomer of each constitutional unit in the above-described alkali-soluble resin.

From the viewpoint of patterning properties and reliability, a content of the residual monomer is preferably 5,000 ppm by mass or less, more preferably 2,000 ppm by mass or less, and still more preferably 500 ppm by mass or less with respect to the total mass of the alkali-soluble resin. The lower limit is not particularly limited, but is preferably 1 ppm by mass or more and more preferably 10 ppm by mass or more.

From the viewpoint of patterning properties and reliability, the residual monomer of each constitutional unit in the alkali-soluble resin is preferably 3,000 ppm by mass or less, more preferably 600 ppm by mass or less, and still more preferably 100 ppm by mass or less with respect to the total mass of the photosensitive composition layer. The lower limit is not particularly limited, but is preferably 0.1 ppm by mass or more and more preferably 1 ppm by mass or more.

It is preferable that the amount of residual monomer of the monomer in a case of synthesizing the alkali-soluble resin by the polymer reaction is also within the above-described range. For example, in a case where glycidyl acrylate is reacted with a carboxylic acid side chain to synthesize the alkali-soluble resin, the content of glycidyl acrylate is preferably within the above-described range.

The amount of residual monomers can be measured by a known method such as liquid chromatography and gas chromatography.

Other Components

The photosensitive composition layer may include a component other than the above-mentioned components (hereinafter also referred to as “other components”). Examples of the other components include a colorant, an antioxidant, and particles (for example, metal oxide particles). In addition, examples of the other components also include other additives described in paragraphs [0058] to [0071] of JP2000-310706A.

Particles

As the particles, metal oxide particles are preferable.

The metal of the metal oxide particles also includes semimetal such as B, Si, Ge, As, Sb, or Te.

From the viewpoint of transparency of the protective film, for example, an average primary particle diameter of the particles is preferably 1 to 200 nm and more preferably 3 to 80 nm.

The average primary particle diameter of the particles is calculated by measuring particle diameters of 200 random particles using an electron microscope and arithmetically averaging the measurement result. In a case where the shape of the particle is not a spherical shape, the longest side is set as the particle diameter.

In a case where the photosensitive composition layer includes the particles, the photosensitive composition layer may include only one kind of particles, or may include two or more kinds of particles having different metal types, sizes, and the like.

It is preferable that the photosensitive composition layer does not include the particles, or in a case where the photosensitive composition layer includes the particles, a content of the particles is more than 0% by mass and 35% by mass or less with respect to the total mass of the photosensitive composition layer; it is more preferable that the photosensitive composition layer does not include the particles, or in a case where the photosensitive composition layer includes the particles, a content of the particles is more than 0% by mass and 10% by mass or less with respect to the total mass of the photosensitive composition layer; it is still more preferable that the photosensitive composition layer does not include the particles, or in a case where the photosensitive composition layer includes the particles, a content of the particles is more than 0% by mass and 5% by mass or less with respect to the total mass of the photosensitive composition layer; it is even more preferable that the photosensitive composition layer does not include the particles, or in a case where the photosensitive composition layer includes the particles, a content of the particles is more than 0% by mass and 1% by mass or less with respect to the total mass of the photosensitive composition layer; and it is particularly preferable that the photosensitive composition layer does not include the particles.

Colorant

The photosensitive composition layer may include a trace amount of a colorant (pigment, dye, and the like), but for example, from the viewpoint of transparency, it is preferable that the photosensitive composition layer does not substantially include the colorant.

In a case where the photosensitive composition layer includes the colorant, a content of the colorant is preferably less than 1% by mass and more preferably less than 0.1% by mass with respect to the total mass of the photosensitive composition layer.

Antioxidant

Examples of the antioxidant include 3-pyrazolidones such as 1-phenyl-3-pyrazolidone (another name; phenidone), 1-phenyl-4,4-dimethyl-3-pyrazolidone, and 1-phenyl-4-methyl-4-hydroxymethyl-3-pyrazolidone; polyhydroxybenzenes such as hydroquinone, catechol, pyrogallol, methylhydroquinone, and chlorohydroquinone; paramethylaminophenol, paraaminophenol, parahydroxyphenylglycine, and paraphenylenediamine.

Among these, as the antioxidant, from the viewpoint that the effects of the present invention are more excellent, 3-pyrazolidones are preferable, and 1-phenyl-3-pyrazolidone is more preferable.

In a case where the photosensitive composition layer includes the antioxidant, a content of the antioxidant is preferably 0.001% by mass or more, more preferably 0.005% by mass or more, and still more preferably 0.01% by mass or more with respect to the total mass of the photosensitive composition layer. The upper limit is not particularly limited, and is preferably 1% by mass or less.

Thickness of Photosensitive Composition Layer

A thickness of the photosensitive composition layer is not particularly limited, but from the viewpoint that the effects of the present invention are more excellent, is often 30 μm or less, preferably 20 μm or less, more preferably 15 μm or less, still more preferably 10 μm or less, and particularly preferably 5.0 μm or less. From the viewpoint that hardness of a film obtained by curing the photosensitive composition layer is excellent, the lower limit is preferably 0.60 μm or more and more preferably 1.5 μm or more.

For example, the thickness of the photosensitive composition layer is obtained as an average value of 5 random points measured by cross-sectional observation with a scanning electron microscope (SEM).

Refractive Index of Photosensitive Composition Layer

A refractive index of the photosensitive composition layer is preferably 1.41 to 1.59 and more preferably 1.47 to 1.56

Color of Photosensitive Composition Layer

The photosensitive composition layer is preferably achromatic. Specifically, in CIE1976 (L*, a*, b*) color space of the total reflection (incidence angle: 8°, light source: D-65 (visual field: 2°)), the L* value is preferably 10 to 90, the a* value is preferably −1.0 to 1.0, and the b* value is preferably −1.0 to 1.0.

A pattern obtained by curing the photosensitive composition layer (cured film of the photosensitive composition layer) is preferably achromatic.

Specifically, in CIE1976 (L*, a*, b*) color space, the total reflection (incidence angle: 8°, light source: D-65 (visual field: 2°)) preferably has a pattern L* value of 10 to 90, preferably has a pattern a* value of −1.0 to 1.0, and preferably has a pattern b* value of −1.0 to 1.0.

Transmittance of Photosensitive Composition Layer

A visible light transmittance of the photosensitive composition layer at a film thickness of approximately 1.0 μm is preferably 80% or more, more preferably 90% or more, and most preferably 95% or more. As the visible light transmittance, it is preferable that an average transmittance at a wavelength of 400 nm to 800 nm, the minimum value of the transmittance at a wavelength of 400 nm to 800 nm, and a transmittance at a wavelength of 400 nm all satisfy the above. Examples of a preferred value of the transmittance include 87%, 92%, and 98%. The same applies to a transmittance of the cured film of the photosensitive composition layer at a film thickness of approximately 1 μm.

Moisture Permeability of Photosensitive Composition Layer

From the viewpoint of rust preventive property of electrode or wiring line, and viewpoint of device reliability, a moisture permeability of the pattern obtained by curing the photosensitive composition layer (cured film of the photosensitive composition layer) at a film thickness of 40 μm is preferably 500 g/m²·24 hr, more preferably 300 g/m²·24 hr, and still more preferably 100 g/m²·24 hr.

The moisture permeability is measured with a cured film obtained by curing the photosensitive composition layer by exposing the photosensitive composition layer with i-rays at an exposure amount of 300 mJ/cm², and then performing post-baking at 145° C. for 30 minutes. The moisture permeability is measured according to a cup method of JIS Z0208. It is preferable that the above-described moisture permeability is as above under any test conditions of temperature 40° C. and humidity 90%, temperature 65° C. and humidity 90%, or temperature 80° C. and humidity 95%. Examples of a specific preferred numerical value include 80 g/m²·24 hr, 150 g/m²·24 hr, and 220 g/m²·24 hr.

Dissolution Rate of Photosensitive Composition Layer

From the viewpoint of suppressing residue during development, a dissolution rate of the photosensitive composition layer in a 1.0% sodium carbonate aqueous solution is preferably 0.01 μm/sec or more, more preferably 0.10 μm/sec or more, and still more preferably 0.20 μm/sec or more. From the viewpoint of edge shape of the pattern, it is preferable to be 5.0 μm/sec or less, more preferable to be 4.0 μm/sec or less, and still more preferable to be 3.0 μm/sec or less. Examples of a specific preferred numerical value include 1.8 μm/sec, 1.0 μm/sec, and 0.7 μm/sec. The dissolution rate of the photosensitive composition layer in a 1.0% by mass sodium carbonate aqueous solution per unit time is measured as follows.

A photosensitive composition layer (within a film thickness of 1.0 to 10 μm) formed on a glass substrate, from which the solvent has been sufficiently removed, is subjected to a shower development with a 1.0% by mass sodium carbonate aqueous solution at 25° C. until the photosensitive composition layer is dissolved completely (however, the maximum time is 2 minutes).

The dissolution rate of the photosensitive composition layer is obtained by dividing the film thickness of the photosensitive composition layer by the time required for the photosensitive composition layer to dissolve completely. In a case where the photosensitive composition layer is not dissolved completely in 2 minutes, the dissolution rate of the photosensitive composition layer is calculated in the same manner as above, from the amount of change in film thickness up to 2 minutes.

A dissolution rate of the cured film (within a film thickness of 1.0 to 10 μm) of the photosensitive composition layer in a 1.0% sodium carbonate aqueous solution is preferably 3.0 μm/sec or less, more preferably 2.0 μm/sec or less, still more preferably 1.0 μm/sec or less, and most preferably 0.2 μm/sec or less. The cured film of the photosensitive composition layer is a film obtained by exposing the photosensitive composition layer with i-rays at an exposure amount of 300 mJ/cm². Examples of a specific preferred numerical value include 0.8 μm/sec, 0.2 μm/sec, and 0.001 μm/sec. For development, a shower nozzle of ¼ MiNJJX030PP manufactured by H.IKEUCHI Co., Ltd. is used, and a spraying pressure of the shower is set to 0.08 MPa. Under the above-described conditions, a shower flow rate per unit time is set to 1,800 mL/min.

Swelling Ratio of Photosensitive Composition Layer

From the viewpoint of improving pattern formability, a swelling ratio of the photosensitive composition layer after exposure with respect to a 1.0% by mass sodium carbonate aqueous solution is preferably 100% or less, more preferably 50% or less, and still more preferably 30% or less. The swelling ratio of the photosensitive resin layer after exposure with respect to a 1.0% by mass sodium carbonate aqueous solution is measured as follows.

A photosensitive resin layer (within a film thickness of 1.0 to 10 μm) formed on a glass substrate, from which the solvent has been sufficiently removed, is exposed at an exposure amount of 500 mJ/cm² (i-ray measurement) with an ultra-high pressure mercury lamp. The glass substrate is immersed in a 1.0% by mass sodium carbonate aqueous solution at 25° C., and the film thickness is measured after 30 seconds. Then, an increased proportion of the film thickness after immersion to the film thickness before immersion is calculated. Examples of a specific preferred numerical value include 4%, 13%, and 25%.

Foreign Substance in Photosensitive Composition Layer

From the viewpoint of pattern formability, the number of foreign substances having a diameter of 1.0 μm or more in the photosensitive composition layer is preferably 10 pieces/mm² or less, and more preferably 5 pieces/mm² or less. The number of foreign substances is measured as follows. Any 5 regions (1 mm×1 mm) on a surface of the photosensitive composition layer are visually observed from a normal direction of the surface of the photosensitive composition layer with an optical microscope, the number of foreign substances having a diameter of 1.0 μm or more in each region is measured, and the values are arithmetically averaged to calculate the number of foreign substances. Examples of a specific preferred numerical value include 0 pieces/mm², 1 pieces/mm², 4 pieces/mm², and 8 pieces/mm².

Haze of Dissolved Substance in Photosensitive Composition Layer

From the viewpoint of suppressing generation of aggregates during development, a haze of a solution obtained by dissolving 1.0 cm³ of the photosensitive resin layer in 1.0 liter of a 1.0% by mass sodium carbonate aqueous solution at 30° C. is preferably 60% or less, more preferably 30% or less, still more preferably 10% or less, and most preferably 1% or less. The haze is measured as follows. First, a 1.0% by mass sodium carbonate aqueous solution is prepared, and a liquid temperature is adjusted to 30° C. 1.0 cm³ of the photosensitive resin layer is added to 1.0 L of the sodium carbonate aqueous solution. The solution is stirred at 30° C. for 4 hours, being careful not to mix air bubbles. After stirring, the haze of the solution in which the photosensitive resin layer is dissolved is measured. The haze is measured using a haze meter (product name “NDH4000”, manufactured by Nippon Denshoku Industries Co., Ltd.), a liquid measuring unit, and a liquid measuring cell having an optical path length of 20 mm. Examples of a specific preferred numerical value include 0.4%, 1.0%, 9%, and 24%.

Protective Film

The transfer film may have a protective film.

As the protective film, a resin film having heat resistance and solvent resistance can be used, and examples thereof include polyolefin films such as a polypropylene film and a polyethylene film, polyester films such as a polyethylene terephthalate film, polycarbonate films, and polystyrene films.

In addition, as the protective film, a resin film formed of the same material as in the above-described temporary support may be used.

Among these, as the protective film, a polyolefin film is preferable, a polypropylene film or a polyethylene film is more preferable, and a polyethylene film is still more preferable.

A thickness of the protective film is preferably 1 to 100 μm, more preferably 5 to 50 μm, still more preferably 5 to 40 μm, and particularly preferably 15 to 30 μm.

From the viewpoint of excellent mechanical hardness, the thickness of the protective film is preferably 1 μm or more, and from the viewpoint of relatively low cost, the thickness of the protective film is preferably 100 μm or less.

In addition, in the protective film, it is preferable that the number of fisheyes with a diameter of 80 μm or more in the protective film is 5 pieces/m² or less.

The “fisheye” means that, in a case where a material is hot-melted, kneaded, extruded, biaxially stretched, cast or the like to produce a film, foreign substances, undissolved substances, oxidatively deteriorated substances, and the like of the material are incorporated into the film.

The number of particles having a diameter of 3 μm or more included in the protective film is preferably 30 particles/mm² or less, more preferably 10 particles/mm² or less, and still more preferably 5 particles/mm² or less.

As a result, it is possible to suppress defects caused by ruggedness due to the particles included in the protective film being transferred to the photosensitive composition layer or a conductive layer.

From the viewpoint of imparting take-up property, in the protective film, an arithmetic average roughness Ra on a surface opposite to a surface in contact with the composition layer is preferably 0.01 μm or more, more preferably 0.02 μm or more, and still more preferably 0.03 μm or more. On the other hand, it is preferable to be less than 0.50 μm, more preferable to be 0.40 μm or less, and still more preferable to be 0.30 μm or less.

From the viewpoint of suppressing defects during transfer, in the protective film, the surface roughness Ra on the surface in contact with the composition layer is preferably 0.01 pm or more, more preferably 0.02 μm or more, and still more preferably 0.03 μm or more. On the other hand, it is preferable to be less than 0.50 μm, more preferable to be 0.40 μm or less, and still more preferable to be 0.30 μm or less.

Relationship between temporary support, photosensitive composition layer, and protective film

It is preferable that a breaking elongation of the cured film obtained by curing the photosensitive composition layer at 120° C. is 15% or more, an arithmetic average roughness Ra of a surface of the temporary support on the photosensitive composition layer side is 50 nm or less, and an arithmetic average roughness Ra of a surface of the protective film on the photosensitive composition layer side is 150 nm or less.

It is preferable to satisfy the following expression (1).

X×Y<1500 Expression (1)

Here, in Expression (1), X represents a value (%) of the breaking elongation of the cured film obtained by curing the photosensitive composition layer at 120° C., and Y represents a value (nm) of the arithmetic average roughness Ra of the surface of the temporary support on the photosensitive composition layer side. The X×Y is more preferably 750 or less. Examples of a specific numerical value of the X include 18%, 25%, 30%, and 35%. Examples of a specific numerical value of the Y include 4 nm, 8 nm, 15 nm, and 30 nm. Examples of a specific numerical value of the X×Y include 150, 200, 300, 360, and 900.

It is preferable that the above-described breaking elongation at 120° C. is twice or more larger than a breaking elongation of the cured film obtained by curing the photosensitive composition layer at 23° C.

The breaking elongation is measured by a tensile test with a cured film which is obtained by exposing a photosensitive composition layer having a thickness of 20 μm at an exposure amount of 120 mJ/cm² with an ultra-high pressure mercury lamp to be cured, further exposing at an exposure amount of 400 mJ/cm² with a high pressure mercury lamp, and heating at 145° C. for 30 minutes.

It is preferable to satisfy the following expression (2).

Y≤Z Expression (2)

Here, in Expression (2), Y represents the value (nm) of the arithmetic average roughness Ra of the surface of the temporary support on the photosensitive composition layer side, and Z represents a value (nm) of the arithmetic average roughness Ra of the surface of the protective film on the photosensitive composition layer side.

Refractive Index Adjusting Layer

The transfer film preferably has a refractive index adjusting layer.

As the refractive index adjusting layer, a known refractive index adjusting layer can be adopted. Examples of a material included in the refractive index adjusting layer include a binder polymer, an ethylenically unsaturated compound, a metal salt, and particles.

A method for controlling a refractive index of the refractive index adjusting layer is not particularly limited, and examples thereof include a method using a resin having a predetermined refractive index alone, a method using a resin and particles, and a method using a composite body of a metal salt and a resin.

Examples of the binder polymer and the ethylenically unsaturated compound include the binder polymer and the ethylenically unsaturated compound described in the section of “Photosensitive composition layer”.

Examples of the particles include metal oxide particles and metal particles.

The type of the metal oxide particles is not particularly limited, and examples thereof include known metal oxide particles. The metal of the metal oxide particles also includes semimetal such as B, Si, Ge, As, Sb, or Te.

From the viewpoint of transparency of the cured film, for example, an average primary particle diameter of the particles is preferably 1 to 200 nm and more preferably 3 to 80 nm.

The average primary particle diameter of the particles is calculated by measuring particle diameters of 200 random particles using an electron microscope and arithmetically averaging the measurement result. In a case where the shape of the particle is not a spherical shape, the longest side is set as the particle diameter.

Specifically, as the metal oxide particles, at least one selected from the group consisting of zirconium oxide particles (ZrO₂ particles), Nb₂O₅ particles, titanium oxide particles (TiO₂ particles), silicon dioxide particles (SiO₂ particles), and composite particles thereof is preferable.

Among these, for example, from the viewpoint that it is easy to adjust the refractive index, the metal oxide particles are more preferably at least one selected from the group consisting of zirconium oxide particles and titanium oxide particles.

Examples of a commercially available product of the metal oxide particles include calcined zirconium oxide particles (manufactured by CIK-Nano Tek., product name: ZRPGM15WT %-F04), calcined zirconium oxide particles (manufactured by CIK-Nano Tek., product name: ZRPGM15WT %-F74), calcined zirconium oxide particles (manufactured by CIK-Nano Tek., product name: ZRPGM15WT %-F75), calcined zirconium oxide particles (manufactured by CIK-Nano Tek., product name: ZRPGM15WT %-F76), zirconium oxide particles (NanoUse OZ-S30M, manufactured by Nissan Chemical Corporation), and zirconium oxide particles (NanoUse OZ-S30K, manufactured by Nissan Chemical Corporation).

The particles may be used alone or in combination of two or more kinds thereof.

A content of the particles in the refractive index adjusting layer is preferably 1% to 95% by mass, more preferably 20% to 90% by mass, and still more preferably 40% to 85% by mass with respect to the total mass of the refractive index adjusting layer.

In a case where titanium oxide is used as the metal oxide particles, the content of the titanium oxide particles is preferably 1% to 95% by mass, more preferably 20% to 90% by mass, and still more preferably 40% to 85% by mass with respect to the total mass of the refractive index adjusting layer.

It is preferable that the refractive index of the refractive index adjusting layer is higher than the refractive index of the photosensitive composition layer.

The refractive index of the refractive index adjusting layer is preferably 1.50 or more, more preferably 1.55 or more, still more preferably 1.60 or more, and particularly preferably 1.65 or more. The upper limit of the refractive index of the refractive index adjusting layer is preferably 2.10 or less, more preferably 1.85 or less, and still more preferably 1.78 or less.

A thickness of the refractive index adjusting layer is preferably 50 to 500 nm, more preferably 55 to 110 nm, and still more preferably 60 to 100 nm.

The thickness of the refractive index adjusting layer is obtained as an average value of 5 random points measured by cross-sectional observation with a scanning electron microscope (SEM).

Manufacturing Method of Transfer Film

A manufacturing method of the transfer film of the first embodiment is not particularly limited, and a known method can be used.

Examples of the manufacturing method of the above-described transfer film include a method including a step of applying the photosensitive composition to a surface of the temporary support to form a coating film and then drying the coating film to form a photosensitive composition layer and a step of applying a composition for forming a refractive index adjusting layer to a surface of the photosensitive composition layer to form a coating film and then drying the coating film to form a refractive index adjusting layer.

In the manufacturing method of the transfer film of the first embodiment, it is preferable to manufacture the transfer film including the temporary support, the photosensitive composition layer, the refractive index adjusting layer, and the protective film by including a step of providing a protective film so as to be in contact with the surface of the refractive index adjusting layer opposite to the side having the temporary support.

After manufacturing the transfer film by the above-described manufacturing method, a roll-shaped transfer film may be manufactured and stored by winding the transfer film. The roll-shaped transfer film is provided as it is in a bonding step described later with the base material in a roll-to-roll method.

In addition, as the manufacturing method of the above-described transfer film, a method of forming the photosensitive resin layer on the surface of the refractive index adjusting layer after forming the refractive index adjusting layer on the protective film may be used.

In addition, as the manufacturing method of the above-described transfer film, a method in which the photosensitive composition layer is formed on the temporary support, the refractive index adjusting layer is separately formed on the protective film, and the refractive index adjusting layer is bonded to the photosensitive composition layer.

Forming Method of Photosensitive Composition and Photosensitive Composition Layer

From the viewpoint of excellent productivity, it is desirable that the photosensitive composition layer in the transfer film is formed by a coating method using a photosensitive composition including the components (for example, the binder polymer, the ethylenically unsaturated compound, the photopolymerization initiator, and the like) constituting the above-described photosensitive composition layer and a solvent. Specifically, as the manufacturing method of the transfer film of the first embodiment, a method in which the photosensitive composition is applied to the temporary support to form a coating film, and the coating film is dried at a predetermined temperature to form the photosensitive composition layer is preferable.

As the solvent which can be included in the photosensitive composition, an organic solvent is preferable. Examples of the organic solvent include methyl ethyl ketone, propylene glycol monomethyl ether, propylene glycol monomethyl ether acetate (another name: 1-methoxy-2-propyl acetate), diethylene glycol ethyl methyl ether, cyclohexanone, methyl isobutyl ketone, ethyl lactate, methyl lactate, caprolactam, n-propanol, and 2-propanol.

In addition, as the solvent, an organic solvent (high-boiling-point solvent) having a boiling point of 180° C. to 250° C. can also be used, as necessary.

The solvent may be used alone or in combination of two or more kinds thereof.

The total solid content of the photosensitive composition is preferably 5% to 80% by mass, more preferably 5% to 40% by mass, and still more preferably 5% to 30% by mass with respect to the total mass of the photosensitive composition.

That is, a content of the solvent in the photosensitive composition is preferably 20% to 95% by mass, more preferably 60% to 95% by mass, and still more preferably 70% to 95% by mass with respect to the total mass of the photosensitive composition.

For example, from the viewpoint of coating properties, a viscosity of the photosensitive composition at 25° C. is preferably 1 to 50 mPa·s, more preferably 2 to 40 mPa·s, and still more preferably 3 to 30 mPa·s. The viscosity is measured using a viscometer. As the viscometer, for example, a viscometer (product name: VISCOMETER TV-22) manufactured by Told Sangyo Co. Ltd. can be suitably used. However, the viscometer is not limited to the above-described viscometer.

For example, from the viewpoint of coating properties, a surface tension of the photosensitive composition at 25° C. is preferably 5 to 100 mN/m, more preferably 10 to 80 mN/m, and still more preferably 15 to 40 mN/m. The surface tension is measured using a tensiometer. As the tensiometer, for example, a tensiometer (product name: Automatic Surface Tensiometer CBVP-Z) manufactured by Kyowa Interface Science Co., Ltd. can be suitably used. However, the tensiometer is not limited to the above-described tensiometer.

Examples of a method for applying the photosensitive composition include a printing method, a spray coating method, a roll coating method, a bar coating method, a curtain coating method, a spin coating method, and a die coating method (that is, a slit coating method).

As a method for drying the coating film of the photosensitive composition, heat drying or vacuum drying is preferable. In the present specification, the “drying” means removing at least a part of the solvent included in the composition. Examples of the drying method include natural drying, heating drying, and drying under reduced pressure. The above-described methods can be adopted alone or in combination of two or more thereof.

The drying temperature is preferably 80° C. or higher and more preferably 90° C. or higher. In addition, the upper limit value thereof is preferably 130° C. or lower and more preferably 120° C. or lower. The drying can be performed by continuously changing the temperature.

In addition, the drying time is preferably 20 seconds or more, more preferably 40 seconds or more, and still more preferably 60 seconds or more. In addition, the upper limit value thereof is not particularly limited, but is preferably 600 seconds or less, and more preferably 300 seconds or less.

Forming Method of Composition for Forming Refractive Index Adjusting Layer and Refractive Index Adjusting Layer

The composition for forming a refractive index adjusting layer preferably includes various components forming the above-described refractive index adjusting layer and a solvent. In the composition for forming a refractive index adjusting layer, a suitable range of the content of each component with respect to the total solid content of the composition is the same as the suitable range of the content of each component with respect to the total mass of the refractive index adjusting layer described above.

The solvent is not particularly limited as long as it can dissolve or disperse the components included in the refractive index adjusting layer, and at least one selected from the group consisting of water and a water-miscible organic solvent is preferable, water or a mixed solvent of water and a water-miscible organic solvent is more preferable.

Examples of the water-miscible organic solvent include an alcohol having 1 to 3 carbon atoms, acetone, ethylene glycol, and glycerin, and an alcohol having 1 to 3 carbon atoms is preferable and methanol or ethanol is more preferable.

The solvent may be used alone, or in combination of two or more kinds thereof.

A content of the solvent is preferably 50 to 2,500 parts by mass, more preferably 50 to 1,900 parts by mass, and still more preferably 100 to 900 parts by mass with respect to 100 parts by mass of the total solid content of the composition.

The forming method of the refractive index adjusting layer is not particularly limited as long as it is a method capable of forming a layer including the components, and examples thereof include known coating methods (slit coating, spin coating, curtain coating, ink jet coating, and the like).

In addition, by bonding a protective film to the refractive index adjusting layer, the transfer film of the first embodiment can be manufactured.

A method of bonding the protective film to the refractive index adjusting layer is not particularly limited, and a known method can be mentioned.

Examples of an apparatus for bonding the protective film to the refractive index adjusting layer include known laminators such as a vacuum laminator and an auto-cut laminator.

It is preferable that the laminator is equipped with any heatable roller such as a rubber roller and can perform pressing and heating.

Manufacturing Method of Touch Panel Sensor

A manufacturing method of a touch panel sensor according to an embodiment of the present invention is not particularly limited as long as a touch panel sensor having the above-described characteristics can be manufactured, but from the viewpoint that it is easy to manufacture the touch panel sensor having the above-described characteristics, it is preferable to use the above-described transfer film.

Among these, a manufacturing method of a touch panel sensor, which includes a preparing step of preparing a base material with a photosensitive composition layer, which has a conductive base material including a touch panel sensor base material and a sensor electrode disposed on the base material and has a photosensitive composition layer disposed on the conductive base material and including a binder polymer, a compound having an ethylenically unsaturated group, and a photopolymerization initiator; an exposing step of exposing the photosensitive composition layer in a patterned manner; a developing step of developing the pattern-exposed photosensitive composition layer to form a resin layer pattern; and a curing step of exposing the resin layer pattern under a condition of the resin layer pattern being at 50° C. to 120° C. to form a protective film covering at least a part of the sensor electrode, is more preferable.

According to the above-described manufacturing method, a touch panel sensor in which a change in resistance value of the sensor electrode of the touch panel sensor after bending is small, and bright spots are less likely to be generated in the touch panel sensor in a case of handling such as a roll transporting can be manufactured. In particular, by performing the above-described curing step, it is easy to manufacture the touch panel sensor having the above-described characteristics.

Hereinafter, the procedure of more preferred steps described above will be described in detail.

Preparing Step

In the preparing step, a base material with a photosensitive composition layer, which has a conductive base material including a touch panel sensor base material and a sensor electrode disposed on the base material and has a photosensitive composition layer disposed on the conductive base material and including a binder polymer, a compound having an ethylenically unsaturated group, and a photopolymerization initiator, is prepared.

The conductive base material is as described above, including the preferred aspect.

The photosensitive composition layer is preferably disposed on the conductive base material using the above-described transfer film, and more preferably disposed by a bonding step of bonding the conductive base material and the transfer film to form a photosensitive composition layer.

The bonding step is a step of bonding a surface of the transfer film opposite to the temporary support to the conductive base material by being in contact with each other to obtain a base material with a photosensitive composition layer, which has the conductive base material, the sensor electrode, the photosensitive composition layer, and the temporary support in this order. In a case where the transfer film has a configuration of having the protective film, the protective film is peeled off and then the bonding step is performed.

In the above-described bonding, the sensor electrode and the surface of the above-described composition layer are pressure-bonded so as to be in contact with each other.

The above-described pressure-bonding method is not particularly limited, and a known transfer method and laminating method can be used. Among these, it is preferable that the surface of the composition layer is superposed on the conductive base material having the sensor electrode, and pressure and heating are performed by a roll or the like.

A known laminator such as a vacuum laminator and an auto-cut laminator can be used for the bonding.

A laminating temperature is not particularly limited, but is preferably, for example, 70° C. to 130° C.

From the purpose of protecting the sensor electrode, it is preferable that the protective film formed of the photosensitive composition layer in the transfer film of the present invention is provided so as to cover at least a part of the sensor electrode directly or through another layer.

Exposing Step

The exposing step is a step of exposing the photosensitive composition layer in a patterned manner.

Here, the “exposure in a patterned manner” refers to exposure in a form of performing the exposure in a patterned manner, that is, a form in which an exposed portion and an unexposed portion are present.

A positional relationship between the exposed portion and the unexposed portion in the exposure in a patterned manner is not particularly limited and is appropriately adjusted.

During the exposure, the exposure may be performed from the side opposite to the base material of the photosensitive composition layer, or may be performed from the base material side of the composition layer.

As a light source of the exposure in a patterned manner, a light source can be appropriately selected, as long as it can emit light at a wavelength region (for example, 365 nm or 405 nm) at which at least the photosensitive composition layer can be cured. Among these, a main wavelength of the exposure light for the exposure in a patterned manner is preferably 365 nm. The main wavelength is a wavelength having the highest intensity.

Examples of the light source include various lasers, a light emitting diode (LED), an ultra-high pressure mercury lamp, a high pressure mercury lamp, and a metal halide lamp.

An exposure amount is preferably 5 to 200 mJ/cm² and more preferably 10 to 200 mJ/cm².

Suitable aspects of the light source, the exposure amount, and the exposing method used for the exposure are described in, for example, paragraphs [0146] and [0147] of WO2018/155193A, the contents of which are incorporated herein by reference.

By performing the exposing step and the developing step described later, a resin layer pattern covering at least the sensor electrode is formed on the sensor electrode on the conductive base material.

Peeling Step

The above-described manufacturing method preferably includes, between the preparing step and the exposing step or between the exposing step and the developing step described later, a peeling step of peeling off the temporary support from the base material with a photosensitive composition layer.

The peeling method is not particularly limited, and the same mechanism as the cover film peeling mechanism described in paragraphs [0161] and [0162] of JP2010-072589A can be used.

Developing Step

The developing step is a step of developing the exposed photosensitive composition layer to form a resin layer pattern.

The development of the above-described photosensitive composition layer can be performed using a developer.

As the developer, an alkali aqueous solution is preferable. Examples of an alkali compound which can be included in the alkali aqueous solution include sodium hydroxide, potassium hydroxide, sodium carbonate, potassium carbonate, sodium hydrogen carbonate, potassium hydrogencarbonate, tetramethyl ammonium hydroxide, tetraethyl ammonium hydroxide, tetrapropyl ammonium hydroxide, tetrabutylammonium hydroxide, and choline (2-hydroxyethyltrimethylammonium hydroxide).

Examples of the development method include methods such as puddle development, shower development, spin development, and dip development.

Examples of the developer which is suitably used in the present specification include the developer described in paragraph [0194] of WO2015/093271A, and examples of the developing method which is suitably used include the developing method described in paragraph [0195] of WO2015/093271A.

Curing Step

The curing step is a step of exposing the resin layer pattern under a condition of the resin layer pattern being at 50° C. to 120° C. to form a protective film covering at least a part of the sensor electrode. That is, in the curing step, exposure is performed while heating the resin layer pattern.

A temperature of the curing step refers to a temperature of the surface of the resin layer pattern measured with a radiation temperature (IT-540 manufactured by Horiba Ltd.).

Here, the “exposing the resin layer pattern under a condition of the resin layer pattern being at 50° C. to 120° C.” refers to that the temperature of at least one measurement point on the surface of the resin layer pattern exposed in the curing step is 50° C. to 120° C. A proportion of an area where the resin layer pattern is at 50° C. to 120° C. in the surface of the exposed resin layer pattern is preferably 10% or more, more preferably 30% or more, still more preferably 50% or more, and particularly preferably 70% or more with respect to the entire area of the resin layer pattern. The upper limit thereof is 100% or less. The proportion of the area where the resin layer pattern is at 50° C. to 120° C. can be calculated by measuring the temperature of the resin layer pattern at different measurement points.

The temperature of the resin layer pattern in the curing step is 50° C. to 120° C. in the above, and is preferably 70° C. to 100° C., more preferably 80° C. to 95° C., and still more preferably 85° C. to 90° C. Further, it is also preferable that a proportion of an area of the above-described preferred temperature range in the surface of the exposed resin layer pattern is in the range of the above-described preferred proportion with respect to the entire area of the resin layer pattern.

An exposure amount in the curing step is preferably 200 to 1500 mJ/cm² and more preferably 200 mJ/cm² or more and less than 1000 mJ/cm². By setting the exposure amount in the curing step within the above-described range, it is easy to manufacture the touch panel sensor having the above-described characteristics.

Post-Baking Step

The above-described manufacturing method may include a step (post-baking step) of heating the protective film obtained in the above-described curing step.

A temperature of the post-baking is preferably 80° C. to 250° C. and more preferably 90° C. to 160° C. A post-baking time is preferably 1 minute to 180 minutes and more preferably 10 minutes to 60 minutes.

Reaction Rate

In the above-described manufacturing method, in a case where an intensity of an infrared absorption peak derived from the ethylenically unsaturated group included in the photosensitive composition layer is defined as Yᵢ and an intensity of an infrared absorption peak derived from the ethylenically unsaturated group included in the protective film is defined as Y₂, it is also preferable that a reaction rate calculated by the following expression (1) is 70% or more. The upper limit thereof is not particularly limited, but is 100% or less, preferably 90% or less and more preferably 85% or less.

Reaction rate [%]={1−(Y₂/Y₁)}×100 Expression (1)

By setting the above-described reaction rate within the above-described range, it is easy to manufacture the touch panel sensor having the above-described characteristics.

Y₁ is measured by the following procedure.

The temporary support on the surface of the base material with a photosensitive composition layer obtained in the above-described preparing step is peeled off, and the surface of the photosensitive composition layer is exposed.

An infrared absorption spectrum is acquired by ATR-IR (detector: MCT, crystal: Ge, wave number resolution: 4cm⁻¹, integration: 32 times) on the surface of the photosensitive composition layer using a fully automatic microscopic FT-IR system LUMOS (manufactured by Bruker Optics).

From the obtained infrared absorption spectrum, a peak surface area of 810 cm⁻¹ corresponding to a peak of a double bond corresponding to the ethylenically unsaturated group is calculated, and an area value thereof is defined as Y₁.

In addition, Y₂ is obtained in the same manner as in the measurement of Y₁ for the protective film obtained in the above-described curing step.

Application of Touch Panel Sensor

The touch panel sensor according to the embodiment of the present invention can be applied to various devices. Examples of the device provided with the above-described touch panel sensor include a display device and a semiconductor package input device, and a touch panel is preferable, and a capacitive touch panel is more preferable.

More specifically, the touch panel sensor according to the embodiment of the present invention can be suitably used for manufacturing a touch panel module. The touch panel module includes the touch panel sensor, a cover glass, and a peripheral wire.

In addition, the touch panel sensor according to the embodiment of the present invention can be suitably used for manufacturing a touch panel. The touch panel includes a touch panel module and a display device.

As the above-described display device, a display device such as an organic electroluminescent display device and a liquid crystal display device can be applied.

### EXAMPLES

Hereinbelow, the present invention will be described in more detail with reference to Examples.

The materials, the amounts and proportions of the materials used, the details of treatments, the procedure of treatments, and the like shown in the following Examples can be appropriately modified as long as the gist of the present invention is maintained. Therefore, the scope of the present invention should not be construed as being limited to Examples shown below.

Preparation of materials used for transfer film

Binder Polymer

Synthesis of Polymer P-1

A solution P-1 including a polymer P-1 represented by the following chemical formula was produced.

A compositional ratio of constitutional units in the following chemical formula is a molar ratio. The P-1 solution was produced by the following method.

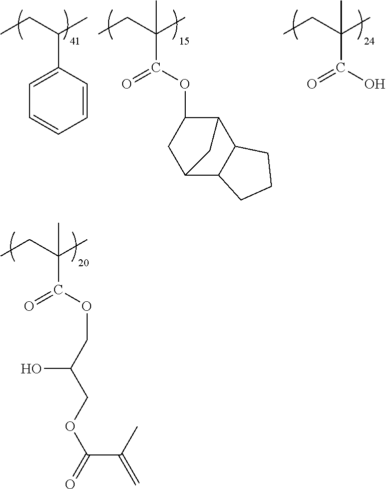

Propylene glycol monomethyl ether (82.4 g) was charged into a flask and heated to 90° C. under a nitrogen stream. To the flask, a solution in which styrene (38.4 g), dicyclopentanyl methacrylate (30.1 g), and methacrylic acid (34.0 g) had been dissolved in 20 g of propylene glycol monomethyl ether and a solution in which a polymerization initiator V-601 (manufactured by FUJIFILM Wako Pure Chemical Corporation, 5.4 g) had been dissolved in propylene glycol monomethyl ether acetate (43.6 g) was simultaneously added dropwise over 3 hours. After the dropwise addition, V-601 (0.75 g) was added thereto three times every hour.

The reaction solution was diluted with propylene glycol monomethyl ether acetate (58.4 g) and propylene glycol monomethyl ether (11.7 g). The reaction solution was heated to 100° C. under an air stream, and tetraethylammonium bromide (0.53 g) and p-methoxyphenol (0.26 g) were added thereto. Glycidyl methacrylate (Blemmer GH manufactured by NOF Corporation, 25.5 g) was added dropwise to the obtained mixture over 20 minutes. The obtained mixture was reacted at 100° C. for 7 hours to obtain a solution P-1 including a polymer P-1.

A concentration of solid contents of the solution P-1 was 36.5% by mass. The amount of residual monomer measured by gas chromatography was less than 0.1% by mass with respect to the solid content of the polymer P-1 in any of the monomers.

Properties of the polymer P-1 were as follows. The weight-average molecular weight (Mw) and number-average molecular weight (Mn) are standard polystyrene-equivalent molecular weights measured by gel permeation chromatography (GPC).
Weight-average molecular weight (Mw): 17,000
Number-average molecular weight (Mn): 7,400
Dispersity: 2.3
Acid value: 95 mgKOH/g

Synthesis of Polymer P-2

A solution P-2 including a polymer P-2 represented by the following chemical formula was produced.

A compositional ratio of constitutional units in the following chemical formula is a molar ratio. The P-2 solution was produced by the following method.

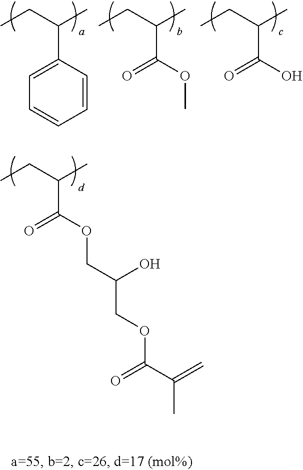

Propylene glycol monomethyl ether (113.5 g) was charged into a flask and heated to 90° C. under a nitrogen stream. To the flask, a solution in which styrene (172 g), methyl methacrylate (4.7 g), and methacrylic acid (112.1 g) had been dissolved in propylene glycol monomethyl ether (30 g) and a solution in which a polymerization initiator V-601 (manufactured by FUJIFILM Wako Pure Chemical Corporation, 27.6 g) had been dissolved in propylene glycol monomethyl ether (57.7 g) was simultaneously added dropwise over 3 hours. After the dropwise addition, V-601 (2.5 g) was added thereto three times every hour. Thereafter, the reaction was continued for another 3 hours.

The reaction solution was diluted with propylene glycol monomethyl ether acetate (160.7 g) and propylene glycol monomethyl ether (233.3 g). The reaction solution was heated to 100° C. under an air stream, and tetraethylammonium bromide (1.8 g) and p-methoxyphenol (0.86 g) were added thereto, and then glycidyl methacrylate (Blemmer G manufactured by NOF Corporation, 71.9 g) was added dropwise thereto over 20 minutes. The obtained mixture was reacted at 100° C. for 7 hours to obtain a solution P-2 including a polymer P-2.

A concentration of solid contents of the solution P-2 was 36.2% by mass. The amount of residual monomer measured by gas chromatography was less than 0.1% by mass with respect to the solid content of the polymer P-2 in any of the monomers.

Properties of the polymer P-2 were as follows. The weight-average molecular weight (Mw) and number-average molecular weight (Mn) are standard polystyrene-equivalent molecular weights measured by gel permeation chromatography (GPC).
Weight-average molecular weight (Mw): 18,000
Number-average molecular weight (Mn): 7,800
Dispersity: 2.3
Acid value: 124 mgKOH/g

Synthesis of Polymer P-3

A polymer P-3 was synthesized in the same manner as in the synthesis of the polymer P-1 to obtain a solution P-3, except that, in the synthesis of the polymer P-1, the step of adding glycidyl methacrylate dropwise was not performed.

A concentration of solid contents of the solution P-3 was 36.5% by mass. The amount of residual monomer measured by gas chromatography was less than 0.1% by mass with respect to the solid content of the polymer P-3 in any of the monomers.

Properties of the polymer P-3 were as follows. The weight-average molecular weight (Mw) and number-average molecular weight (Mn) are standard polystyrene-equivalent molecular weights measured by gel permeation chromatography (GPC).
Weight-average molecular weight (Mw): 18,000
Number-average molecular weight (Mn): 7,800
Dispersity: 2.3
Acid value: 174 mgKOH/g

Synthesis of Polymer P-4

A solution P-4 including a polymer P-4 represented by the following chemical formula was produced.

A compositional ratio of constitutional units in the following chemical formula is a molar ratio. The P-4 solution was produced by the following method.

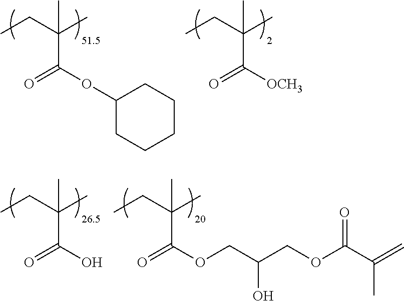

Propylene glycol monomethyl ether acetate (manufactured by Sanwa Chemical Industrial Co., Ltd., product name PGM-Ac) (60 g) and propylene glycol monomethyl ether (manufactured by Sanwa Chemical Industrial Co., Ltd., product name: PGM) (240 g) were introduced into a 2000 mL flask. The obtained liquid was heated to 90° C. while stirring.

For the preparation of a dropping liquid (1), methacrylic acid (manufactured by Mitsubishi Rayon Co., Ltd., product name: Acryester M) (107.1 g), methyl methacrylate (manufactured by Mitsubishi Gas Chemical Company, Inc., product name MMA) (5.46 g), and cyclohexyl methacrylate (manufactured by Mitsubishi Gas Chemical Co., Ltd., product name: CHMA) (231.42 g) were mixed and diluted with PGM-Ac (60 g) to obtain the dropping liquid (1).

For the preparation of a dropping liquid (2), dimethyl 2,2′-azobis(2-methylpropionate) (manufactured by FUJIFILM Wako Pure Chemical Corporation, product name: V-601) (9.637 g) was dissolved in PGM-Ac (136.56 g) to obtain the dropping liquid (2).

The dropping liquid (1) and the dropping liquid (2) were simultaneously added dropwise to the above-described 2000 mL flask (specifically, the 2000 mL flask containing the liquid heated to 90° C.) over 3 hours.

Next, the container of the dropping liquid (1) was washed with PGM-Ac (12 g) and the washing solution was added dropwise to the 2000 mL flask. Next, the container of the dropping liquid (2) was washed with PGM-Ac (6 g) and the washing solution was added dropwise to the 2000 mL flask. During these dropwise additions, the reaction solution in the 2000 mL flask was kept at 90° C. and stirred. Further, as a post-reaction, the reaction solution was stirred at 90° C. for 1 hour.

V-601 (2.401 g) was added to the reaction solution after the post-reaction as a first additional addition of the initiator. Further, the container of V-601 was washed with PGM-Ac (6 g), and the washing solution was introduced into the reaction solution. Thereafter, the reaction solution was stirred at 90° C. for 1 hour.

Next, V-601 (2.401 g) was added to the reaction solution as a second additional addition of the initiator. Further, the container of V-601 was washed with PGM-Ac (6 g), and the washing solution was introduced into the reaction solution. Thereafter, the reaction solution was stirred at 90° C. for 1 hour.

Next, V-601 (2.401 g) was added to the reaction solution as a third additional addition of the initiator. Further, the container of V-601 was washed with PGM-Ac (6 g), and the washing solution was introduced into the reaction solution. Thereafter, the reaction solution was stirred at 90° C. for 3 hours.

The obtained reaction solution was stirred at 90° C. for 3 hours, and then PGM-Ac (178.66 g) was introduced into the reaction solution. Next, tetraethylammonium bromide (manufactured by FUJIFILM Wako Pure Chemical Corporation) (1.8 g) and hydroquinone monomethyl ether (manufactured by FUJIFILM Wako Pure Chemical Corporation) (0.8 g) were added to the reaction solution. Further, each container was washed with PGM-Ac (6 g), and the washing solution was introduced into the reaction solution. Thereafter, the reaction solution was heated to 100° C.

Next, glycidyl methacrylate (manufactured by NOF Corporation, product name: Blemmer G) (76.03 g) was added dropwise to the reaction solution over 1 hour. The container of Blemmer G was washed with PGM-Ac (6 g), and the washing solution was introduced into the reaction solution. Thereafter, as an addition reaction, the reaction solution was stirred at 100° C. for 6 hours to obtain a solution P-4 including a polymer P-4.

A concentration of solid contents of the solution P-4 was 36.3% by mass. The amount of residual monomer measured by gas chromatography was less than 0.1% by mass with respect to the solid content of the polymer P-4 in any of the monomers.

Properties of the polymer P-4 were as follows. The weight-average molecular weight (Mw) and number-average molecular weight (Mn) are standard polystyrene-equivalent molecular weights measured by gel permeation chromatography (GPC).
Weight-average molecular weight (Mw): 27,000
Number-average molecular weight (Mn): 15,000
Dispersity: 1.8
Acid value: 95 mgKOH/g

Thermal Crosslinking Agent

Synthesis of Blocked Isocyanate Compound Q-1

Under a nitrogen stream, 453 g of butanone oxime (manufactured by Idemitsu Kosan Co., Ltd.) was dissolved in 700 g of methyl ethyl ketone. To the obtained mixture, 500 g of 1,3-bis(isocyanatomethyl)cyclohexane (mixture of cis-trans isomer, manufactured by Mitsui Chemicals Inc., TAKENATE 600) was added dropwise over 1 hour under ice-cooling, and the reaction was performed for another 1 hour. Thereafter, the temperature was raised to 40° C. and the reaction was performed for 1 hour.

It was confirmed by ¹H-nuclear magnetic resonance (NMR) and high performance liquid chromatography (HPLC) that the reaction was completed to obtain a methyl ethyl ketone solution of a blocked isocyanate compound Q-1. The blocked isocyanate compound Q-1 is represented by the following chemical formula.

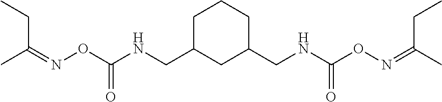 [SMILES: CC/C(C)=N\OC(=O)NCC1CCCC(CNC(=O)O/N=C(/C)CC)C1]

Preparation of Blocked Isocyanate Compound Q-2

As a blocked isocyanate compound Q-2, “DURANATE TPA-B80E” (manufactured by Asahi Kasei Corporation) was prepared.

### Example 1

Hereinafter, a procedure of Example 1 will be described.

Preparation of Photosensitive Composition A-1

A photosensitive composition A-1 was prepared by mixing the components (1) to (5) shown below, methyl ethyl ketone, and 1-methoxy-2-propyl acetate. The unit of the content of the components (1) to (5) shown below is a part by mass expressed in terms of solid contents.

The amount of methyl ethyl ketone and 1-methoxy-2-propyl acetate added was adjusted so that the concentration of solid contents of the photosensitive composition A-1 was 25% by mass. The amount of methyl ethyl ketone added was adjusted so that the proportion of methyl ethyl ketone in the solvent in the photosensitive composition A-1 was 60% by mass. (1) Binder polymer
P-1 solution: amount in which the solid content of the polymer was 52.67 parts by mass

(2) Polymerizable Compound

(2-1) Monomer having Two Ethylenically Unsaturated Bonds:
Tricyclodecane dimethanol diacrylate (A-DCP, manufactured by Shin-Nakamura Chemical Co., Ltd.): 17.90 parts by mass
Acrylic monomer (A-NOD-N, manufactured by Shin-Nakamura Chemical Co., Ltd.): 2.73 parts by mass

(2-2) Monomer having Five or more Ethylenically Unsaturated Bonds:
Monomer having a carboxy group (ARONIX TO2349, manufactured by Toagosei Co., Ltd.): 2.98 parts by mass
Acrylic monomer (A-DPH, manufactured by Shin-Nakamura Chemical Co., Ltd.): 7.99 parts by mass

(3) Thermal Crosslinking Compound
Blocked isocyanate compound Q-2: 12.50 parts by mass

(4) Polymerization Initiator
1-[9-ethyl-6-(2-methylbenzoyl)-9H-carbazole-3-yl]ethanone-1-(O-acetyloxime) (OXE-02, manufactured by BASF): 0.36 parts by mass
1-(biphenyl-4-yl)-2-methyl-2-morpholinopropan-1-one (APi-307, manufactured by Shenzhen UV-ChemTech Co., Ltd.): 0.73 parts by mass

(5) Additive
N-phenylglycine (manufactured by Tokyo Chemical Industry Co., Ltd.): 0.10 parts by mass
Benzimidazole (manufactured by Tokyo Chemical Industry Co., Ltd.): 0.52 parts by mass
Isonicotinamide (manufactured by Tokyo Chemical Industry Co., Ltd.): 0.13 parts by mass
XIRAN EF-40 (manufactured by KAWAHARA PETROCHEMICAL CO., LTD.): 1.20 parts by mass
MEGAFACE F551A (manufactured by DIC Corporation): 0.19 parts by mass

Manufacturing of Transfer Film

As a temporary support, a 16 μm-thick polyethylene terephthalate film (LUMIRROR 16KS40, manufactured by Toray Industries, Inc.) was prepared. The photosensitive composition A-1 was applied to the temporary support using a slit-shaped nozzle, and by volatilizing the solvent in a drying zone at 100° C., a photosensitive composition layer having a film thickness of 5.5 μm was formed. A protective film (LUMIRROR 16KS40, manufactured by Toray Industries, Inc.) was pressed onto the photosensitive composition layer to manufacture a transfer film.

Manufacturing of Touch Panel Sensor

A touch panel sensor was manufactured by the steps shown below. Each step shown below was performed by a roll-to-roll process.

Preparing Step

Manufacturing of Conductive Base Material

By the following procedure, a substrate including a base material, a transparent film, and a transparent electrode pattern (electrode sensor) in this order was obtained.

As the base material, a cycloolefin polymer film (thickness: 38 μm, refractive index: 1.53) was prepared. Using a high-frequency oscillator, the base material was subjected to a corona discharge treatment under the following conditions.

Output voltage: 100%

Output: 250 W

Electrode: wire electrode having a diameter of 1.2 mm

Electrode length: 240 mm

Distance between work electrodes 1.5 mm

Treatment time: 3 seconds

Next, a composition including components shown in Table 1 (numerical value of each component in Table 1 is the content (part by mass)) was applied to the base material using a slit-shaped nozzle, and then the composition was irradiated with ultraviolet rays (integrated light intensity: 300 mJ/cm²) and dried at approximately 110° C. to form a transparent film (refractive index: 1.60, thickness: 80 nm).

TABLE 1

| | Part by |
|---|---|
| Material | mass |
| ZrO₂: ZR-010 manufactured by Solar Corporation | 2.08 |
| KARAYAD DPHA (dipentaerythritol hexaacrylate, | 0.11 |
| manufactured by Nippon Kayaku Co., Ltd.) | |
| Urethane-based monomer: NK OLIGO UA-32P, manufactured | 0.11 |
| by Shin-Nakamura Chemical Co., Ltd. | |
| VISCOAT #802 (mixture of tripentaerythritol acrylate and | 0.36 |
| mono-, di-, or polypentaerythritol acrylate, manufactured by | |
| Osaka Organic Chemical Industry Ltd.) | |
| Polymer having structure represented by Formula P-25, | 0.85 |
| Mw: 35,000 | |
| Photoradical polymerization initiator: | 0.03 |
| 2-benzyl-2-dimethylamino-1-(4-morpholinylphenyl)butanone | |
| (Irgacure (resitered trademark) 369, manufactured by BASF SE) | |
| Photopolymerization initiator: KAYACURE DETX-S | 0.03 |
| (manufactured by Nippon Kayaku Co., Ltd., alkylthio xanthone) | |
| MEGAFACE F-551 (manufactured by DIC Corporation) | 0.01 |
| l-Methoxy-2-propyl acetate | 38.73 |
| Methyl ethyl ketone | 57.69 |
| Total (part by mass) | 100 |

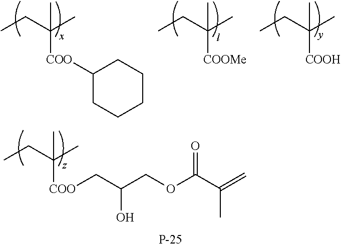

x:l:y:z = 46:2:20:32 (mol %)

An indium tin oxide (ITO) film having a thickness of 40 nm and a refractive index of 1.82 was formed on the transparent film by DC magnetron sputtering, and a transparent electrode pattern (electrode sensor) was formed on the transparent film by patterning the formed ITO film by photoetching. The formation of the ITO film and the patterning of the ITO film were carried out by the methods described in paragraphs [0119] to [0122] of JP2014-10814A.

Bonding Step

After peeling off the protective film of the transfer film, the transfer film was laminated to the substrate so that the photosensitive composition layer covered the transparent film and the electrode sensor.

The lamination was performed using a vacuum laminator manufactured by MCK under conditions of a temperature of the base material (that is, the cycloolefin polymer film): 40° C., a rubber roller temperature: 100° C., a linear pressure: 3 N/cm, and a transportation speed: 4 m/min.

By the above-described procedure, a base material with a photosensitive composition layer was obtained.

Exposing Step

Next, using a proximity type exposure machine (manufactured by Hitachi High-Tech Electronics Engineering Co., Ltd.) including an ultra-high pressure mercury lamp, an exposure mask (quartz exposure mask having a pattern for forming an overcoat) and the temporary support were closely attached, and the photosensitive composition layer was exposed in a patterned manner with an exposure amount of 150 mJ/cm² through the temporary support. The above-described exposure amount was measured by i-rays.

Developing Step

The exposed resin layer was allowed to stand in an environment of 23° C. and a relative humidity of 55% RH for 24 hours, and then the temporary support was peeled off and developed with a 1.0% by mass sodium carbonate aqueous solution (liquid temperature: 25° C.) for 25 seconds. The developed sample was washed with water by spraying pure water at 21° C. for 25 seconds from an ultra-high pressure washing nozzle, and air was blown to remove water adhering to the sample.

By the above-described procedure, a resin layer pattern was formed on the conductive base material.

Curing Step

While heating the resin layer pattern obtained in the above-described step with a hot plate, using a post-exposure machine (manufactured by USHIO INC.) having a high-pressure mercury lamp, the resin layer pattern was exposed at an exposure amount of 500 mJ/cm².

More specifically, a hot plate was installed directly under the lamp of the post-exposure machine, and the temperature of the hot plate was adjusted so that the temperature of the surface of the resin layer pattern was 90° C. The temperature of the surface of the resin layer pattern was measured with a radiation thermometer (IT-540, manufactured by Horiba Ltd.).

In addition, as for the exposure amount, the irradiation time at which the exposure amount was 500 mJ/cm² was confirmed in advance, and the exposure was performed at this irradiation time. The above-described exposure amount was measured by i-rays.

By the above-described step, a protective film covering at least a part of the sensor electrode was formed.

Post-Baking Step

A heat treatment was performed at 145° C. for 30 minutes to obtain a touch panel sensor used in Example 1, which included the base material, the transparent film, the electrode sensor, and the protective film in this order. The protective film is a cured substance of the photosensitive composition A-1.

### Examples 2 to 9, 12 to 14, and 17 to 19

Touch panel sensors used in Examples 2 to 9, 12 to 14, and 17 to 19 were obtained in the same manner as in the procedure of Example 1, except that the photosensitive composition was changed as shown in Table 4 described later, and the exposure conditions in the curing step were changed as shown in Table 4. In the photosensitive composition used in each Example, the additive used for the preparation of the photosensitive composition A-1 of Example 1 and the amount thereof were the same as those of A-1.

### Examples 10 and 11

Touch panel sensors used in Examples 10 and 11 were obtained according to the procedure of Example 1, except that, in the manufacturing of the transfer film of Example 1, a refractive index adjusting layer was provided on the surface of the photosensitive composition layer opposite to the temporary support, the photosensitive composition layer was changed as shown in Table 4 described later, and the exposure conditions in the curing step were changed as shown in Table 4. In the photosensitive composition used in each Example, the additive used for the preparation of the photosensitive composition A-1 of Example 1 and the amount thereof were the same as those of A-1.

Hereinafter, a production method of the refractive index adjusting layer will be shown.

Formation of Refractive Index Adjusting Layer

As a temporary support, a 16 μm-thick polyethylene terephthalate film (LUMIRROR 16KS40, manufactured by Toray Industries, Inc.) was prepared. The photosensitive composition A-1 was applied to the temporary support using a slit-shaped nozzle, and by volatilizing the solvent in a drying zone at 100° C., a photosensitive composition layer having a film thickness of 5.5 μm was formed.

Thereafter, a composition including components shown in Table 2 (numerical value of each component in Table 2 is the content (part by mass)) was applied to the photosensitive composition layer using a slit-shaped nozzle, and then by volatilizing the solvent in a drying zone at 110° C., a refractive index adjusting layer (refractive index: 1.68, thickness: 73 nm) was formed.

A protective film (LUMIRROR 16KS40, manufactured by Toray Industries, Inc.) was pressed onto the refractive index adjusting layer to manufacture a transfer film.

TABLE 2

| | Part by |
|---|---|
| Material | mass |
| NanoUse OZ-S30M: ZrO₂ particles (containing tin oxide) methanol dispersion | 4.34 |
| liquid (non-volatile component: 30.5%) manufactured by Nissan Chemical Corporation | |
| Ammonia water (25%) | 7.84 |
| Copolymer resin of methacrylic acid/allyl methacrylate (Mw: 38,000, composition | 0.20 |
| ratio = 20/80 wt %) | |
| ARUFON UC-3920 (manufactured by Toagosei Co., Ltd.) | 0.02 |
| Monomer having carboxy group ARONIX TO-2349 (manufactured by Toagosei Co., Ltd.) | 0.03 |
| Adenine (manufactured by Tokyo Chemical Industry Co., Ltd.) | 0.03 |
| N-Methyl diethanol amine (manufactured by Tokyo Chemical Industry Co., Ltd.) | 0.03 |
| MEGAFACE F444 (manufactured by DIC Corporation) | 0.01 |
| Ion exchange water | 21.3 |
| Methanol | 66.2 |
| Total (part by mass) | 100 |

### Examples 15 and 16

Touch panel sensors used in Examples 15 and 16 were obtained in the same manner as in the procedure of Example 1, except that the photosensitive composition was changed as shown in Table 3 described later, and the exposure conditions in the curing step were changed as shown in Table 4.

TABLE 3

| | | | Example | |
|---|---|---|---|---|
| | | | 15 | 16 |
| Composition | Photosensitive | — | A-8 | A-9 |
| | composition | | | |
| Binder polymer | Type | — | P-2 | P-4 |
| | Content | Part by mass | 55.62 | 61.22 |
| Polymerizable | KAYARAD R-604 | Part by mass | 10.94 | 11.48 |
| compound | A-NOD-N | Part by mass | 10.99 | 11.48 |
| | TO-2349 | Part by mass | 3.95 | 3.22 |
| | A-DPH | Part by mass | 10.26 | 10.55 |
| Thermal | SBN-70D | Part by mass | 3.54 | — |
| crosslinking | | | | |
| compound | | | | |
| Polymerization | APi 307 | Part by mass | 1.97 | 0.93 |
| initiator | Irgacure 379EG | Part by mass | 0.72 | 0.31 |
| Additive | Benzoimidazole | Part by mass | 0.31 | 0.31 |
| | Isonicotinamide | Part by mass | 0.99 | — |
| | EXP.MFS-578 | Part by mass | 1.08 | 0.82 |

In Table 3, each notation of the compound is as follows.

(1) Binder Polymer
P-2: P-2 solution described above
P-4: P-4 solution described above

The part by mass in the table represents the solid content of each solution.

(2) Polymerizable Compound

(2-1) Monomer having Two Ethylenically Unsaturated Bonds:
KAYARAD R-604: acrylic monomer, manufactured by Nippon Kayaku Co., Ltd.
A-NOD-N: acrylic monomer, manufactured by Shin-Nakamura Chemical Co., Ltd.

(2-2) Monomer having Five or more Ethylenically Unsaturated Bonds:
TO2349: monomer having a carboxy group, ARONIX TO2349, manufactured by Toagosei Co., Ltd.
A-DPH: acrylic monomer, manufactured by Shin-Nakamura Chemical Co., Ltd.

(3) Thermal Crosslinking Compound
SBN-70D: DURANATE SBN-70D, manufactured by Asahi Kasei Corporation

(4) Polymerization Initiator
APi-307: 1-(biphenyl-4-yl)-2-methyl-2-morpholinopropan-1-one, manufactured by Shenzhen UV-ChemTech Co., Ltd.
Irgacure 379EG: 2-(dimethylamino)-2-(4-methylbenzyl)-1-(4-morpholinophenyl) butan-1-one, manufactured by BASF

(5) Additive
Benzimidazole (manufactured by Tokyo Chemical Industry Co., Ltd.)
Isonicotinamide (manufactured by Tokyo Chemical Industry Co., Ltd.)
EXP.MFS-578: MEGAFACE EXP.MFS-578, manufactured by DIC Corporation

### Comparative Examples 1 and 2

Touch panel sensors used in Comparative Examples 1 and 2 were obtained in the same manner as in the procedure of Example 1, except that the temperature of the surface of the protective film in the curing step was changed to 30° C. as shown in Table 4 described later, and the exposure amount in the curing step was changed as shown in Table 4.

Measurement

Surface Hardness

A surface hardness of the touch panel sensor of each Example and each Comparative Example was measured by the method described above. The obtained surface hardness is shown in Table 4 below.

Mandrel Test

A mandrel test of the touch panel sensor of each Example and each Comparative Example was performed by the method described above. The obtained diameter X is shown in Table 4 below.

Reaction Rate

A reaction rate in the manufacturing step of the touch panel sensor of each Example and each Comparative Example was measured by the method described above. The obtained reaction rate is shown in Table 4 below.

Evaluation

Evaluation of Bright Spots

A web sample of the touch panel sensor manufactured above was transported using a web handling device equipped with a transport roll. For the transported touch panel sensor, the surface of the protective film was visually observed and observed with an optical microscope (binocular stereomicroscope, magnification: 10 times).

The visual observation was performed from the protective film side under fluorescent lighting. In addition, the observation with an optical microscope was performed from the protective film side.

In the observation, bright spots were evaluated based on the following evaluation standard according to the condition of the bright spots where a reflected light looks strong.

A to C are evaluations which have no problem in practical use.

Evaluation Standard

A: no bright spots could be seen by both the microscopic observation and visual observation.

B: slight bright spots could be seen by the microscopic observation, but no bright spots could be seen by the visual observation.

C: slight bright spots could be seen by the visual observation.

D: bright spots could be seen by the visual observation.

Evaluation of Resistance Change

The touch panel sensor was allowed to stand still with the touch panel sensor deformed into an S shape, and a change in resistance value of the sensor electrode before and after the standing was measured.

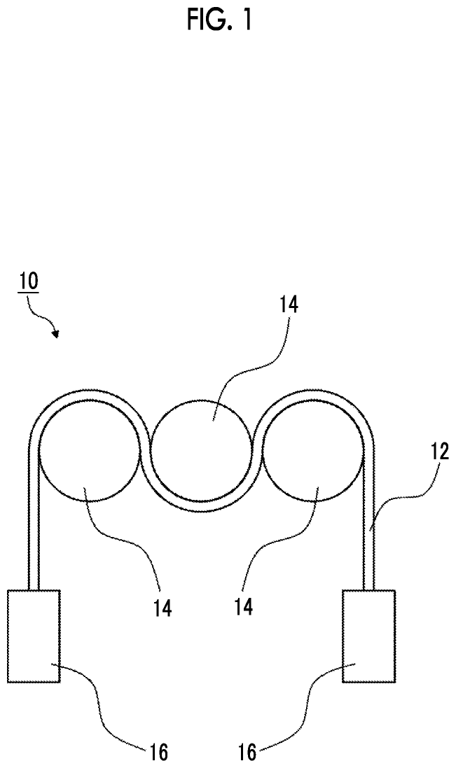

More specifically, as shown in the cross-sectional view (FIG. 1) showing a deformation state 10 of the touch panel sensor, a touch panel sensor 12 was deformed into an S shape along a cylindrical rod 14 having a diameter of 3 mm, and a load 16 was allowed to act at 10 g/cm. In this state, the touch panel sensor was allowed to stand still in an environment of 60° C. and 90% for 500 hours.

Thereafter, from a change in resistance value of the sensor electrode (ITO electrode) before and after the standing, a resistance change was evaluated based on the following evaluation standard. The change in resistance value (%) was calculated by {(Resistance value after standing−Resistance value before standing)/Resistance value before standing}×100.

A to C are resistance changes which have no problem in practical use.

Evaluation Standard

A: change in resistance value was less than 0.1%.

B: change in resistance value was 0.1% or more and less than 1.0%.

C: change in resistance value was 1.0% or more and less than 5.0%.

D: change in resistance value was 5.0% or more.

Result

Table 4 shows the above-described evaluation results of each Example and each Comparative Example.

In Table 4, the notation of each compound of the transfer film is as follows.

(1) Binder Polymer
P-1: P-1 solution described above
P-2: P-2 solution described above
P-3: P-3 solution described above

The part by mass in the table represents the solid content of each solution.

(2) Polymerizable Compound

(2-1) Monomer having Two Ethylenically Unsaturated Bonds:
A-DCP: tricyclodecane dimethanol diacrylate, manufactured by Shin-Nakamura Chemical Co., Ltd.
A-NOD-N: acrylic monomer, manufactured by Shin-Nakamura Chemical Co., Ltd.

(2-2) Monomer having Five or more Ethylenically Unsaturated Bonds:
TO2349: monomer having a carboxy group, ARONIX TO2349, manufactured by Toagosei Co., Ltd.
A-DPH: acrylic monomer, manufactured by Shin-Nakamura Chemical Co., Ltd.
8UX-015A: urethane acrylate monomer, manufactured by Taisei Fine Chemical Co., Ltd.

(3) Thermal Crosslinking Compound
Q-1: blocked isocyanate compound Q-1 described above
Q-2: blocked isocyanate compound Q-2 described above

(4) Polymerization Initiator
OXE-02: 1-[9-ethyl-6-(2-methylbenzoyl)-9H-carbazole-3-yl]ethanone-1-(O-acetyloxime, manufactured by BASF
Irgacure 907: 2-methyl-4′-methylthio-2-morpholinopropiophenone, manufactured by BASF
APi-307: 1-(biphenyl-4-yl)-2-methyl-2-morpholinopropan-1-one, manufactured by Shenzhen UV-ChemTech Co., Ltd.

TABLE 4

| | | | | Example | | | | | | | |
|---|---|---|---|---|---|---|---|---|---|---|---|
| | | | | 1 | 2 | 3 | 4 | 5 | 6 | 7 | 8 |
| Transfer | Composition | Refractive index | — | — | — | — | — | — | — | — | — |
| film | | adjusting layer | | | | | | | | | |
| | | composition | | | | | | | | | |
| | | Photosensitive | — | A-1 | A-2 | A-3 | A-1 | A-1 | A-1 | A-4 | A-5 |
| | | composition | | | | | | | | | |
| | Binder polymer | Type | — | P-1 | P-1 | P-2 | P-1 | P-1 | P-1 | P-3 | P-1 |
| | | Content | Part by mass | 52.67 | 52.67 | 49.04 | 52.67 | 52.67 | 52.67 | 52.67 | 52.67 |
| | Polymerizable | A-DCP | Part by mass | 17.90 | 17.90 | 9.13 | 17.90 | 17.90 | 17.90 | 17.90 | 17.90 |
| | compound | A-NOD-N | Part by mass | 2.73 | 2.73 | 2.79 | 2.73 | 2.73 | 2.73 | 2.73 | 13.70 |
| | | TO2349 | Part by mass | 2.98 | 2.98 | 3.04 | 2.98 | 2.98 | 2.98 | 2.98 | — |
| | | A-DPH | Part by mass | 7.99 | 7.99 | 17.28 | 7.99 | 7.99 | 7.99 | 7.99 | — |
| | | 8UX-015A | Part by mass | — | — | — | — | — | — | — | — |
| | Thermal crosslinking | Q-1 | Part by mass | 12.50 | 12.50 | 12.50 | 12.50 | 12.50 | 12.50 | 12.50 | 12.50 |
| | compound | Q-2 | Part by mass | — | — | 2.97 | — | — | — | — | — |
| | Polymerization | OXE-02 | Part by mass | 0.36 | 0.36 | 0.37 | 0.36 | 0.36 | 0.36 | 0.36 | 0.36 |
| | initiator | Irgacure 907 | Part by mass | — | 0.73 | — | — | — | — | — | — |
| | | Api-307 | Part by mass | 0.73 | — | 0.74 | 0.73 | 0.73 | 0.73 | 0.73 | 0.73 |
| | Layer thickness | Transparent layer | nm | — | — | — | — | — | — | — | — |
| | | Photosensitive | μm | 5.5 | 5.5 | 5.5 | 5.5 | 5.5 | 5.5 | 5.5 | 5.5 |
| | | resin layer | | | | | | | | | |

| | | | | | | | | | |
|---|---|---|---|---|---|---|---|---|---|
| Second polymerizable compound/ | — | 0.532 | 0.532 | 1.705 | 0.532 | 0.532 | 0.532 | 0.532 | — |
| first polymerizable compound | | | | | | | | | |

| Curing step | Temperature | ° C. | 90 | 90 | 90 | 85 | 80 | 100 | 90 | 90 |
|---|---|---|---|---|---|---|---|---|---|---|
| | Exposure amount | mJ/cm² | 500 | 500 | 500 | 500 | 450 | 1000 | 500 | 500 |
| Physical property measurement | Surface hardness | mN/mm² | 210 | 210 | 200 | 195 | 190 | 220 | 190 | 185 |
| | Mandrel test | mm | 2 | 2 | 3 | 2 | 1 | 3 | 3 | 1 |
| | Reaction rate | % | 75 | 75 | 72 | 72 | 70 | 78 | 75 | 80 |
| Evaluation | Evaluation of | — | A | A | A | A | B | A | B | C |
| | bright spots | | | | | | | | | |
| | Evaluation of | — | B | B | C | B | A | C | C | A |
| | resistance | | | | | | | | | |
| | change | | | | | | | | | |

| | | | | Example | | | | | | |
|---|---|---|---|---|---|---|---|---|---|---|
| | | | | 9 | 10 | 11 | 12 | 13 | 14 | 15 |
| Transfer | Composition | Refractive index | — | — | B-1 | B-1 | — | — | — | — |
| film | | adjusting layer | | | | | | | | |
| | | composition | | | | | | | | |
| | | Photosensitive | — | A-6 | A-2 | A-3 | A-7 | A-1 | A-1 | A-8 |
| | | composition | | | | | | | | |
| | Binder polymer | Type | — | P-1 | P-1 | P-2 | P-1 | P-1 | P-1 | P-2 |
| | | Content | Part by mass | 52.67 | 52.67 | 49.04 | 65.17 | 52.67 | 52.67 | See |
| | Polymerizable | A-DCP | Part by mass | — | 17.90 | 9.13 | 17.90 | 17.90 | 17.90 | Table 3 |
| | compound | A-NOD-N | Part by mass | — | 2.73 | 2.79 | 2.73 | 2.73 | 2.73 | |
| | | TO2349 | Part by mass | — | 2.98 | 3.04 | 2.98 | 2.98 | 2.98 | |
| | | A-DPH | Part by mass | 17.90 | 7.99 | 17.28 | 7.99 | 7.99 | 7.99 | |
| | | 8UX-015A | Part by mass | 13.70 | — | — | — | — | — | |
| | Thermal crosslinking | Q-1 | Part by mass | 12.50 | 12.50 | 12.50 | — | 12.50 | 12.50 | |
| | compound | Q-2 | Part by mass | — | — | 2.97 | — | — | — | |
| | Polymerization | OXE-02 | Part by mass | 0.36 | 0.36 | 0.37 | 0.36 | 0.36 | 0.36 | |
| | initiator | Irgacure 907 | Part by mass | — | 0.73 | — | — | — | — | |
| | | Api-307 | Part by mass | 0.73 | — | 0.74 | 0.73 | 0.73 | 0.73 | |
| | Layer thickness | Transparent layer | nm | — | 73 | 73 | — | — | — | — |
| | | Photosensitive | μm | 5.5 | 5.5 | 5.5 | 5.5. | 8.0 | 3.0 | 5.5 |
| | | resin layer | | | | | | | | |

| | | | | | | | | |
|---|---|---|---|---|---|---|---|---|
| Second polymerizable compound/ | — | — | 0.532 | 1.705 | 0.532 | 0.532 | 0.532 | 0.648 |
| first polymerizable compound | | | | | | | | |

| Curing step | Temperature | ° C. | 90 | 90 | 90 | 90 | 90 | 90 | 90 |
|---|---|---|---|---|---|---|---|---|---|
| | Exposure amount | mJ/cm² | 500 | 500 | 500 | 500 | 500 | 500 | 500 |
| Physical property measurement | Surface hardness | mN/mm² | 210 | 210 | 200 | 210 | 210 | 210 | 210 |
| | Mandrel test | mm | 3 | 2 | 3 | 2 | 2 | 2 | 2 |
| | Reaction rate | % | 75 | 75 | 72 | 75 | 75 | 75 | 75 |
| Evaluation | Evaluation of | — | A | A | A | A | A | A | A |
| | bright spots | | | | | | | | |
| | Evaluation of | — | C | B | C | B | B | B | B |
| | resistance | | | | | | | | |
| | change | | | | | | | | |

| | | | | Example | | | | Comparative Example | |
|---|---|---|---|---|---|---|---|---|---|
| | | | | 16 | 17 | 18 | 19 | 1 | 2 |
| Transfer | Composition | Refractive index | — | — | — | — | — | — | — |
| film | | adjusting layer | | | | | | | |
| | | composition | | | | | | | |
| | | Photosensitive | — | A-9 | A-10 | A-11 | A-12 | A-1 | A-1 |
| | | composition | | | | | | | |
| | Binder polymer | Type | — | P-4 | P-1 | P-1 | P-1 | P-1 | P-1 |
| | | Content | Part by mass | See | 52.67 | 52.67 | 52.67 | 52.67 | 52.67 |
| | Polymerizable | A-DCP | Part by mass | Table 3 | 18.40 | 20.90 | 12.09 | 17.90 | 17.90 |
| | compound | A-NOD-N | Part by mass | | 3.73 | 3.73 | 1.73 | 2.73 | 2.73 |
| | | TO2349 | Part by mass | | 3.98 | 3.98 | 1.98 | 2.98 | 2.98 |
| | | A-DPH | Part by mass | | 5.49 | 2.99 | 15.8 | 7.99 | 7.99 |
| | | 8UX-015A | Part by mass | | — | — | — | — | — |
| | Thermal crosslinking | Q-1 | Part by mass | | 12.50 | 12.50 | 12.50 | 12.50 | 12.50 |
| | compound | Q-2 | Part by mass | | — | — | — | — | — |
| | Polymerization | OXE-02 | Part by mass | | 0.36 | 0.36 | 0.36 | 0.36 | 0.36 |
| | initiator | Irgacure 907 | Part by mass | | — | — | — | — | — |
| | | Api-307 | Part by mass | | 0.73 | 0.73 | 0.73 | 0.73 | 0.73 |
| | Layer thickness | Transparent layer | nm | — | — | — | — | — | — |
| | | Photosensitive | μm | 5.5 | 5.5 | 5.5 | 5.5 | 5.5 | 5.5 |
| | | resin layer | | | | | | | |

| | | | | | | | |
|---|---|---|---|---|---|---|---|
| Second polymerizable compound/ | — | 0.600 | 0.428 | 0.283 | 1.287 | 0.532 | 0.532 |
| first polymerizable compound | | | | | | | |

| Curing step | Temperature | ° C. | 90 | 90 | 90 | 90 | 30 | 30 |
|---|---|---|---|---|---|---|---|---|
| | Exposure amount | mJ/cm² | 500 | 500 | 500 | 500 | 400 | 2000 |
| Physical property measurement | Surface hardness | mN/mm² | 210 | 210 | 190 | 210 | 180 | 230 |
| | Mandrel test | mm | 2 | 2 | 2 | 2 | 1 | 5 |
| | Reaction rate | % | 75 | 75 | 75 | 75 | 60 | 78 |
| Evaluation | Evaluation of | — | A | A | B | A | D | A |
| | bright spots | | | | | | | |

| | | | | | | | |
|---|---|---|---|---|---|---|---|
| Evaluation of | — | B | B | B | B | A | D |
| resistance | | | | | | | |
| change | | | | | | | |

From the results in Table 4, it was confirmed that the touch panel sensor according to the embodiment of the present invention had a desired effect.

From the comparison between Example 7 and other Examples, it was confirmed that, in a case where the photosensitive composition included the binder polymer having an ethylenically unsaturated group in the side chain, the effects of the present invention were more excellent.

From the comparison between Examples 8 and 9 and other Examples, it was confirmed that, in a case where the photosensitive composition included the first polymerizable compound having two ethylenically unsaturated groups and the second polymerizable compound having five or more ethylenically unsaturated groups, the effects of the present invention were more excellent.

From the comparison between Examples 3 and 18 and other Examples, it was confirmed that, in a case where the photosensitive composition included the first polymerizable compound and the second polymerizable compound, in which a mass ratio of the content of the second polymerizable compound to the content of the first polymerizable compound was 0.4 to 1.3, the effects of the present invention were more excellent.

From the comparison between each Comparative Example and each Example, it was confirmed that, according to the above-described more preferred manufacturing method of a touch panel sensor, the touch panel sensor according to the embodiment of the present invention could be manufactured.

From the comparison between Example 6 and other Examples, it was confirmed that, in a case where the exposure amount in the curing step was 200 mJ/cm² or more and less than 1000 mJ/cm², a touch panel sensor in which the effects of the present invention were more excellent was manufactured.

### EXPLANATION OF REFERENCES

10: deformation state of touch panel sensor

12: touch panel sensor

14: cylindrical rod

16: load

What is claimed is:

1. A touch panel sensor comprising:
a conductive base material including a base material and a sensor electrode disposed on the base material; and
a protective film covering at least a part of the sensor electrode,
wherein a surface hardness of the protective film on an opposite side to the conductive base material is 185 mN/mm² or more, and
a diameter X obtained by performing the following mandrel test is 3 mm or less,
mandrel test: an operation of winding the touch panel sensor around a mandrel and returning the touch panel sensor to an original position is repeated 10 times, an operation of observing the protective film of the touch panel sensor with an optical microscope at a magnification of 10 times to confirm presence or absence of cracks in the protective film is repeated while reducing a diameter of the mandrel, and a diameter of the mandrel in which the protective film is cracked is defined as the diameter X.

2. The touch panel sensor according to claim 1,
wherein the protective film is a film formed of a photosensitive composition, and
the photosensitive composition includes a binder polymer having an ethylenically unsaturated group in a side chain.

3. The touch panel sensor according to claim 2,
wherein the photosensitive composition further includes a first polymerizable compound having two ethylenically unsaturated groups and a second polymerizable compound having five or more ethylenically unsaturated groups.

4. The touch panel sensor according to claim 3,
wherein a mass ratio of a content of the second polymerizable compound to a content of the first polymerizable compound is 0.4 to 1.3.

5. A manufacturing method of a touch panel sensor, comprising:
a preparing step of preparing a base material with a photosensitive composition layer, which has a conductive base material including a base material and a sensor electrode disposed on the base material and has a photosensitive composition layer disposed on the conductive base material and including a binder polymer, a compound having an ethylenically unsaturated group, and a photopolymerization initiator;
an exposing step of exposing the photosensitive composition layer in a patterned manner;
a developing step of developing the exposed photosensitive composition layer to form a resin layer pattern; and
a curing step of exposing the resin layer pattern under a condition of the resin layer pattern being at 50° C. to 120° C. to form a protective film covering at least a part of the sensor electrode.

6. The manufacturing method of a touch panel sensor according to claim 5,
wherein an exposure amount in the curing step is 200 to 1500 mJ/cm².

7. The manufacturing method of a touch panel sensor according to claim 5,
wherein an exposure amount in the curing step is 200 mJ/cm² or more and less than 1000 mJ/cm².

8. The manufacturing method of a touch panel sensor according to claim 5,
wherein, in a case where an intensity of an infrared absorption peak derived from the ethylenically unsaturated group included in the photosensitive composition layer is defined as Y₁ and an intensity of an infrared absorption peak derived from the ethylenically unsaturated group included in the protective film is defined as Y₂, a reaction rate calculated by the following expression (1) is 70% or more,
reaction rate [%]={1−(Y₂/Y₁)}×100. expression (1)

9. The manufacturing method of a touch panel sensor according to claim 6,
wherein, in a case where an intensity of an infrared absorption peak derived from the ethylenically unsaturated group included in the photosensitive composition layer is defined as Y₁ and an intensity of an infrared absorption peak derived from the ethylenically unsaturated group included in the protective film is defined as Y₂, a reaction rate calculated by the following expression (1) is 70% or more,
reaction rate [%]={1−(Y₂/Y₁)}×100. expression (1)

10. The manufacturing method of a touch panel sensor according to claim 7,
wherein, in a case where an intensity of an infrared absorption peak derived from the ethylenically unsaturated group included in the photosensitive composition layer is defined as Y₁ and an intensity of an infrared absorption peak derived from the ethylenically unsaturated group included in the protective film is defined as Y₂, a reaction rate calculated by the following expression (1) is 70% or more,
reaction rate [%]={1−(Y₂/Y₁)}×100. expression (1)
